(19) United States
(12) Patent Application Publication
(10) Pub. No.: US 2026/0231478 A1
(43) Pub. Date: Aug. 6, 2026

(54) SEMICONDUCTOR APPARATUS AND ELECTRONIC DEVICE

(71) Applicant: SONY SEMICONDUCTOR SOLUTIONS CORPORATION, KANAGAWA (JP)

(72) Inventors: AKIKO HONJO, KANAGAWA (JP); YOSHIAKI KIKUCHI, KANAGAWA (JP)

(21) Appl. No.: 19/153,290

(22) PCT Filed: Dec. 22, 2023
(86) PCT No.: PCT/JP2023/046210

§ 371 Date: Aug. 1, 2025

(30) Foreign Application Priority Data
Feb. 10, 2023 (JP) 2023-019112

(51) Int. Cl. H10D 30/69; H10D 30/63; H10D 62/17; H10D 84/83; H10F 39/00

(52) U.S. Cl. CPC H10D 30/792; H10D 30/637; H10D 62/235; H10D 84/83; H10F 39/80373; H10F 39/80377

(57) ABSTRACT

Mutual conductance of a field effect transistor is increased. A semiconductor apparatus includes: a semiconductor part having an upper face and a side face; a field effect transistor having a gate electrode provided across the upper face and the side face of the semiconductor part; and a stress part provided between the upper face of the semiconductor part and the gate electrode, the stress part producing, in the semiconductor part, stress in a direction that increases current flowing in the semiconductor part.

### TECHNICAL FIELD

The present technique (the technique according to the present disclosure) relates to a semiconductor apparatus and an electronic device, and particularly relates to a technique useful for applications in a semiconductor apparatus having a field effect transistor and an electronic device provided therewith.

### BACKGROUND ART

A field effect transistor, in which a semiconductor part having a three-dimensional shape is provided with a gate electrode, is known as a field effect transistor mounted in a semiconductor apparatus. PTL 1 discloses a fin-type field effect transistor (Fin-FET) provided with a gate electrode across three faces (an upper face and two side faces) of a semiconductor part, and a field effect transistor having a Gate all Around (GAA) structure in which a gate electrode is provided across four faces (an upper face, a lower face, and two side faces) of a semiconductor part.

PTL 1, meanwhile, discloses a technique for improving carrier mobility by providing a stress liner that distorts a semiconductor fin.

### CITATION LIST

### Patent Literature

### [PTL 1]

WO 2020/262643

### [PTL 2]

JP 2007-242737 A

### SUMMARY

### Technical Problem

As the integration and miniaturization of semiconductor apparatuses progresses, the field effect transistors mounted in semiconductor apparatuses are becoming smaller as well. For this reason, a field effect transistor capable of achieving large change in drain current in response to a small change in gate voltage is desired.

An object of the present technique is to provide a technique capable of improving the mutual conductance (gm) in a field effect transistor.

### Solution to Problem

(1) A semiconductor apparatus according to one aspect of the present technique includes:
a semiconductor part having an upper face and a side face;
a field effect transistor having a gate electrode provided across the upper face and the side face of the semiconductor part; and
a stress part provided between the upper face of the semiconductor part and the gate electrode, the stress part producing, in the semiconductor part, stress in a direction that increases current flowing in the semiconductor part.
   (2) A semiconductor apparatus according to another aspect of the present technique includes:
a semiconductor part having an upper face and a side face;
a field effect transistor having a gate electrode provided across the upper face and the side face of the semiconductor part; and
a stress part provided, in plan view, overlapping with the semiconductor part and on an opposite side of the semiconductor part to the upper face side, the stress part producing, in the semiconductor part, stress in a direction that increases current flowing in the semiconductor part.
   (3) a Semiconductor Apparatus According to Another Aspect of the Present technique includes:
a semiconductor part having an upper face and a side face;
a field effect transistor having a gate electrode provided across the upper face and the side face of the semiconductor part; and
a stress part adjacent to the semiconductor part along a thickness direction of the semiconductor part on an outer side of the gate electrode, the stress part producing stress in the semiconductor part in a direction that increases current flowing in the semiconductor part.
   (4) A semiconductor apparatus according to another aspect of the present technique includes:
a semiconductor part having an upper face and a side face;
a field effect transistor having a gate electrode provided across the upper face and the side face of the semiconductor part;
an insulating layer surrounding the side face of the semiconductor part in plan view; and
a cavity part provided between the insulating layer and the side face of the semiconductor part.
   (5) An electronic device according to another aspect of the present technique includes:
the semiconductor apparatus;
an optical system in which image light from a subject is formed in the semiconductor apparatus; and
a signal processing circuit that performs signal processing on a signal output from the semiconductor apparatus.

### BRIEF DESCRIPTION OF DRAWINGS

FIG. 1 is a plan view schematically illustrating an example of the configuration of a semiconductor apparatus according to Embodiment 1 of the present technique.

FIG. 2 is a longitudinal cross-sectional view schematically illustrating a longitudinal cross-sectional structure along a line a1-a1 in FIG. 1.

FIG. 3 is a longitudinal cross-sectional view schematically illustrating a longitudinal cross-sectional structure along a line b1-b1 in FIG. 1.

FIG. 4 is a longitudinal cross-sectional view schematically illustrating Variation 1-1 on Embodiment 1.

FIG. 5 is a plan view schematically illustrating an example of the configuration of a semiconductor apparatus according to Embodiment 2 of the present technique.

FIG. 6 is a longitudinal cross-sectional view schematically illustrating a longitudinal cross-sectional structure along a line a5-a5 in FIG. 5.

FIG. 7 is a longitudinal cross-sectional view schematically illustrating a longitudinal cross-sectional structure along a line b5-b5 in FIG. 5.

FIG. 8 is a plan view schematically illustrating the longitudinal cross-sectional structure of a semiconductor apparatus according to Embodiment 3 of the present technique.

FIG. 9 is a plan view schematically illustrating an example of the configuration of a semiconductor apparatus according to Embodiment 4 of the present technique.

FIG. 10 is a longitudinal cross-sectional view schematically illustrating a longitudinal cross-sectional structure along a line a9-a9 in FIG. 9.

FIG. 11 is a longitudinal cross-sectional view schematically illustrating a longitudinal cross-sectional structure along a line b9-b9 in FIG. 9.

FIG. 12 is a longitudinal cross-sectional view schematically illustrating Variation 4-1 on Embodiment 4 of the present technique.

FIG. 13 is a plan view schematically illustrating an example of the configuration of a semiconductor apparatus according to Embodiment 5 of the present technique.

FIG. 14 is a longitudinal cross-sectional view schematically illustrating a longitudinal cross-sectional structure along a line a13-a13 in FIG. 13.

FIG. 15 is a longitudinal cross-sectional view schematically illustrating a longitudinal cross-sectional structure along a line b13-b13 in FIG. 13.

FIG. 16A is a longitudinal cross-sectional view schematically illustrating Variation 5-1 on Embodiment 5 of the present technique.

FIG. 16B is a longitudinal cross-sectional view schematically illustrating Variation 5-1 on Embodiment 5 of the present technique.

FIG. 17 is a plan view schematically illustrating an example of the configuration of a semiconductor apparatus according to Embodiment 6 of the present technique.

FIG. 18 is a longitudinal cross-sectional view schematically illustrating a longitudinal cross-sectional structure along a line a17-a17 in FIG. 17.

FIG. 19 is a longitudinal cross-sectional view schematically illustrating a longitudinal cross-sectional structure along a line b17-b17 in FIG. 17.

FIG. 20 is a longitudinal cross-sectional view schematically illustrating Variation 6-1 on Embodiment 6 of the present technique.

FIG. 21 is a longitudinal cross-sectional view schematically illustrating Variation 6-2 on Embodiment 6 of the present technique.

FIG. 22 is a longitudinal cross-sectional view schematically illustrating Variation 6-3 on Embodiment 6 of the present technique.

FIG. 23 is a longitudinal cross-sectional view schematically illustrating Variation 6-4 on Embodiment 6 of the present technique.

FIG. 24 is a longitudinal cross-sectional view schematically illustrating Variation 6-5 on Embodiment 6 of the present technique.

FIG. 25 is a longitudinal cross-sectional view schematically illustrating Variation 6-6 on Embodiment 6 of the present technique.

FIG. 26 is a plan view schematically illustrating an example of the configuration of a semiconductor apparatus according to Embodiment 7 of the present technique.

FIG. 27 is a longitudinal cross-sectional view schematically illustrating a longitudinal cross-sectional structure along a line a26-a26 in FIG. 26.

FIG. 28 is a longitudinal cross-sectional view schematically illustrating a longitudinal cross-sectional structure along a line b26-26 in FIG. 26.

FIG. 29 is a longitudinal cross-sectional view schematically illustrating a longitudinal cross-sectional structure along a line c26-c26 in FIG. 26.

FIG. 30 is a longitudinal cross-sectional view schematically illustrating Variation 7-1 on Embodiment 7 of the present technique.

FIG. 31 is a longitudinal cross-sectional view schematically illustrating Variation 7-2 on Embodiment 7 of the present technique.

FIG. 32 is a longitudinal cross-sectional view schematically illustrating Variation 7-3 on Embodiment 7 of the present technique.

FIG. 33 is a longitudinal cross-sectional view schematically illustrating Variation 7-4 on Embodiment 7 of the present technique.

FIG. 34 is a longitudinal cross-sectional view schematically illustrating Variation 7-5 on Embodiment 7 of the present technique.

FIG. 35 is a longitudinal cross-sectional view schematically illustrating Variation 7-6 on Embodiment 7 of the present technique.

FIG. 36 is a longitudinal cross-sectional view schematically illustrating Variation 7-7 on Embodiment 7 of the present technique.

FIG. 37 is a longitudinal cross-sectional view schematically illustrating Variation 7-8 on Embodiment 7 of the present technique.

FIG. 38 is a plan view schematically illustrating an example of the configuration of a semiconductor apparatus according to Embodiment 8 of the present technique.

FIG. 39 is a longitudinal cross-sectional view schematically illustrating a longitudinal cross-sectional structure along a line a38-a38 in FIG. 38.

FIG. 40 is a longitudinal cross-sectional view schematically illustrating a longitudinal cross-sectional structure along a line b38-b38 in FIG. 38.

FIG. 41 is a plan view schematically illustrating steps in a method for manufacturing a semiconductor apparatus according to Embodiment 8 of the present technique.

FIG. 42 is a longitudinal cross-sectional view schematically illustrating a longitudinal cross-sectional structure along a line a41-a41 in FIG. 41.

FIG. 43 is a longitudinal cross-sectional view schematically illustrating a longitudinal cross-sectional structure along a line b41-b41 in FIG. 41.

FIG. 44 is a plan view schematically illustrating steps continuing from FIG. 41.

FIG. 45 is a longitudinal cross-sectional view schematically illustrating a longitudinal cross-sectional structure along a line a44-a44 in FIG. 44.

FIG. 46 is a longitudinal cross-sectional view schematically illustrating a longitudinal cross-sectional structure along a line b44-b44 in FIG. 44.

FIG. 47 is a plan view schematically illustrating steps continuing from FIG. 44.

FIG. 48 is a longitudinal cross-sectional view schematically illustrating a longitudinal cross-sectional structure along a line b47-b47 in FIG. 47.

FIG. 49 is a plan view schematically illustrating steps continuing from FIG. 47.

FIG. 50 is a longitudinal cross-sectional view schematically illustrating a longitudinal cross-sectional structure along a line b49-b49 in FIG. 49.

FIG. 51 is a plan view schematically illustrating steps continuing from FIG. 49.

FIG. 52 is a longitudinal cross-sectional view schematically illustrating a longitudinal cross-sectional structure along a line b51-b51 in FIG. 51.

FIG. 53 is a plan view schematically illustrating steps continuing from FIG. 51.

FIG. 54 is a longitudinal cross-sectional view schematically illustrating a longitudinal cross-sectional structure along a line a53-a53 in FIG. 53.

FIG. 55 is a plan view schematically illustrating steps continuing from FIG. 53.

FIG. 56 is a longitudinal cross-sectional view schematically illustrating a longitudinal cross-sectional structure along a line a55-a55 in FIG. 55.

FIG. 57 is a longitudinal cross-sectional view schematically illustrating a longitudinal cross-sectional structure along a line b55-b55 in FIG. 55.

FIG. 58 is a plan view schematically illustrating steps continuing from FIG. 5.

FIG. 59 is a longitudinal cross-sectional view schematically illustrating a longitudinal cross-sectional structure along a line a58-a58 in FIG. 68.

FIG. 60 is a longitudinal cross-sectional view schematically illustrating a longitudinal cross-sectional structure along a line b58-b58 in FIG. 58.

FIG. 61 is a plan view schematically illustrating steps continuing from FIG. 58.

FIG. 62 is a longitudinal cross-sectional view schematically illustrating a longitudinal cross-sectional structure along a line a61-a61 in FIG. 61.

FIG. 63 is a longitudinal cross-sectional view schematically illustrating a longitudinal cross-sectional structure along a line b61-b61 in FIG. 61.

FIG. 64 is a plan view schematically illustrating steps continuing from FIG. 61.

FIG. 65 is a longitudinal cross-sectional view schematically illustrating a longitudinal cross-sectional structure along a line a64-a64 in FIG. 64.

FIG. 66 is a longitudinal cross-sectional view schematically illustrating a longitudinal cross-sectional structure along a line b64-b64 in FIG. 64.

FIG. 67 is a longitudinal cross-sectional view schematically illustrating steps continuing from FIG. 64.

FIG. 68 is a longitudinal cross-sectional view schematically illustrating the longitudinal cross-sectional structure of a comparative example.

FIG. 69 is a plan view schematically illustrating Variation 8-1 on Embodiment 8 of the present technique.

FIG. 70 is a longitudinal cross-sectional view schematically illustrating a longitudinal cross-sectional structure along a line a69-a69 in FIG. 69.

FIG. 71 is a plan view schematically illustrating Variation 8-2 on Embodiment 8 of the present technique.

FIG. 72 is a longitudinal cross-sectional view schematically illustrating the longitudinal cross-sectional structure of an example of the configuration of a semiconductor apparatus according to Embodiment 9 of the present technique.

FIG. 73 is a longitudinal cross-sectional view schematically illustrating steps in a method for manufacturing a semiconductor apparatus according to Embodiment 9 of the present technique.

FIG. 74 is a longitudinal cross sectional view schematically illustrating steps continuing from FIG. 73.

FIG. 75 is a longitudinal cross-sectional view schematically illustrating steps continuing from FIG. 74.

FIG. 76 is a longitudinal cross-sectional view schematically illustrating steps continuing from FIG. 75.

FIG. 77 is a longitudinal cross-sectional view schematically illustrating steps continuing from FIG. 76.

FIG. 78 is a longitudinal cross-sectional view schematically illustrating steps continuing from FIG. 77.

FIG. 79 is a longitudinal cross-sectional view schematically illustrating steps continuing from FIG. 78.

FIG. 80 is a plan view schematically illustrating an example of the configuration of a semiconductor apparatus according to Embodiment 10 of the present technique.

FIG. 81 is a longitudinal cross-sectional view schematically illustrating a longitudinal cross-sectional structure along a line b80-b80 in FIG. 80.

FIG. 82 is a longitudinal cross-sectional view schematically illustrating steps in a method for manufacturing a semiconductor apparatus according to Embodiment 10 of the present technique.

FIG. 83 is a longitudinal cross-sectional view schematically illustrating steps continuing from FIG. 82.

FIG. 84 is a longitudinal cross-sectional view schematically illustrating steps continuing from FIG. 83.

FIG. 85 is a longitudinal cross-sectional view schematically illustrating the longitudinal cross-sectional structure of an example of the configuration of a semiconductor apparatus according to Embodiment 11 of the present technique.

FIG. 86 is a longitudinal cross-sectional view schematically illustrating the longitudinal cross-sectional structure of an example of the configuration of a semiconductor apparatus according to Embodiment 12 of the present technique.

FIG. 87 is a plan layout view schematically illustrating an example of the configuration of a solid-state imaging device according to Embodiment 13 of the present technique.

FIG. 88 is a block diagram schematically illustrating an example of the configuration of the solid-state imaging device according to Embodiment 13 of the present technique.

FIG. 89 is an equivalent circuit diagram illustrating an example of the configuration of a pixel and a pixel circuit in the solid-state imaging device according to Embodiment 13 of the present technique.

FIG. 90 is a longitudinal cross-sectional view schematically illustrating the longitudinal cross-sectional structure of a pixel array unit of the solid-state imaging device according to Embodiment 13 of the present technique.

FIG. 91 is a diagram illustrating an example of the configuration of an electronic device according to Embodiment 14 of the present technique.

### DESCRIPTION OF EMBODIMENTS

Embodiments of the present technique will be described in detail hereinafter with reference to the drawings.

In the descriptions of the drawings referred to in the following descriptions, identical or similar parts will be given identical or similar reference signs.

However, it should be noted that the drawings are schematic, and the relationships between thicknesses and planar dimensions, the ratios of thicknesses of layers, and the like are different from the actual ratios, thicknesses, and the like. Therefore, specific thicknesses and dimensions should be determined in light of the following descriptions.

In addition, it goes without saying that the drawings also include parts having dimensional relationships and ratios different from those in other drawings.

Furthermore, the effects described herein are merely exemplary and not intended to be limiting, and other effects may be provided as well.

The following embodiments exemplify devices, methods, and the like for embodying the technical spirit of the present technique, and the configurations are not limited to those described below. In other words, the technical spirit of the present technique can be modified in various ways within the technical scope set forth in the claims.

In addition, it is to be understood that definitions of directions such as “up-down” in the following descriptions are merely definitions provided for the sake of brevity and are not intended to limit the technical spirit of the present technique. For example, it is obvious that when an object is observed after being rotated by 90 degrees, “up-down” is transformed into and interpreted as “left right”, and when an object is observed after being rotated by 180 degrees, “up-down” is interpreted as being inverted.

Furthermore, in the following embodiments, in the three directions orthogonal to each other in a space, a first direction and a second direction orthogonal to each other in the same plane are defined as an X direction and a Y direction, respectively, and a third direction orthogonal to both the first direction and the second direction is defined as a Z direction. Furthermore, in the following embodiments, a thickness direction of a semiconductor layer 2 (described later) will be defined as being the Z direction.

Additionally, in the following embodiments, the “thickness” of a semiconductor layer is the separation distance between a first face and a second face located on opposite sides from each other in the Z direction, and the “thickness direction” of the semiconductor layer is a direction representing the thickness of the semiconductor layer.

Furthermore, in the following embodiments, “plan view” refers to a case where a semiconductor layer is viewed from (one direction in) the Z direction. “Cross-sectional view” refers to a case where a cross-section along (one direction in) the Z direction is viewed from a direction orthogonal to that cross-section (the Z direction).

### Embodiment 1

Embodiment 1 will describe an example in which the present technique is applied in a semiconductor apparatus 1A having an n-channel conductivity type field effect transistor Q1 provided in a semiconductor part 5 having a three-dimensional shape.

### <<Overall Configuration of Semiconductor Apparatus>>

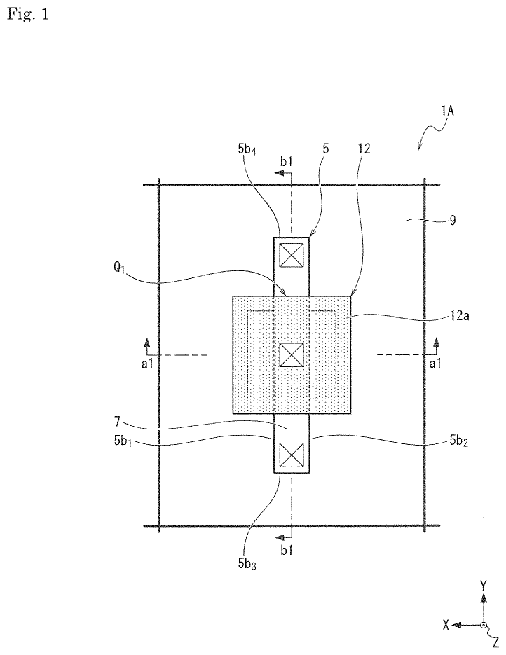

The overall configuration of the semiconductor apparatus 1A will be described first with reference to FIGS. 1 to 3.

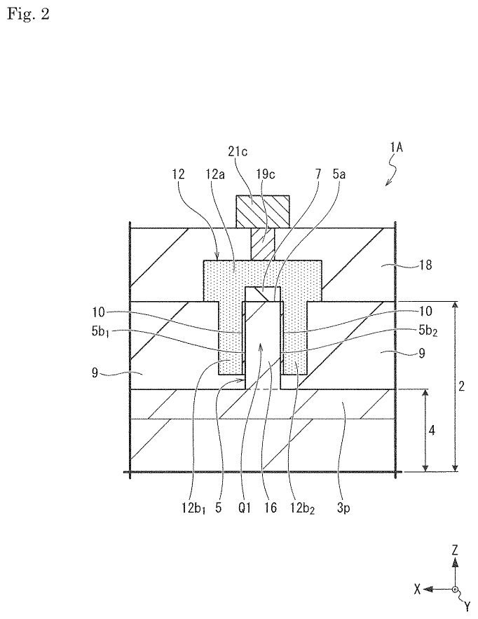

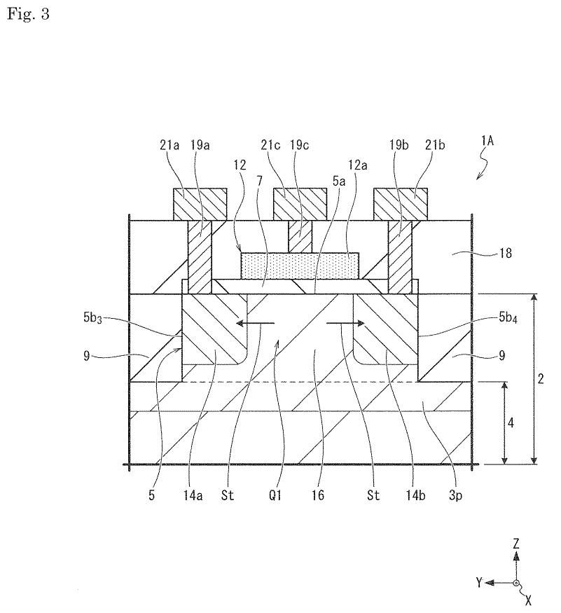

For the sake of simplicity, FIG. 1 does not illustrate an insulating layer 18, contact electrodes (19a, 19b, 19c), and interconnects (21a, 21b, 21c), which are illustrated in FIGS. 2 and 3.

As illustrated in FIGS. 1 to 3, the semiconductor apparatus 1A according to Embodiment 1 of the present technique includes the semiconductor layer 2 and the field effect transistor Q1 mounted on the semiconductor layer 2.

The semiconductor apparatus 1A according to Embodiment 1 of the present technique further includes a stress part (a stress-inducing part) 7, which is provided between an upper face 5a of the semiconductor part 5 and a gate electrode 12, and which produces (induces) stress in the semiconductor part 5 in a direction in which current flowing in the semiconductor part 5 increases.

### <Semiconductor Layer>

As illustrated in FIGS. 1 to 3, the semiconductor layer 2 includes a base part 4 extending two-dimensionally in the X direction and the Y direction, and the semiconductor part 5, which has a three-dimensional shape and protrudes upward (in the Z direction) from the base part 4. Although not limited thereto, the semiconductor part 5 is configured having a cuboid shape integrated with the base part 4, for example, and includes the upper face 5a and four side faces 5b₁, 5b₂, 5b₃, and 5b₄. The semiconductor part 5 extends such that the lengthwise direction is the Y direction in plan view.

In the semiconductor part 5, of the four side faces 5b₁, 5b₂, 5b₃, and 5b₄, the two side faces 5b₁ and 5b₂ are located opposite to each other in the widthwise direction of the semiconductor part 5 (the X direction). The remaining two side faces 5b₃ and 5b₄ are located opposite to each other in the lengthwise direction of the semiconductor part 5 (the Y direction). The upper face 5a is located on the side of the semiconductor part 5 opposite from the side where the base part 4 is located, in the thickness direction of the semiconductor layer 2 (the Z direction).

The semiconductor part 5 can be formed by selectively etching the semiconductor layer 2 to a depth at which the base part 4 remains. Although not limited thereto, the semiconductor layer 2 uses a semiconductor substrate that, for example, takes silicon (Si) as the semiconductor material, a single crystal as the crystal, and p-type as the conductivity type. Aside from Si, a semiconductor substrate such as germanium (Ge), silicon germanium (SiGe), gallium arsenide (GaAs), indium phosphorus (InP), or the like can also be used for the semiconductor layer 2.

As illustrated in FIGS. 2 and 3, a p-type well region 3p constituted by a p-type semiconductor region, for example, is provided in the semiconductor layer 2.

The p-type well region 3p is provided throughout the entire region of the semiconductor part 5, and is provided in a surface layer part on the side of the base part 4 where the semiconductor part 5 is located. The p-type well region 3p is separated from a back face of the base part 4 opposite from the side where the semiconductor part 5 is located.

The base part 4 supports the semiconductor part 5 on the side of the semiconductor part 5 opposite from the side where the upper face 5a is located.

### <Insulating Layer>

As illustrated in FIGS. 2 and 3, an insulating layer 9 is provided on the semiconductor part 5 side of the base part 4 so as to surround the semiconductor part 5. The surface layer part of the insulating layer 9 is flattened on the side opposite from the side where the base part 4 is located, and is formed at a film thickness approximately equal to the height to which the semiconductor part 5 protrudes from the base part 4 (a protrusion amount). The insulating layer 9 is constituted by a silicon oxide (SiO₂) film, for example.

The insulating layer 18 is provided on the upper face of the insulating layer 9, on the side opposite from the side where the base part 4 is located, covering a tip part 12a of the gate electrode 12, which will be described later. The insulating layer 18 is also constituted by a silicon oxide (SiO₂) film, for example.

Interconnects 21a, 21b, and 21c included in an interconnect layer as a first layer are provided on the upper face of the insulating layer 18 on the side opposite from the side where the insulating layer 9 is located. Each of the interconnects 21a, 21b, and 21c in the interconnect layer is constituted by a metal film such as aluminum (Al) film, copper (Cu) film, or the like, or an alloy film that takes Cu as its main component, for example.

### <Field Effect Transistor>

Although not limited thereto, the field effect transistor Q1 illustrated in FIGS. 1 to 3 is formed having n-type channel conductivity, for example. The field effect transistor Q1 is constituted by a Metal Oxide Semiconductor Field Effect Transistor (MOSFET) using a silicon oxide film as a gate insulating film. A Metal Insulator Semiconductor Field Effect Transistor (MISFET) using a silicon nitride film or a layered film (composite film) including a silicon nitride film and a silicon oxide film as a gate insulating film may be used as the field effect transistor Q1.

As illustrated in FIGS. 1 to 3, the field effect transistor Q1 is provided in the semiconductor part 5. The field effect transistor Q1 is used as a circuit element for constructing a predetermined circuit.

The field effect transistor Q1 has a channel forming part 16 provided in the semiconductor part 5; the gate electrode 12, which is provided across the upper face 5a and the two side faces 5b₁ and 5b₂ of the semiconductor part 5 in a widthwise direction (the X direction) intersecting the lengthwise direction of the semiconductor part 5 (a gate length direction of the gate electrode 12; the Y direction); and a gate insulating film 10 provided between the semiconductor part 5 and the gate electrode 12.

The field effect transistor Q1 further has a pair of main electrode regions 14a and 14b individually provided in each semiconductor part 5 on respective sides in the gate length direction of the gate electrode 12 (the Y direction).

The pair of main electrode regions 14a and 14b function as a source region and a drain region. The pair of main electrode regions 14a and 14b are constituted by n-type semiconductor regions formed by selectively introducing n type impurities into the semiconductor part 5, for example. The pair of main electrode regions 14a and 14b are arranged in a row on respective sides of the channel forming part 16 in the gate length direction of the gate electrode 12 (the Y direction).

The field effect transistor Q1 is formed having a fin shape in which the gate electrode 12 is provided in the semiconductor part 5 having a three-dimensional shape, with the gate insulating film 10 interposed therebetween. The field effect transistor Q1 can be configured in, for example, enhancement mode (normally-off mode) in which a drain current flows in response to the application of a gate voltage greater than or equal to a threshold voltage to the gate electrode 12. The field effect transistor Q1 can also be configured in depletion mode (normally-off mode) in which a drain current flows even when no voltage is applied to the gate electrode 12. Although not limited thereto, enhancement mode is used in Embodiment 1, for example. In enhancement mode, in the field effect transistor Q1, a channel that electrically connects the pair of main electrode regions 14a and 14b (an inverting layer) is formed (induced) in the channel forming part 16 by a voltage applied to the gate electrode 12, and a current (a drain current Id) flows from the drain region side (e.g., the one main electrode region 14a side) toward the source region side (e.g., the other main electrode region 14b side) through the channel in the channel forming part 16.

### <Gate Electrode and Gate Insulating Film>

Although not limited thereto, as illustrated in FIGS. 1 to 3, the gate electrode 12 includes, for example, a tip part (first part) 12a provided on the upper face 5a side of the semiconductor part 5 over the stress part 7, which will be described later; and two leg parts (second parts) 12b₁ and 12b₂ which are formed integrally with the tip part 12a, and which are provided on outer sides of corresponding ones of the two side faces 5b₁ and 5b₂ located on opposite sides from each other in the widthwise direction of the semiconductor part 5 (the X direction) over the gate insulating film 10. In other words, the gate electrode 12 is provided across the upper face 5a and the two side faces 5b₁ and 5b₂ of the semiconductor part 5. The gate electrode 12 has a C-shape in which the longitudinal cross-sectional shape follows the X direction. The gate electrode 12 is constituted by a polycrystal silicon film into which impurities that reduce the resistance value have been introduced, for example.

Each of the two leg parts 12b₁ and 12b₂ is embedded in the insulating layer 9. The tip part 12a protrudes above the insulating layer 9 from the insulating layer 9.

The gate insulating film 10 is provided in each of the two side faces 5b₁ and 5b₂ of the semiconductor part 5, between the semiconductor part 5 and the gate electrode 12. The gate insulating film 10 is constituted by a silicon oxide film, for example. As will be described later, in Embodiment 1, the stress part 7 is provided on the upper face 5a of the semiconductor part 5, and thus the gate insulating film 10 is not provided in the upper face 5a of the semiconductor part 5.

### <Contact Electrodes and Interconnects>

As illustrated in FIGS. 2 and 3, in the field effect transistor Q1, the gate electrode 12 is electrically connected to an interconnect 21c on the insulating layer 18 through a contact electrode 19c provided in the insulating layer 18. As illustrated in FIG. 3, of the pair of main electrode regions 14a and 14b, the one main electrode region 14a is electrically connected to an interconnect 21a on the insulating layer 18 through a contact electrode 19a provided in the insulating layer 18. Of the pair of main electrode regions 14a and 14b, the other main electrode region 14b is electrically connected to an interconnect 21b on the insulating layer 18 through a contact electrode 19b provided in the insulating layer 18.

A high melting point metal film such as titanium (Ti), tungsten (W), or the like can be used as the material of the contact electrodes 19a, 19b, and 19c, for example.

### <Stress Part>

As illustrated in FIGS. 1 to 3, the stress part 7 is provided between the upper face 5a of the semiconductor part 5 and the gate electrode 12. The stress part 7 is a stress-inducing part that produces (induces) stress in the semiconductor part 5 in a direction in which current flowing in the semiconductor part 5 increases. In other words, the stress part 7 produces (induces) stress in the semiconductor part 5 in a direction in which current (the drain current Id) flowing from one to the other of the pair of main electrode regions 14a and 14b through the channel forming part 16 increases. To rephrase again, the stress part 7 produces (induces) stress in the semiconductor part 5 in a direction in which the mobility of carriers moving from one to the other of the pair of main electrode regions 14a and 14b through the channel forming part 16 increases.

Although not limited thereto, in the upper face 5a of the semiconductor part 5, the stress part 7 in Embodiment 1 extends to both ends of the semiconductor part 5 in the lengthwise direction (the Y direction) (i.e., to one and the other sides of the semiconductor part 5 on which the side faces 5b₃ and 5b₄ are located), at a width that is generally the same as the width of the semiconductor part 5 in the widthwise direction (the X direction). In other words, the stress part 7 is provided in the upper face 5a of the semiconductor part 5, across both the inside and outside the gate electrode 12 in plan view.

A silicon nitride (SiN) film that can be formed through plasma CVD can be used as the stress part 7, for example. With a silicon nitride film, the thermal expansion coefficient can be controlled by changing the conditions under which the silicon nitride film serving as the stress part 7, the semiconductor part 5, and the like contract by returning from high temperature to normal temperature during the manufacturing process. Accordingly, when the stress part 7 is provided on the upper face 5a of the semiconductor part 5, making the thermal expansion coefficient of the silicon nitride film serving as the stress part 7 smaller (lower) than the thermal expansion coefficient of the semiconductor part 5 makes it possible to produce tensile stress St in the semiconductor part 5 in the gate length direction of the gate electrode 12 (the lengthwise direction of the semiconductor part 5; the Y direction), i.e., in the direction in which the pair of main electrode regions 14a and 14b are arranged (the lengthwise direction of the semiconductor part 5; the Y direction), as illustrated in FIG. 3. In this case, the stress part 7 provided on the upper face 5a of the semiconductor part 5 has an inherent tensile stress.

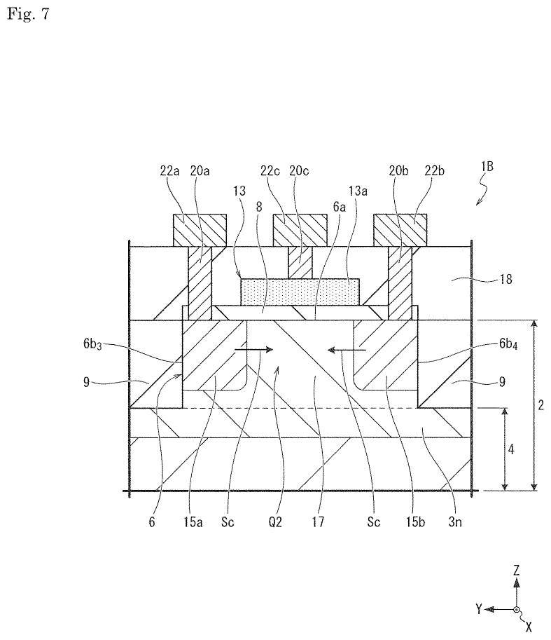

When the stress part 7 is provided on the upper face 5a of the semiconductor part 5, making the thermal expansion coefficient of the silicon nitride film serving as the stress part 7 larger (higher) than the thermal expansion coefficient of the semiconductor part 5 makes it possible to produce compressive stress Sc in the semiconductor part 5 in the gate length direction of the gate electrode 12 (the direction in which the pair of main electrode regions 14a and 14b are arranged), as illustrated in FIG. 7 of Embodiment 2, which will be described later. In this case, the stress part 7 provided on the upper face 5a of the semiconductor part 5 has an inherent compressive stress.

The stress part 7 of Embodiment 1 is constituted by a silicon nitride film having a smaller thermal expansion coefficient than that of the silicon of the semiconductor part 5. Silicon has a thermal expansion coefficient of about 3.9×10⁻⁶/K, for example.

Here, referring to FIGS. 1 to 3 of Embodiment 1, it is known that in an n-channel conductivity type MOSFET, when a tensile stress St (see FIG. 3) acting in the lengthwise direction of the semiconductor part 5 (the Y direction), which is the direction in which the source region and the drain region are arranged (the gate length direction of the gate electrode), is imparted on the semiconductor part 5, or when a tensile stress acting in the widthwise direction of the semiconductor part 5 (the X direction), which is a direction intersecting with the direction in which the source region and the drain region are arranged (the Y direction) (i.e., the gate width direction of the gate electrode 12) in plan view, is imparted on the increases.

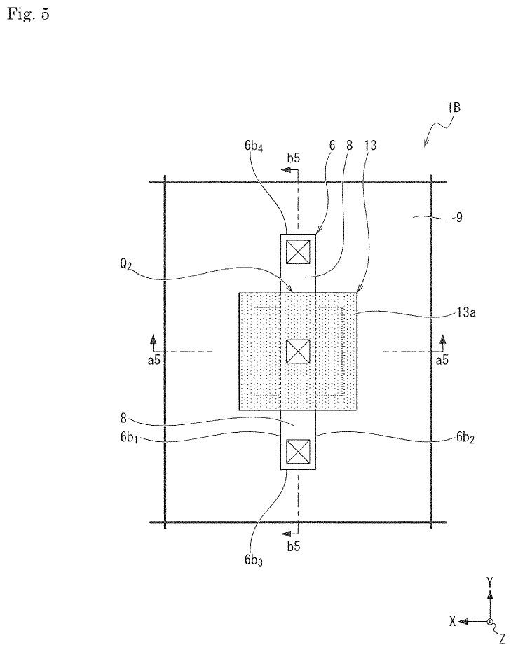

On the other hand, referring to FIGS. 5 to 7 of Embodiment 2, which will be described later, it is known that in a p-channel conductivity type MOSFET, when a compressive stress Sc (see FIG. 7) acting in the lengthwise direction of the semiconductor part 5 (the Y direction) is imparted on the semiconductor part 5, or when a tensile stress acting in the widthwise direction of the semiconductor part 5 (the X direction) is applied to the semiconductor part 5, the carrier mobility improves and the drain current (Id) increases.

Accordingly, because the field effect transistor Q1 according to Embodiment 1 is formed having the n-channel conductivity type, providing the stress part 7, which produces the tensile stress St in the semiconductor part 5 in the gate length direction of the gate electrode 12 (the Y direction), on the upper face 5a of the semiconductor part 5 can improve the mobility of carriers moving in the semiconductor part 5, and can increase the current (the drain current Id) flowing from one to the other of the pair of main electrode regions 14a and 14b through the channel forming part 16. In other words, the field effect transistor Q1 according to Embodiment 1 is of the n-channel conductivity type, and the stress produced by the stress part 7 in the semiconductor part 5 is tensile stress.

When the stress part 7 is provided on the upper face 5a of the semiconductor part 5, tensile stress is also produced in the widthwise direction of the semiconductor part 5 (the X direction).

It is preferable that the stress part 7 have a smaller thermal expansion coefficient than the gate insulating film 10. It is also preferable that the stress part 7 be thicker than the gate insulating film 10.

In Embodiment 1, the semiconductor part 5 and the stress part 7 provided on the upper face 5a of the semiconductor part 5 each have inherent tensile stress. In addition, in Embodiment 1, the stress part 7 is provided across both ends of the semiconductor part 5 in the lengthwise direction (the side face 5b₃ side and the side face 5b₄ side of the semiconductor part 5), and thus each of the contact electrodes 19a and 19b reaches the semiconductor part 5 via the insulating layer 18 and the stress part 7.

### <<Main Effects of Embodiment 1>>

The main effects of Embodiment 1 will be described next.

The semiconductor apparatus 1A according to Embodiment 1 includes the n-channel conductivity type field effect transistor Q1, which has the gate electrode 12 provided across the upper face 5a and the side faces 5b₁ and 5b₂ of the semiconductor part 5; and the stress part 7, which is provided between the upper face 5a of the semiconductor part 5 and the gate electrode 12, and which produces stress in the semiconductor part 5 in a direction in which the current flowing in the semiconductor part 5 (the drain current Id) increases.

Accordingly, the mobility of carriers moving in the semiconductor part 5 can be improved, and the current (the drain current Id) flowing from one to the other of the pair of main electrode regions 14a and 14b through the channel forming part 16 can be increased. Therefore, the semiconductor apparatus 1A according to Embodiment 1 makes it possible to improve the mutual conductance (gm) of the n-channel conductivity type field effect transistor Q1.

In addition, because the mutual conductance (gm) of the field effect transistor Q1 can be improved, the circuit including the field effect transistor Q1 can be made faster, and the semiconductor apparatus 1A can therefore be made faster.

Additionally, the stress part 7 is provided in the upper face 5a of the semiconductor part 5, across both the inside and outside the gate electrode 12 in plan view. Accordingly, the stress produced in the semiconductor part 5 (the stress in the direction in which the current flowing in the semiconductor part 5 (the drain current Id) increases) can be increased compared to when the stress part 7 is selectively provided between the upper face 5a of the semiconductor part 5 and the gate electrode 12.

### <<Variation on Embodiment 1>>

### <Variation 1-1>

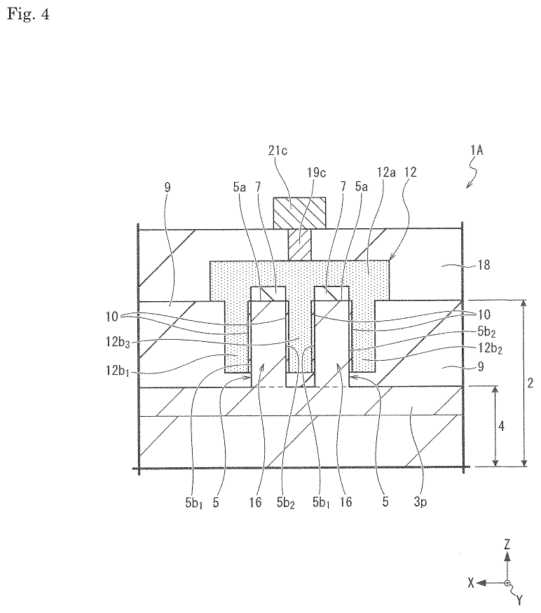

The foregoing Embodiment 1 described the gate electrode 12 as including the tip part 12a and the two leg parts 12b₁ and 12b₂. However, the gate electrode 12 is not limited to the two leg parts 12b₁ and 12b₂. For example, as illustrated in FIG. 4, the gate electrode 12 may include three leg parts 12b₁, 12b₂, and 12b₃.

Furthermore, although not illustrated, the gate electrode 12 may include four or more leg parts. In this case, when the number of leg parts of the gate electrode 12 is n, the number of semiconductor parts 5 is “n-1”. The present technique can be applied in such a case as well.

### Embodiment 2

Embodiment 2 will describe an example in which the present technique is applied in a semiconductor apparatus 1B having a p-channel conductivity type field effect transistor Q2 provided in a semiconductor part 6 having a three-dimensional shape, with reference to FIGS. 5 to 7.

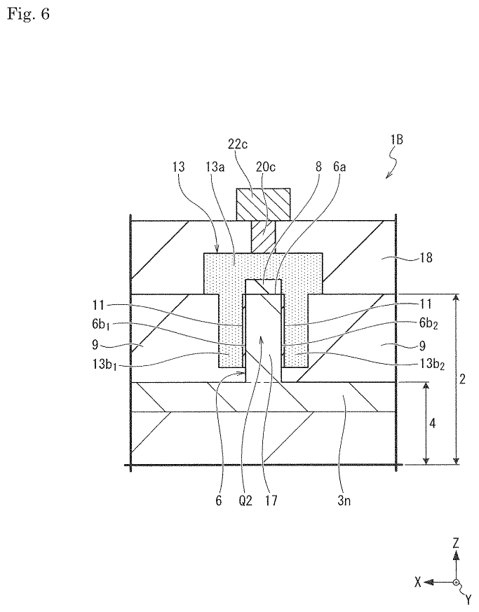

For the sake of simplicity, FIG. 5 does not illustrate the insulating layer 18, contact electrodes (20a, 20b, 20c), and interconnects (22a, 22b, 22c), which are illustrated in FIGS. 6 and 7.

### <<Overall Configuration of Semiconductor Apparatus>>

As illustrated in FIGS. 5 to 7, the semiconductor apparatus 1B according to Embodiment 2 of the present technique has basically the same configuration as the semiconductor apparatus 1A according to the foregoing Embodiment 1, with the exception of the following configurations.

As illustrated in FIGS. 5 to 7, the semiconductor apparatus 1B according to Embodiment 2 includes the field effect transistor Q2 and a stress part 8 instead of the field effect transistor Q1 and the stress part 7 illustrated in FIGS. 1 to 3 and described above in Embodiment 1. The other configurations are generally the same as those in Embodiment 1.

### <Semiconductor Layer>

As illustrated in FIGS. 5 to 7, the semiconductor layer 2 includes the base part 4 extending two-dimensionally in the X direction and the Y direction, and the semiconductor part 6, which has a three-dimensional shape and protrudes upward (in the Z direction) from the base part 4. Although not limited thereto, like the semiconductor part 5 described above, the semiconductor part 6 is configured having a cuboid shape integrated with the base part 4, for example, and includes an upper face 6a and four side faces 6b₁, 6b₂, 6b₃, and 6b₄. The semiconductor part 6 extends such that the lengthwise direction is the Y direction in plan view.

In the semiconductor part 6, of the four side faces 6b₁, 6b₂, 6b₃, and 6b₄, the two side faces 6b₁ and 6b₂ are located opposite to each other in the widthwise direction of the semiconductor part 6 (the X direction). The remaining two side faces 6b₃ and 6b₄ are located opposite to each other in the lengthwise direction of the semiconductor part 6 (the Y direction). The upper face 6a is located on the side of the semiconductor part 6 opposite from the side where the base part 4 is located, in the thickness direction of the semiconductor layer 2 (the Z direction).

Like the semiconductor part 5 of the foregoing Embodiment 1, the semiconductor part 6 can be formed by selectively etching the semiconductor layer 2 to a depth at which the base part 4 remains. Accordingly, the semiconductor part 6 can be formed through the same process as the semiconductor part 5 of the foregoing Embodiment 1. Although not limited thereto, the semiconductor layer 2 uses a semiconductor substrate that, for example, takes silicon (Si) as the semiconductor material, a single crystal as the crystal, and p-type as the conductivity type.

As illustrated in FIGS. 6 and 7, an n type well region 3n constituted by an n-type semiconductor region, for example, is provided in the semiconductor layer 2.

The n-type well region 3n is provided throughout the entire region of the semiconductor part 6, and is provided in a surface layer part on the side of the base part 4 where the semiconductor part 6 is located. The n-type well region 3n is separated from a back face of the base part 4 opposite from the side where the semiconductor part 6 is located.

The base part 4 supports the semiconductor part 6 on the side of the semiconductor part 6 opposite from the side where the upper face 6a is located.

### <Insulating Layer>

As illustrated in FIGS. 6 and 7, the insulating layer 9 is provided on the semiconductor part 6 side of the base part 4 so as to surround the semiconductor part 6. The upper face of the insulating layer 9 is flattened on the side opposite from the side where the base part 4 is located, and is formed at a film thickness approximately equal to the height to which the semiconductor part 6 protrudes from the base part 4 (a protrusion amount).

The insulating layer 18 is provided on the upper face of the insulating layer 9, on the side opposite from the side where the base part 4 is located, covering a tip part 13a of a gate electrode 13, which will be described later. Interconnects 22a, 22b, and 22c included in an interconnect layer as a first layer are provided on the upper face of the insulating layer 18 on the side opposite from the side where the insulating layer 9 is located.

### <Field Effect Transistor>

Although not limited thereto, the field effect transistor Q2 illustrated in FIGS. 5 to 7 is formed having p-type channel conductivity, for example. The field effect transistor Q2 is constituted by a MOSFET using a silicon oxide film as a gate insulating film. A MISFET can also be used as the field effect transistor Q2.

As illustrated in FIGS. 5 to 7, the field effect transistor Q2 is provided in the semiconductor part 6. The field effect transistor Q2 is used as a circuit element for constructing a predetermined circuit.

The field effect transistor Q2 has a channel forming part 17 provided in the semiconductor part 6; the gate electrode 13, which is provided across the upper face 6a and the two side faces 6b₁ and 6b₂ of the semiconductor part 6 in a widthwise direction (the X direction) intersecting the lengthwise direction of the semiconductor part 6 (the Y direction); and a gate insulating film 11 provided between the semiconductor part 6 and the gate electrode 13.

The field effect transistor Q2 further has a pair of main electrode regions 15a and 15b individually provided in each semiconductor part 6 on respective sides in the gate length direction of the gate electrode 13 (the lengthwise direction of the semiconductor part 6).

The pair of main electrode regions 15a and 15b function as a source region and a drain region. The pair of main electrode regions 15a and 15b are constituted by p-type semiconductor regions formed by selectively introducing p-type impurities into the semiconductor part 6, for example. The pair of main electrode regions 15a and 15b are arranged in a row on respective sides of the channel forming part 17 in the gate length direction of the gate electrode 13 (the Y direction). This field effect transistor Q2 is formed having a fin shape in which the gate electrode 13 is provided in the semiconductor part 6 having a three-dimensional shape, with the gate insulating film 11 interposed therebetween.

The field effect transistor Q2 can be configured in an enhancement mode (normally-off mode) or a depletion mode (normally-off mode), for example. Although not limited thereto, enhancement mode is used in Embodiment 2, for example. In enhancement mode, in the field effect transistor Q2, a channel that electrically connects the pair of main electrode regions 15a and 15b (an inverting layer) is formed (induced) in the channel forming part 17 by a voltage applied to the gate electrode 13, and a current (the drain current Id) flows from the drain region side (e.g., the one main electrode region 15a side) toward the source region side (e.g., the other main electrode region 15b side) through the channel in the channel forming part 17.

### <Gate Electrode and Gate Insulating Film>

Although not limited thereto, as illustrated in FIGS. 5 to 7, the gate electrode 13 includes, for example, a tip part (first part) 13a provided on the upper face 6a side of the semiconductor part 6 over the stress part 8, which will be described later; and two leg parts (second parts) 13b₁ and 13b₂ which are formed integrally with the tip part 13a, and which are provided on outer sides of corresponding ones of the two side faces 6b₁ and 6b₂ located on opposite sides from each other in the X direction of the semiconductor part 6 over the gate insulating film 11. In other words, the gate electrode 13 is provided across the upper face 6a and the two side faces 6b₁ and 6b₂ of the semiconductor part 6. The gate electrode 13 has a C-shape in which the longitudinal cross-sectional shape follows the X direction. The gate electrode 13 is constituted by a polycrystal silicon film into which impurities that reduce the resistance value have been introduced, for example.

Each of the two leg parts 13b₁ and 13b₂ is embedded in the insulating layer 9. The tip part 13a protrudes above the insulating layer 9 from the insulating layer 9.

The gate insulating film 11 is provided in each of the two side faces 6b₁ and 6b₂ of the semiconductor part 6, between the semiconductor part 6 and the gate electrode 13. The gate insulating film 11 is constituted by a silicon oxide film, for example. As will be described later, in Embodiment 2 as well, the stress part 8 is provided on the upper face 6a of the semiconductor part 6, and thus the gate insulating film 11 is not provided on the upper face 6a of the semiconductor part 6.

### <Contact Electrodes and Interconnects>

As illustrated in FIGS. 6 and 7, in the field effect transistor Q2, the gate electrode 13 is electrically connected to an interconnect 22c on the insulating layer 18 through a contact electrode 20c provided in the insulating layer 18. As illustrated in FIG. 7, of the pair of main electrode regions 15a and 15b, the one main electrode region 15a is electrically connected to an interconnect 22a on the insulating layer 18 through a contact electrode 20a provided in the insulating layer 18. Of the pair of main electrode regions 14a and 14b, the other main electrode region 15b is electrically connected to an interconnect 22b on the insulating layer 18 through a contact electrode 20b provided in the insulating layer 18. A high melting point metal film such as titanium (Ti), tungsten (W), or the like can be used as the material of the contact electrodes 20a, 20b, and 20c, for example.

### <Stress Part>

As illustrated in FIGS. 5 to 7, the semiconductor apparatus 1B according to Embodiment 2 of the present technique further includes the stress part 8, which is provided between the upper face 6a of the semiconductor part 6 and the gate electrode 13, and which produces (induces) stress in the semiconductor part 6 in a direction in which current flowing in the semiconductor part 6 increases. In other words, the stress part 8 produces (induces) stress in the semiconductor part 6 in a direction in which current (the drain current Id) flowing from one to the other of the pair of main electrode regions 15a and 15b through the channel forming part 17 increases. To rephrase again, the stress part 8 produces (induces) stress in the semiconductor part 6 in a direction in which the mobility of carriers moving from one to the other of the pair of main electrode regions 15a and 15b through the channel forming part 17 increases.

Although not limited thereto, in the upper face 6a of the semiconductor part 6, the stress part 8 in Embodiment 2 extends to both ends of the semiconductor part 6 in the lengthwise direction (the Y direction) (i.e., to the one side and the other side of the semiconductor part 6 on which the side faces 6b₃ and 6b₄ are located), at a width that is generally the same as the width of the semiconductor part 6 in the widthwise direction (the X direction), in the same manner as the stress part 7 of the foregoing Embodiment 1.

A silicon nitride (SiN) film that can be formed through plasma CVD can be used as the stress part 8, for example. As described above, with a silicon nitride film, the coefficient of thermal expansion can be controlled by changing the conditions under which the film is formed (the reaction gas, pressure, temperature, high-frequency power, and the like).

The silicon nitride film serving as the stress part 8, the semiconductor part 6, and the like contract by returning from high temperature to normal temperature during the manufacturing process. Accordingly, when the stress part 8 is provided on the upper face 6a of the semiconductor part 6, making the thermal expansion coefficient of the silicon nitride film serving as the stress part 8 larger (higher) than the thermal expansion coefficient of the semiconductor part 6 makes it possible to produce compressive stress Sc in the semiconductor part 6 in the gate length direction of the gate electrode 13 (the lengthwise direction of the semiconductor part 6; the Y direction), i.e., in the direction in which the pair of main electrode regions 15a and 15b are arranged (the lengthwise direction of the semiconductor part 6; the Y direction), as illustrated in FIG. 7. In this case, the stress part 8 provided on the upper face 6a of the semiconductor part 6 has an inherent compressive stress.

Additionally, when the stress part 8 is provided on the upper face 6a of the semiconductor part 6, making the thermal expansion coefficient of the silicon nitride film serving as the stress part 8 smaller (lower) than the thermal expansion coefficient of the semiconductor part 6 makes it possible to produce tensile stress in the semiconductor part 6 in the gate length direction of the gate electrode 13 (the direction in which the pair of main electrode regions 15a and 15b are arranged). In this case, the stress part 8 provided on the upper face 6a of the semiconductor part 6 has an inherent tensile stress.

The stress part 8 of Embodiment 2 is constituted by a silicon nitride film having a greater thermal expansion coefficient than that of the silicon of the semiconductor part 6.

Referring to FIGS. 5 to 7 of Embodiment 2, as described above, it is known that in a p-channel conductivity type MOSFET, when a compressive stress acting in the lengthwise direction of the semiconductor part 6 (the Y direction) is applied to the semiconductor part 6, or when a tensile stress is applied in the widthwise direction of the semiconductor part 6 (the X direction), the carrier mobility improves and the drain current (Id) increases.

Accordingly, because the field effect transistor Q2 according to Embodiment 2 is formed having the p-channel conductivity type, providing the stress part 8, which produces the compressive stress Sc in the semiconductor part 6, in the upper face 6a of the semiconductor part 6, acting in the gate length direction of the gate electrode 13 (the direction in which the pair of main electrode regions 15a and 15b are arranged; the Y direction), can improve the carrier mobility, and increase the current (the drain current Id) flowing from one to the other of the pair of main electrode regions 15a and 15b through the channel forming part 17. In other words, the field effect transistor Q2 according to Embodiment 1 is of the p-channel conductivity type, and the stress produced by the stress part 8 in the semiconductor part 6 is compressive stress.

Although not illustrated, when the stress part 8 is provided on the upper face of the semiconductor part 6, compressive stress Sc is also produced in the widthwise direction of the semiconductor part 6 (the X direction). The compressive stress Sc in the X direction is known to reduce carrier mobility in p-type MOSFETs.

However, because the semiconductor part 6 is formed having a cuboid shape, the compressive stress in the Y direction is stronger than the compressive stress in the X direction, and as a result, the current (the drain current Id) flowing from one to the other of the pair of main electrode regions 15a and 15b through the channel forming part 17 can be increased.

It is more preferable to use a film having a greater thermal expansion coefficient than the gate insulating film 11 as the stress part 8.

In addition, in Embodiment 2, the stress part 8 is provided across both ends of the semiconductor part 6 in the lengthwise direction (the side face 6b₃ side and the side face 6b₄ side of the semiconductor part 6), and thus each of the contact electrodes 20a and 20b reaches the semiconductor part 6 via the insulating layer 18 and the stress part 8.

In addition, in Embodiment 2, the semiconductor part 6 and the stress part 8 provided on the upper face 6a of the semiconductor part 6 each has inherent compressive stress.

### <<Main Effects of Embodiment 2>>

The semiconductor apparatus 1B according to Embodiment 2 includes the p-channel conductivity type field effect transistor Q2, which has the gate electrode 13 provided across the upper face 6a and the side faces 6b₁ and 6b₂ of the semiconductor part 6; and the stress part 8, which is provided between the upper face 6a of the semiconductor part 6 and the gate electrode 13, and which produces stress in the semiconductor part 6 in a direction in which the current flowing in the semiconductor part 6 (the drain current Id) increases.

Accordingly, the mobility of carriers moving in the semiconductor part 6 can be improved, and the current (the drain current Id) flowing from one to the other of the pair of main electrode regions 15a and 15b through the channel forming part 17 can be increased. Therefore, the semiconductor apparatus 1B according to Embodiment 2 makes it possible to improve the mutual conductance (gm) of the p-channel conductivity type field effect transistor Q2.

In addition, because the mutual conductance of the field effect transistor Q2 can be improved, the circuit including the field effect transistor Q2 can be made faster, and the semiconductor apparatus 1B can therefore be made faster.

Additionally, the stress part 8 is provided in the upper face 6a of the semiconductor part 6, across both the inside and outside the gate electrode 13 in plan view. Accordingly, the stress produced in the semiconductor part 6 (the stress in the direction in which the current flowing in the semiconductor part 5 (the drain current Id) increases) can be increased compared to when the stress part 8 is selectively provided between the upper face 6a of the semiconductor part 6 and the gate electrode 13.

The foregoing Embodiment 2 described the gate electrode 13 as including the tip part 13a and the two leg parts 13b₁ and 13b₂. However, the number of leg parts of the gate electrode 13 is not limited to two, as with the gate electrode 12 of the foregoing Embodiment 1. For example, although not illustrated, the gate electrode 13 may include three leg parts. Furthermore, the gate electrode 13 may include four or more leg parts. In this case, when the number of leg parts of the gate electrode 13 is n, the number of semiconductor parts 6 is “n-1”. The present technique can be applied in such a case as well.

### Embodiment 3

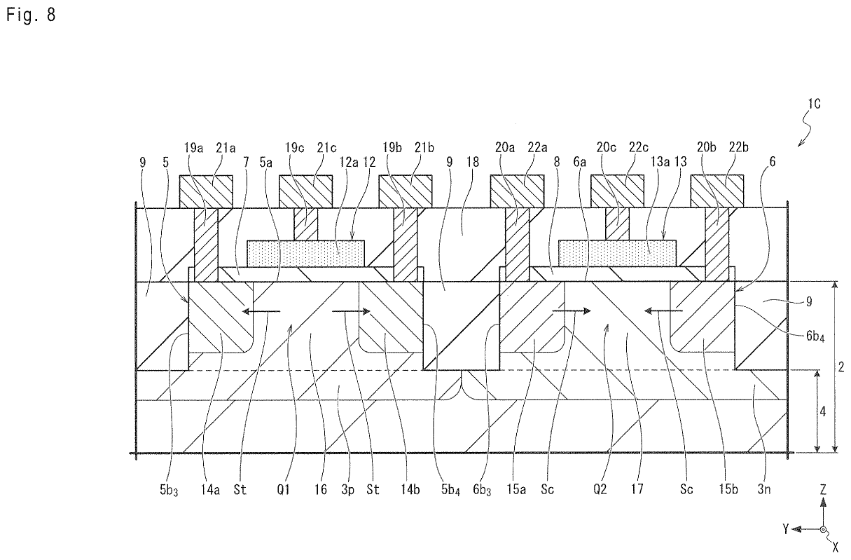

Referring to FIG. 8, Embodiment 3 will describe an example in which the present technique is applied in a semiconductor apparatus 1C having an n-channel conductivity type field effect transistor Q1 provided in a semiconductor part 5 having a three-dimensional shape and a p-channel conductivity type field effect transistor Q2 provided in a semiconductor part 6 having a three-dimensional shape.

### <<Overall Configuration of Semiconductor Apparatus>>

As illustrated in FIG. 8, the semiconductor apparatus 1C according to Embodiment 3 of the present technique includes the semiconductor layer 2, the field effect transistors Q1 and Q2, and the stress parts 7 and 8.

The semiconductor layer 2 includes the base part 4, which extends two-dimensionally in the X direction and the Y direction, and the semiconductor parts 5 and 6, each having a three-dimensional shape and protruding upward (in the Z direction) from the base part 4. As in the foregoing Embodiment 1, the semiconductor part 5 is configured having a cuboid shape integrated with the base part 4, and includes the upper face 5a and the four side faces 5b₁, 5b₂, 5b₃, and 5b₄. As in the foregoing Embodiment 2, the semiconductor part 6 is configured having a cuboid shape integrated with the base part 4, and includes the upper face 6a and the four side faces 6b₁, 6b₂, 6b₃, and 6b₄. A p-type semiconductor substrate constituted by single-crystal silicon is used as the semiconductor layer 2, in the same manner as the foregoing Embodiments 1 and 2.

The p-type well region 3p similar to that of the foregoing Embodiment 1 and the n-type well region 3n similar to that of the foregoing Embodiment 2 are provided in the semiconductor layer 2.

The insulating layer 9 is provided on the semiconductor part 5 and 6 sides of the base part 4 so as to surround the semiconductor parts 5 and 6. As in Embodiments 1 and 2, the upper face of the insulating layer 9 is flattened on the side opposite from the side where the base part 4 is located, and is formed at a film thickness approximately equal to the height to which the semiconductor parts 5 and 6 protrude from the base part 4 (a protrusion amount).

The insulating layer 18 is provided on the upper face of the insulating layer 9, on the side opposite from the side where the base part 4 is located, covering the tip parts 12a and 13a of the gate electrodes 12 and 13. The interconnects 21a, 21b, 21c, 22a, 22b, and 22c included in a first interconnect layer are provided on the upper face of the insulating layer 18 on the side opposite from the side where the insulating layer 9 is located.

The field effect transistor Q1 is provided in the semiconductor part 5 and has the same configuration as in the foregoing Embodiment 1. The stress part 7 is provided between the upper face 5a of the semiconductor part 5 and the gate electrode 12, and has the same configuration as in the foregoing Embodiment 1.

The field effect transistor Q2 is provided in the semiconductor part 6 and has the same configuration as in the foregoing Embodiment 2. The stress part 8 is provided between the upper face 6a of the semiconductor part 6 and the gate electrode 13, and has the same configuration as in the foregoing Embodiment 2.

In the field effect transistor Q1, the gate electrode 12 is electrically connected to an interconnect 21c on the insulating layer 18 through a contact electrode 19c provided in the insulating layer 18. Of the pair of main electrode regions 14a and 14b, the one main electrode region 14a is electrically connected to the interconnect 21a on the insulating layer 18 through the contact electrode 19a provided in the insulating layer 18. Of the pair of main electrode regions 14a and 14b, the other main electrode region 14b is electrically connected to an interconnect 21b on the insulating layer 18 through a contact electrode 19b provided in the insulating layer 18.

In the field effect transistor Q2, the gate electrode 13 is electrically connected to the interconnect 22c on the insulating layer 18 through the contact electrode 20c provided in the insulating layer 18. Of the pair of main electrode regions 15a and 15b, the one main electrode region 15a is electrically connected to the interconnect 22a on the insulating layer 18 through the contact electrode 20a provided in the insulating layer 18. Of the pair of main electrode regions 15a and 15b, the other main electrode region 15b is electrically connected to the interconnect 22b on the insulating layer 18 through the contact electrode 20b provided in the insulating layer 18.

### <<Main Effects of Embodiment 3>>

The semiconductor apparatus 1C according to Embodiment 3 provides effects similar to those of the semiconductor apparatus 1A of the foregoing Embodiment 1, as well as effects similar to those of the semiconductor apparatus 1B of the foregoing Embodiment 2.

In addition, CMOS circuits such as inverter circuits including the n-channel conductivity type field effect transistor Q1 and the p-channel conductivity type field effect transistor Q2 can be made faster, and the semiconductor apparatus 1C can therefore be made faster.

### Embodiment 4

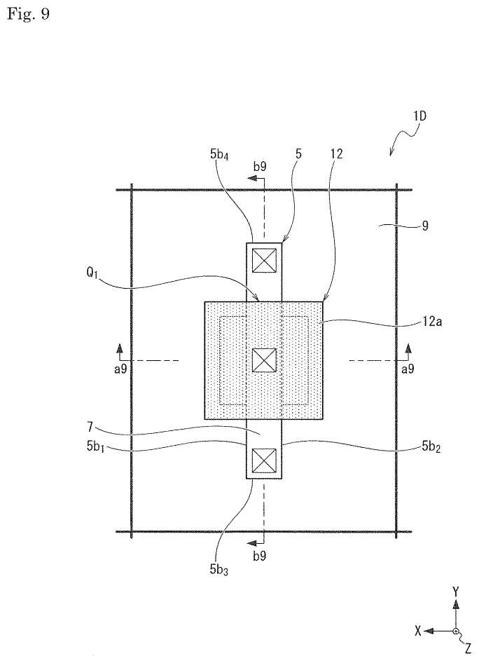

Referring to FIGS. 9 to 11, Embodiment 4 will describe an example in which the present technique is applied in a semiconductor apparatus 1D having the n-channel conductivity type field effect transistor Q1 provided in the semiconductor part 5 having a three-dimensional shape.

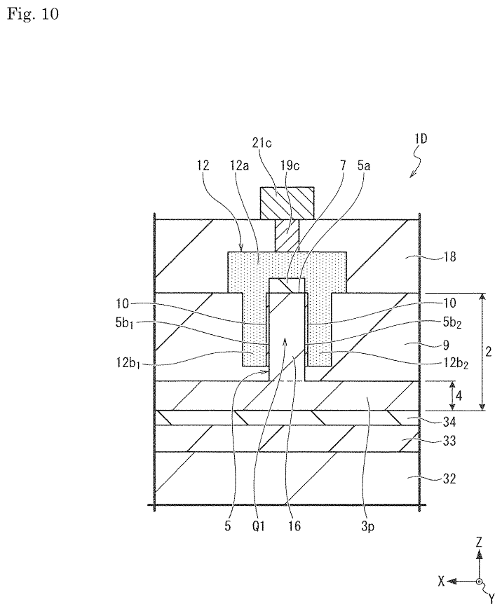

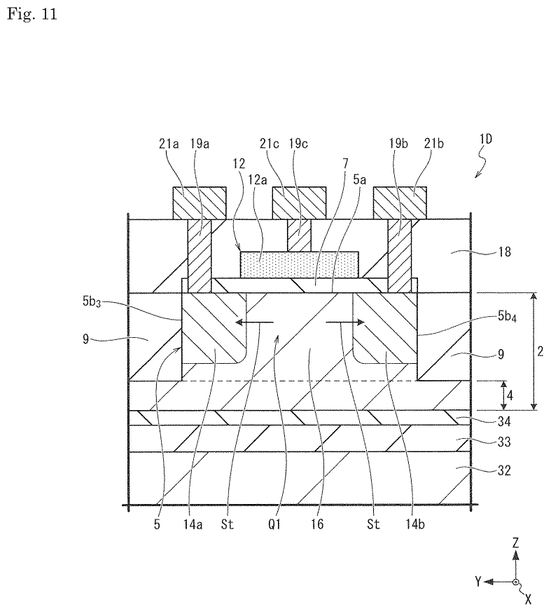

For the sake of simplicity, FIG. 9 does not illustrate the insulating layer 18, contact electrodes (19a, 19b, 19c), and interconnects (21a, 21b, 21c), which are illustrated in FIGS. 10 and 11.

### <<Overall Configuration of Semiconductor Apparatus>>

As illustrated in FIGS. 9 to 11, the semiconductor apparatus 1D according to Embodiment 4 of the present technique has basically the same configuration as the semiconductor apparatus 1A according to the foregoing Embodiment 1, with the exception of the following configurations.

As illustrated in FIGS. 10 and 11, the semiconductor apparatus 1D according to Embodiment 4 further includes a stress part 34 in addition to the configuration described above in Embodiment 1.

Here, in Embodiment 4, the stress part 7 corresponds to a specific example of a “first stress part” of the present technique, and the stress part 34 corresponds to a specific example of a “second stress part” of the present technique.

The stress part 34 is a stress-inducing part provided on the side of the semiconductor part 5 opposite from the side where the upper face 5a is located, so as to overlap with the semiconductor part 5 in plan view, and produces (induces) stress in the semiconductor part 5 in a direction in which current flowing in the semiconductor part 5 increases.

The stress part 34 is provided on the side of the base part 4 opposite from the side where the semiconductor part 5 is located, and is joined to the base part 4. A semiconductor layer 32 is provided on the side of the stress part 34 opposite from the side where the base part 4 is located, with an insulating layer 33 interposed therebetween. In other words, in the semiconductor apparatus 1D according to Embodiment 4, the semiconductor layer 2 and the semiconductor layer 32 are stacked in the thickness direction of each (Z direction) with the stress part 34 and the insulating layer 33 provided therebetween.

As with the stress part 7 in the foregoing Embodiment 1, a silicon nitride film in which the thermal expansion coefficient can be controlled by changing the conditions under which the film is formed (the reaction gas, pressure, temperature, high-frequency power, and the like) is used as the stress part 34.

When the stress part 34 is provided on the side of the semiconductor part 5 opposite from the side where the upper face 5a is located, making the thermal expansion coefficient of the silicon nitride film serving as the stress part 34 smaller (lower) than the thermal expansion coefficient of the semiconductor part 5 makes it possible to produce (induce) tensile stress St in the semiconductor part 5 in the gate length direction of the gate electrode 12 (the Y direction), i.e., in the direction in which the pair of main electrode regions 14a and 14b are arranged, as illustrated in FIG. 11. In this case, the stress part 34 provided on the side of the semiconductor part 5 opposite from the side where the upper face 5a is located has an inherent tensile stress, as with the stress part 7 provided on the upper face 5a of the semiconductor part 5.

When the stress part 34 is provided on the side of the semiconductor part 5 opposite from the side where the upper face 5a is located, making the thermal expansion coefficient of the silicon nitride film serving as the stress part 34 larger (higher) than the thermal expansion coefficient of the semiconductor part 5 makes it possible to produce compressive stress Sc in the semiconductor part 5 in the gate length direction of the gate electrode 12 (the direction in which the pair of main electrode regions 14a and 14b are arranged), as described with reference to FIG. 7. In this case, the stress part 34 provided on the side of the semiconductor part 5 opposite from the side where the upper face 5a is located has an inherent compressive stress.

Because the field effect transistor Q1 according to Embodiment 1 is configured having the n-channel conductivity type, providing the stress part 34, which produces the tensile stress St in the semiconductor part 5, on the side of the semiconductor part 5 opposite from the side where the upper face 5a is located, makes it possible to improve the mobility of carriers moving in the semiconductor part 5, and increase the current flowing from one to the other of the pair of main electrode regions 14a and 14b through the channel forming part 16 (the drain current Id).

### <<Main Effects of Embodiment 4>>

The semiconductor apparatus 1D according to Embodiment 4 includes the n-channel conductivity type field effect transistor Q1, which has the gate electrode 12 provided across the upper face 5a and the side faces 5b₁ and 6b₂ of the semiconductor part 5; and the stress part 7, which is provided between the upper face 5a of the semiconductor part 5 and the gate electrode 12, and which produces stress in the semiconductor part 5 in a direction in which the current flowing in the semiconductor part 5 (the drain current Id) increases. The semiconductor apparatus 1D according to Embodiment 4 further includes the stress part 34, which is provided on the side of the semiconductor part 5 opposite from the side where the upper face 5a is located, so as to overlap with the semiconductor part 5 in plan view, and which produces stress in the semiconductor part 5 in a direction in which the current flowing in the semiconductor part 5 (the drain current Id) increases. Accordingly, the semiconductor apparatus 1D according to Embodiment 4 makes it possible to improve the mutual conductance in the n-channel conductivity type field effect transistor Q1 more than with the semiconductor apparatus 1A according to the foregoing Embodiment 1.

### <<Variations on Embodiment 4>>

### <Variation 4-1>

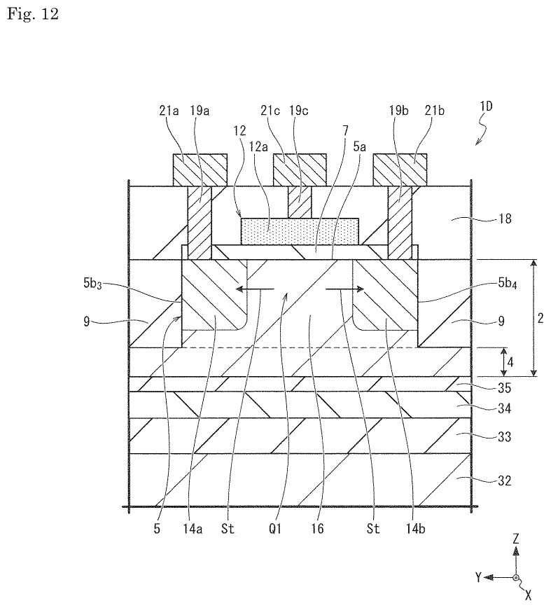

As illustrated in FIG. 12, an insulating layer 35 may be provided between the semiconductor part 5 and the stress part 34. In this case, it is preferable that the stress part 34 have a smaller thermal expansion coefficient than the insulating layer 35. It is also preferable that the stress part 34 be thicker than the insulating layer 35.

### <Variation 4-2>

The foregoing Embodiment 4 described a case where both the stress part 7 and the stress part 34 are provided. However, the present technique is not limited to a case where both the stress part 7 and the stress part 34 are provided. For example, although not illustrated, the stress part 7 may be omitted, and only the stress part 34 may be provided. The mutual conductance of the n-channel conductivity type field effect transistor Q1 can be improved in this case as well.

### <Variation 4-3>

The foregoing Embodiment 4 described a case where the stress part 34 is provided on the side of the semiconductor part 5, where the n-channel conductivity type field effect transistor Q1 is mounted, opposite from the side where the upper face 5a is located. However, the present technique is not limited to a case where the stress part 34 is provided in the semiconductor part 5 where the n-channel conductivity type field effect transistor Q1 is mounted.

For example, to described with reference to FIGS. 5 to 7, a stress part may be provided on the side of the semiconductor part 6, on which the p-channel conductivity type field effect transistor Q2 is mounted, opposite from the side where the upper face 6a, so as to overlap with the semiconductor part 6 in plan view, the stress part producing stress in the semiconductor part 6 in a direction in which current flowing in the semiconductor part 6 (the drain current Id) increases. In this case, the stress part on the side of the semiconductor part 6 opposite from the side where the upper face 6a is located may be provided alone, and as in the foregoing Embodiment 4, a stress part on the side of the semiconductor part 6 opposite from the side where the upper face 6a is located may be provided along with the stress part 8 on the upper face 6a side of the semiconductor part 6.

### Embodiment 5

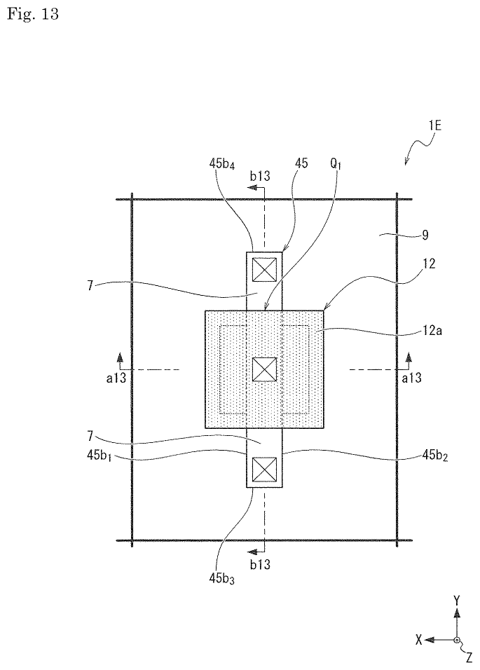

Referring to FIGS. 13 to 15, Embodiment 5 will describe an example in which the present technique is applied in a semiconductor apparatus 1E having the n-channel conductivity type field effect transistor Q1 provided in the semiconductor part 45 having a three-dimensional shape.

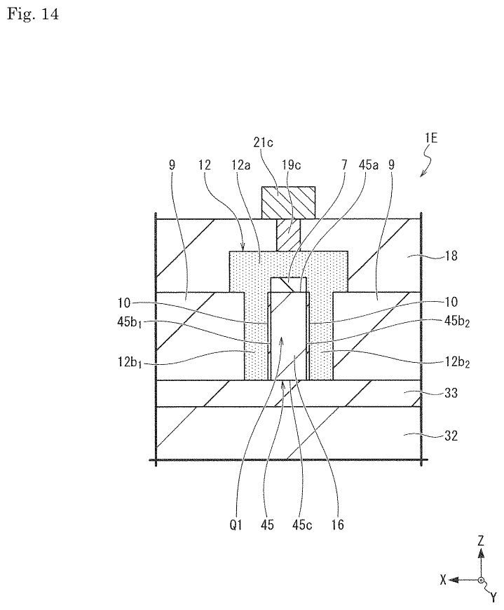

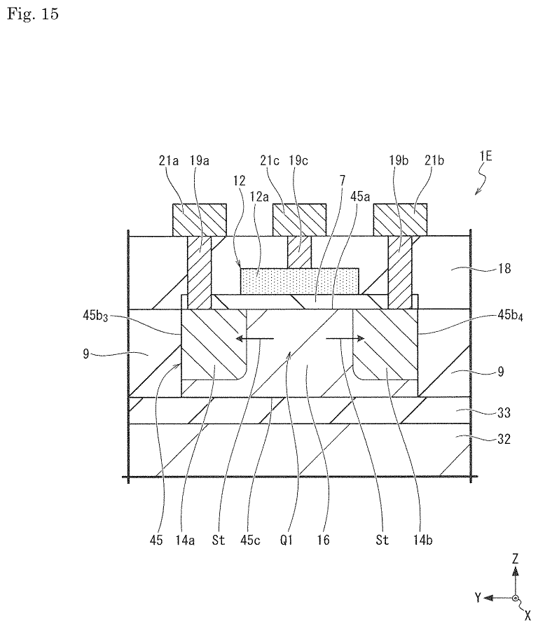

For the sake of simplicity, FIG. 13 does not illustrate the insulating layer 18, contact electrodes (20a, 20b, 20c), and interconnects (22a, 22b, 22c), which are illustrated in FIGS. 14 and 15.

In Embodiment 5, the thickness direction of a semiconductor part 45 (described later) will be defined as the Z direction.

### <<Overall Configuration of Semiconductor Apparatus>>

As illustrated in FIGS. 13 to 15, the semiconductor apparatus 1E according to Embodiment 5 of the present technique has basically the same configuration as the semiconductor apparatus 1A according to the foregoing Embodiment 1, with the exception of the following configurations.

First, as illustrated in FIGS. 13 to 15, the semiconductor apparatus 1E according to Embodiment 5 includes the semiconductor part 45, which has a three-dimensional shape, instead of the semiconductor part 5 illustrated in FIGS. 1 to 3 described above in Embodiment 1. Furthermore, the same field effect transistor Q1 as that of the foregoing Embodiment 1 is provided in the semiconductor part 45.

As illustrated in FIGS. 13 to 15, the semiconductor part 45 is configured having a cuboid shape including an upper face 45a, a lower face 45c, and four side faces 45b₁, 45b₂, 45b₃, and 45b₄. The semiconductor part 45 is provided on a first side of the insulating layer 33 such that the lengthwise direction of the semiconductor part 45 is the Y direction in plan view, and is supported by the insulating layer 33. The semiconductor layer 32 is provided on a second side of the insulating layer 33, which is opposite from the side where the semiconductor part 45 is located.

In the semiconductor part 45, the upper face 45a and the lower face 45b are located on opposite sides from each other in the thickness direction of the semiconductor part 45 (the Z direction). Of the four side faces 45b₁, 45b₂, 45b₃, and 45b₄, the two side faces 45b₁ and 45b₂ are located on opposite sides from each other in the widthwise direction of the semiconductor part 45 (the X direction). The remaining two side faces 45b₃ and 45b₄ are located opposite to each other in the lengthwise direction of the semiconductor part 45 (the Y direction).

Although not limited thereto, the semiconductor part 45 is constituted by a semiconductor material, e.g., silicon (Si), with single-crystal as the crystallinity and p-type as the conductivity type, for example. In other words, the semiconductor part 45 is constituted by p-type single-crystal silicon. Aside from Si, germanium (Ge), silicon germanium (SiGe), gallium arsenide (GaAs), indium Phosphorus (InP), or the like can also be used for the material of the semiconductor part 45.

The same p-type well region 3p as in the foregoing Embodiment 1 is provided in the semiconductor part 45. The semiconductor part 45 can be formed by selectively etching a semiconductor layer provided on the first side of the insulating layer 33 to a depth that reaches the insulating layer 33.

As illustrated in FIGS. 14 and 15, the insulating layer 33 is provided on the lower face 45c side of the semiconductor part 45 in contact with the lower face 45c, and supports the semiconductor part 45 from the lower face 45c side of the semiconductor part 45. The insulating layer 33 is constituted by a silicon oxide film, for example. In other words, the semiconductor apparatus 1E according to Embodiment 5 has a Silicon On Insulator (SOI) structure in which the semiconductor part 45 is provided on the first side of the insulating layer 33.

As illustrated in FIGS. 13 to 15, the insulating layer 9 is provided on the semiconductor part 45 side of the insulating layer 33, i.e., on the insulating layer 33, so as to surround the semiconductor part 45. As in the foregoing Embodiment 1, the surface layer part of the insulating layer 9 is flattened on the side opposite from the side where the insulating layer 33 is located, and is formed at a film thickness approximately equal to the height at which the semiconductor part 45 protrudes upward from the insulating layer 33 (a protrusion amount).

The insulating layer 18 is provided on the upper face of the insulating layer 9 on the side opposite from the side where the insulating layer 33 is located, covering the tip part 12a of the gate electrode 12 and the tip part 13a of the gate electrode 13. The interconnects 21a, 21b, and 21c included in the first interconnect layer are provided on the upper face of the insulating layer 18 on the side opposite from the side where the insulating layer 9 is located.

The field effect transistor Q1 is provided in the semiconductor part 45 and has the same configuration as in the foregoing Embodiment 1. The stress part 7 is provided between the upper face 45a of the semiconductor part 45 and the gate electrode 12, and has the same configuration as the stress part 7 in the foregoing Embodiment 1.

In the field effect transistor Q1, the channel forming part 16 and the pair of main electrode regions 14a and 14b are provided in the semiconductor part 45, in the same manner as in the foregoing Embodiment 1. As in the foregoing Embodiment 1, the gate electrode 12 includes the tip part 12a provided on the upper face 45a side of the semiconductor part 45 over the stress part 7; and the two leg parts 12b₁ and 12b₂ which are formed integrally with the tip part 12a, and which are provided on outer sides of corresponding ones of the two side faces 45b₁ and 45b₂ located on opposite sides from each other in the widthwise direction of the semiconductor part 45 (the X direction) over the gate insulating film 10. In other words, as in the foregoing Embodiment 1, in Embodiment 5 too, the gate electrode 12 is provided across the upper face 45a and the two side faces 45b₁ and 45b₂ of the semiconductor part 45.

### <<Main Effects of Embodiment 5>>

The semiconductor apparatus 1E according to Embodiment 5 also includes the stress part 7, which is provided between the upper face 45a of the semiconductor part 45 and the gate electrode 12, and which produces stress in the semiconductor part 45 in a direction in which the current flowing in the semiconductor part 45 (the drain current Id) increases (tensile stress acting in the gate length direction of the gate electrode 12), and thus the mutual conductance of the n-channel conductivity type field effect transistor Q1 can be improved in the same manner as in the foregoing Embodiment 1.

Additionally, as in the foregoing Embodiment 1, the stress part 7 is provided in the upper face 45a of the semiconductor part 45, across both the inside and outside the gate electrode 12 in plan view. Accordingly, the stress produced in the semiconductor part 45 (the stress in the direction in which the current flowing in the semiconductor part 5 (the drain current Id) increases) can be increased compared to when the stress part 7 is selectively provided between the upper face 45a of the semiconductor part 45 and the gate electrode 12.

### <<Variations on Embodiment 5>>

### <Variation 5-1>

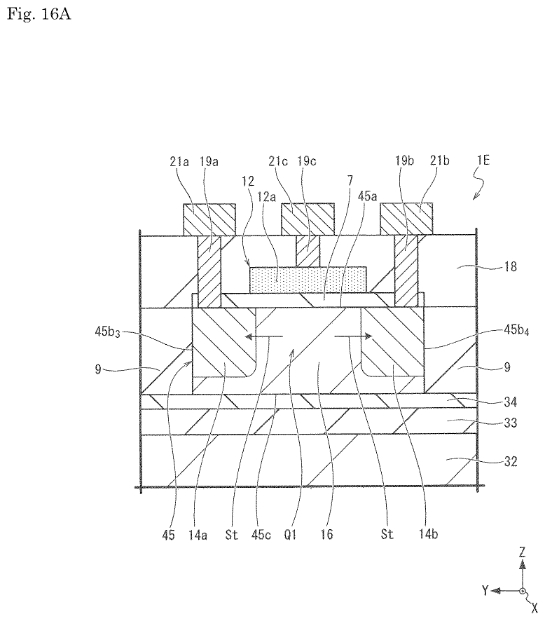

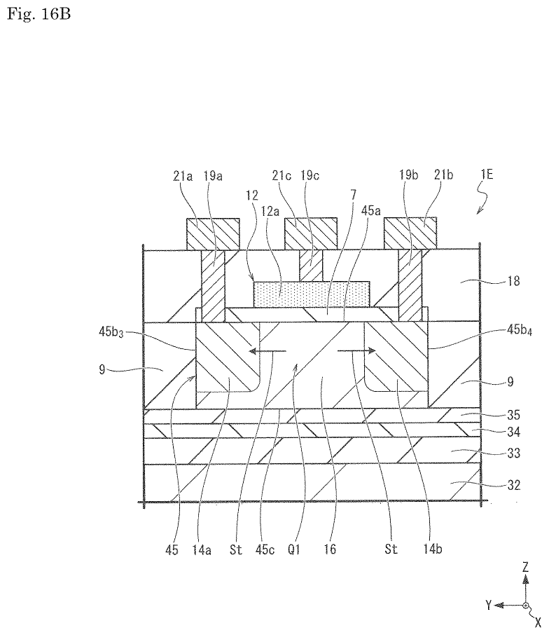

As illustrated in FIG. 16A, the stress part 34 that produces the tensile stress St in the semiconductor part 45 acting in the gate length direction of the gate electrode 12 (the Y direction) may be provided on the lower face 45c side of the semiconductor part 45. In this Variation 5-1, both the stress parts 7 and 34 are provided, but the stress part 7 may be omitted, and only the stress part 34 may be provided. In other words, the mutual conductance (gm) of the n-channel conductivity type field effect transistor Q1 can be improved by providing at least one of the stress parts 7 and 34.

### <Variation 5-2>

In addition, as illustrated in FIG. 16B, the stress part 34 may be provided on the lower face 45c side of the semiconductor part 45 with the insulating layer 35 interposed therebetween.

<variation 5-3>

The foregoing Embodiment 5 described a case where, in the SOI-structure semiconductor part 45 on which the n-channel conductivity type field effect transistor Q1 is mounted, the stress part 7, which produces stress in the semiconductor part 45 in a direction in which current flowing in the semiconductor part 45 increases, is provided between the upper face 45a of the semiconductor part 45 and the gate electrode 12, but the present technique is not limited thereto. For example, in the SOI-structure semiconductor part on which a p-channel conductivity type field effect transistor is mounted, a stress part that produces stress in the semiconductor part in a direction in which the current flowing in the semiconductor part increases may be provided between the upper face of the semiconductor part and the gate electrode. The mutual conductance (gm) of the p-channel conductivity type field effect transistor can be improved in this case as well.

### Embodiment 6

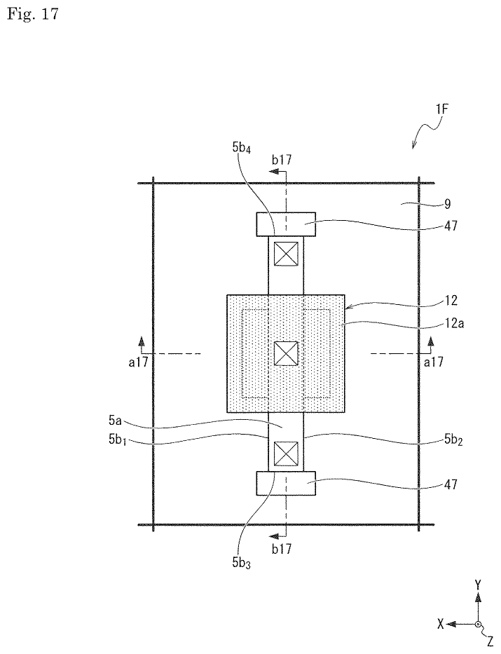

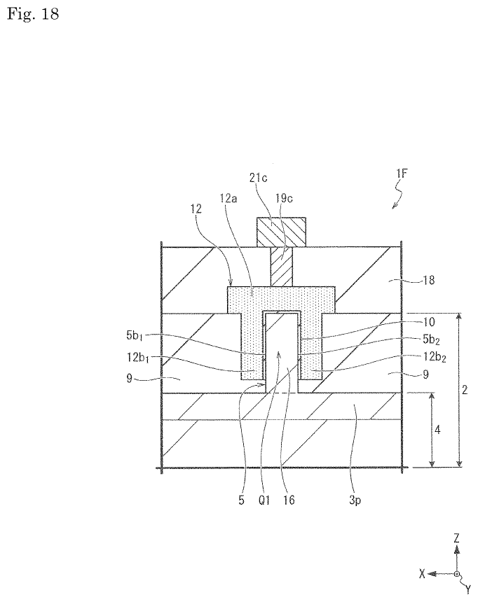

Referring to FIGS. 17 to 19, Embodiment 6 will describe an example in which the present technique is applied in a semiconductor apparatus 1F having the n-channel conductivity type field effect transistor Q1 provided in the semiconductor part 5 having a three-dimensional shape.

For the sake of simplicity, FIG. 13 does not illustrate the insulating layer 18, contact electrodes (19a, 19b, 19c), and interconnects (21a, 21b, 21c), which are illustrated in FIGS. 14 and 15.

In Embodiment 6, the thickness direction of the semiconductor layer 2 will be defined as the Z direction.

### <<Overall Configuration of Semiconductor Apparatus>>

As illustrated in FIGS. 17 to 19, the semiconductor apparatus 1F according to Embodiment 6 of the present technique has basically the same configuration as the semiconductor apparatus 1A according to the foregoing Embodiment 1, with the exception of the following configurations.

As illustrated in FIGS. 17 to 19, the semiconductor apparatus 1F according to Embodiment 6 includes a stress part 47 instead of the stress part 7 illustrated in FIGS. 1 to 3 described above in Embodiment 1. The other configurations are generally the same as those described in the foregoing Embodiment 1.

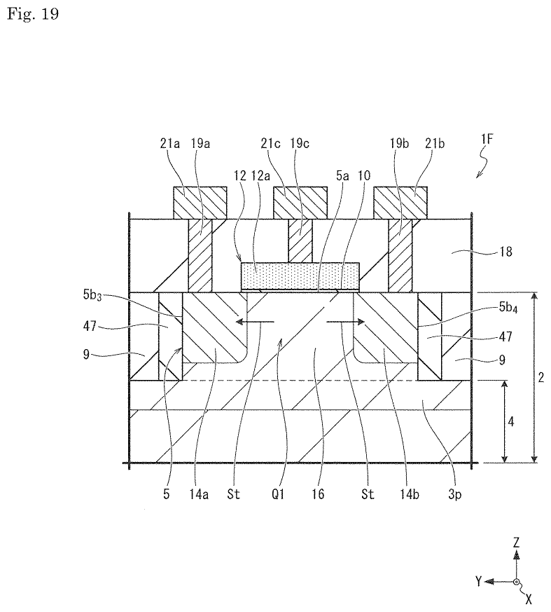

As illustrated in FIG. 19, the stress part 47 is a stress part connected with the semiconductor part 5 along the thickness direction of the semiconductor part 5 (the Z direction) on an outer side of the gate electrode 12, and produces stress in the semiconductor part 5 in a direction in which current flowing in the semiconductor part 5 increases. In other words, the stress part 47 produces (induces) stress in the semiconductor part 5 in a direction in which current (the drain current Id) flowing from one to the other of the pair of main electrode regions 14a and 14b through the channel forming part 16 increases. To rephrase again, the stress part 47 produces (induces) stress in the semiconductor part 5 in a direction in which the mobility of carriers moving from one to the other of the pair of main electrode regions 14a and 14b through the channel forming part 16 increases.

Although not limited thereto, in Embodiment 6, the stress part 47 is provided separately on the outer sides of each of the two side faces 5b₃ and 5b₄ located opposite from each other in the lengthwise direction of the semiconductor part 5 (the Y direction), as illustrated in FIGS. 17 to 19. The stress part 47 is configured to be wider than the width of the semiconductor part 5 in the widthwise direction (the X direction).

As illustrated in FIG. 19, the stress part 47 on the side face 5b₃ side of the semiconductor part 5 extends from the upper face 5a side to the base part 4 side of the semiconductor part 5, and is configured to be approximately the same height as the height of the semiconductor part 5. Likewise, the stress part 47 on the side face 5b₄ side of the semiconductor part 5 extends from the upper face 5a side to the base part 4 side of the semiconductor part 5, and is configured to be approximately the same height as the height of the semiconductor part 5 in the Z direction.

As with the stress part 7 in the foregoing Embodiment 1, a silicon nitride (SiN) film that can be formed through plasma CVD can be used as the stress part 47.

As described above, with a silicon nitride film, the coefficient of thermal expansion can be controlled by changing the conditions under which the film is formed (the reaction gas, pressure, temperature, high-frequency power, and the like).

The silicon nitride film serving as the stress part 47, the semiconductor part 5, and the like contract by returning from high temperature to normal temperature during the manufacturing process. Accordingly, when providing the stress part 47 separately on the outer side of each of the two side faces 5b₃ and 5b₄ located opposite from each other in the lengthwise direction of the semiconductor part 5 (the Y direction), making the thermal expansion coefficient of the silicon nitride film serving as the stress part 47 larger (higher) than the thermal expansion coefficient of the semiconductor part 5 makes it possible to produce tensile stress St in the semiconductor part 5 in the gate length direction of the gate electrode 12 (the Y direction), i.e., in the direction in which the pair of main electrode regions 14a and 14b are arranged (the Y direction), as illustrated in FIG. 19. In this case, the stress part 47 provided on the outer side of the side faces 5b₃ and 5b₄ of the semiconductor part 5 has an inherent compressive stress.

In addition, when providing the stress part 47 separately on the outer side of each of the two side faces 5b₃ and 5b₄ located opposite from each other in the lengthwise direction of the semiconductor part 5 (the Y direction), making the thermal expansion coefficient of the silicon nitride film serving as the stress part 47 smaller (lower) than the thermal expansion coefficient of the semiconductor part 5 makes it possible to produce compressive stress in the semiconductor part 5 in the gate length direction of the gate electrode 12 (the direction in which the pair of main electrode regions 15a and 15b are arranged). In this case, the stress part 47 provided on the outer side of the side faces 5b₃ and 5b₄ of the semiconductor part 5 has an inherent tensile stress.

### <<Main Effects of Embodiment 6>>

In Embodiment 6, the semiconductor part 5 is provided with the n-channel conductivity type field effect transistor Q1. Accordingly, providing the stress part 47, which has a greater thermal expansion coefficient than the semiconductor part 5, on the outer sides of the side faces 5b₂ and 5b₄ of the semiconductor part 5 in the lengthwise direction of the semiconductor part 5 (the Y direction) makes it possible to produce the tensile stress St acting in the gate length direction of the gate electrode 12 in the semiconductor part 5, which improves the carrier mobility and increases the current (the drain current Id) flowing from one to the other of the pair of main electrode regions 14a and 14b through the channel of the channel forming part 16.

As a result, the semiconductor apparatus 1F of Embodiment 6 can improve the mutual conductance (gm) of the n-channel conductivity type field effect transistor Q1, in the same manner as the semiconductor apparatus 1A of Embodiment 1.

In addition, because the mutual conductance of the field effect transistor Q1 can be improved, the circuit including the field effect transistor Q1 can be made faster, i.e., the semiconductor apparatus 1F can be made faster, in the same manner as in the foregoing Embodiment 1.

Note that the stress part 47 does not absolutely have to be provided in each of the two side faces 5b₃ and 5b₄ located opposite from each other in the lengthwise direction of the semiconductor part 5, and may be provided in at least one thereof. However, providing the stress part 47 in each of the two side faces 5b₃ and 5b₄ makes it possible to produce the tensile stress St in the semiconductor part 5 more effectively.

### <<Variations on Embodiment 6>>

### <Variation 6-1 on Embodiment 6>

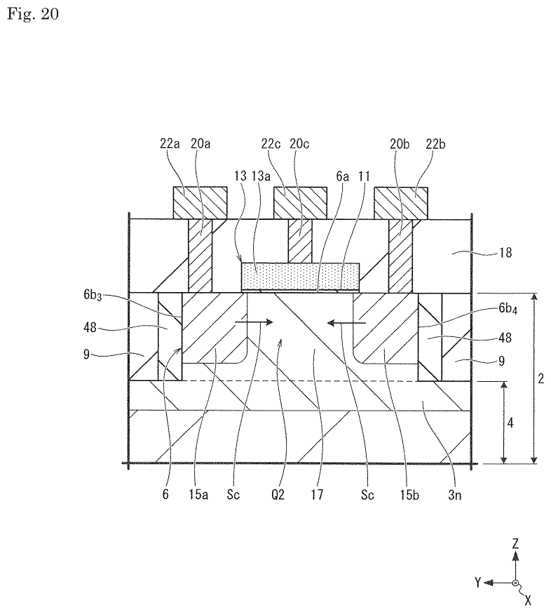

The foregoing Embodiment 6 described a case where the stress part 47 is provided in the side faces of the semiconductor part 5 on which the n-channel conductivity type field effect transistor Q1 is mounted, but the present technique is not limited to the foregoing Embodiment 6. For example, as illustrated in FIG. 20, a stress part 48 can also be provided in the side faces of the semiconductor part 6 on which the p-channel conductivity type field effect transistor Q2 is mounted.

Specifically, the stress part 48, which produces stress in the semiconductor part 6 in a direction in which current flowing in the semiconductor part 6 increases, is connected with the semiconductor part 6 along the thickness direction of the semiconductor part 6 (the Z direction) on an outer side of the gate electrode 13. Although not limited thereto, the stress part 48 is preferably provided separately on the outer sides of each of the two side faces 6b₃ and 6b₄ located opposite from each other in the lengthwise direction of the semiconductor part 6 (the Y direction), as in the foregoing Embodiment 6.

In this case, making the thermal expansion coefficient of the stress part 48 lower than the thermal expansion coefficient of the semiconductor part 6 makes it possible to produce (impart) the compressive stress Sc in the semiconductor part 6 in the gate length direction of the gate electrode 13 (the Y direction), i.e., in the direction in which the pair of main electrode regions 15a and 15b are arranged (the Y direction), as illustrated in FIG. 20. Accordingly, in Variation 6-1 as well, the carrier mobility in the semiconductor part 6 can be improved, and the current (the drain current Id) flowing from one to the other of the pair of main electrode regions 15a and 15b through the channel forming part 17 can be increased. In this case, the stress part 48 has an inherent tensile stress.

Note that the stress part 48 does not absolutely have to be provided in each of the two side faces 6b₃ and 6b₄ located opposite from each other in the lengthwise direction of the semiconductor part 6 (the Y direction), and may be provided in at least one thereof. However, as in the foregoing Embodiment 6, providing the stress part 48 in each of the two side faces 6b₃ and 6b₄ makes it possible to produce the compressive stress Sc in the semiconductor part 6 more effectively.

### <Variation 6-2>

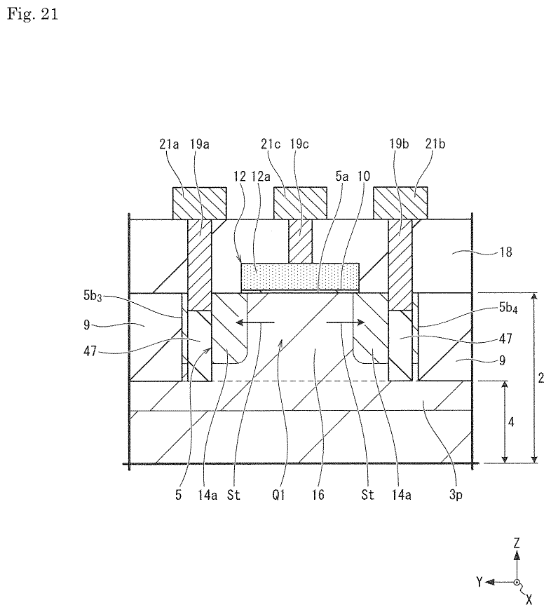

Although the foregoing Embodiment 6 described a case where the stress part 7 is provided in the side face parts (5b₃ and 5b₄) of the semiconductor part 5 in the gate length direction of the gate electrode 12 (the Y direction), the stress part 47 may be provided within the semiconductor part 5 so as to be connected to the semiconductor part 5 along the thickness direction of the semiconductor part 5 (the Z direction) on an outer side of the gate electrode 12, as illustrated in FIG. 21. In this case, the stress part 47 is preferably extended in the thickness direction of the semiconductor part 5 (the Z direction) from the upper face 5a side of the semiconductor part 5 so as to reach the base part 4, such that a surface area of the connection between the stress part 47 and the semiconductor part 5 is increased.

Additionally, as illustrated in FIG. 21, when the stress part 47 and the contact electrodes (19a and 19b) are caused to overlap in plan view, preferably, the stress part 47 is separated from the upper face 5a of the semiconductor part 5, the contact electrodes (19a and 19b) are extended into the interior of the semiconductor part 5, and the surface area of the connection between the main electrode regions (14a and 14b) and the contact electrodes (19a and 19b) is increased.

Additionally, to describe with reference to FIG. 20, Variation 6-2 can also be applied in the semiconductor part 6 on which the p-channel conductivity type field effect transistor Q2 is mounted.

### <Variation 6-3>

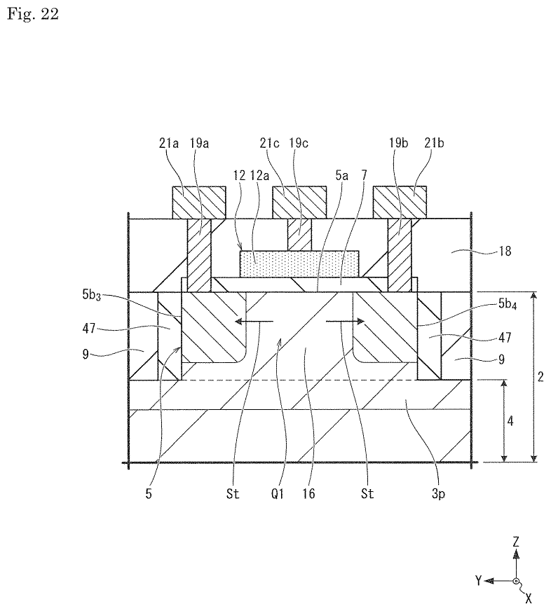

As illustrated in FIG. 22, Variation 6-3 combines the stress part 7 illustrated in FIG. 3 of the foregoing Embodiment 1 with the foregoing Embodiment 6. In other words, Variation 6-3 includes the stress part 47 provided on the side face (5b₃ and 5b₄) sides in the lengthwise direction of the semiconductor part 5, and the stress part 7 provided on the upper face 5a of the semiconductor part 5. In the case of Variation 6-3, the tensile stress St can be produced more effectively in the semiconductor part 5 than in the foregoing Embodiment 6 and Embodiment 1.

The combination in Variation 6-3 can also be applied in the semiconductor part 6 on which the p-channel conductivity type field effect transistor Q2 is mounted.

### <Variation 6-4>

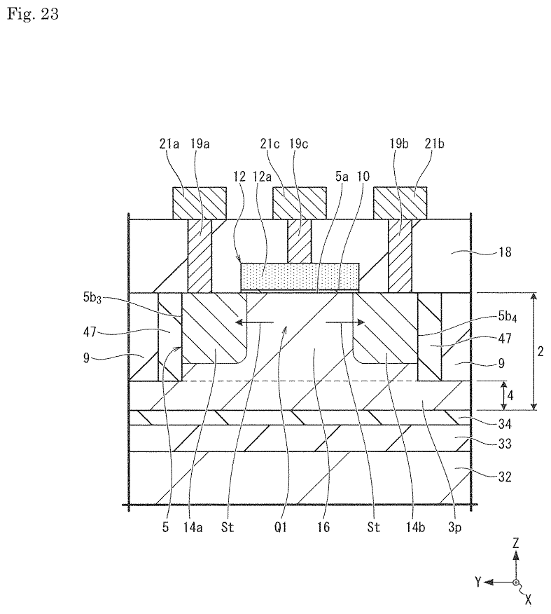

As illustrated in FIG. 23, Variation 6-4 combines the stress part 34 illustrated in FIG. 11 of the foregoing Embodiment 4 with the foregoing Embodiment 6. In other words, Variation 6-4 includes the stress part 47 provided on the side face (5b₃ and 5b₄) sides in the lengthwise direction of the semiconductor part 5, and the stress part 34 provided on the side of the semiconductor part 5 opposite from the side where the upper face 5a is located, overlapping with the semiconductor part 5 in plan view. In the case of Variation 6-4, the tensile stress St can be produced more effectively in the semiconductor part 5 than in the foregoing Embodiment 6.

The combination in Variation 6-4 can also be applied in the semiconductor part 6 on which the p-channel conductivity type field effect transistor Q2 is mounted.

Furthermore, although not illustrated, the stress part 7 illustrated in FIG. 3 of the foregoing Embodiment 1 can also be combined with Variation 6-4.

### <Variation 6-5>

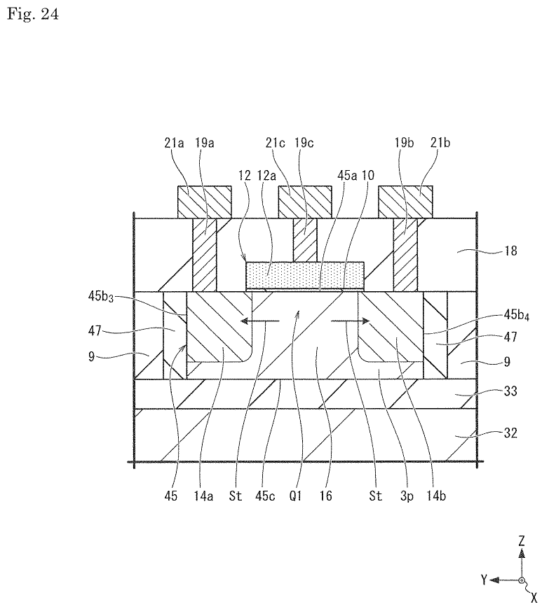

As illustrated in FIG. 24, Variation 6-5 combines the stress part 47 of the foregoing Embodiment 6 with the semiconductor part 45 of the foregoing Embodiment 5 (FIGS. 13 to 15). Variation 6-5 achieves the same effects as those of the foregoing Embodiment 6.

Furthermore, although not illustrated, the combination in Variation 6-5 can also be applied in a SOI-structure semiconductor part on which a p-channel conductivity type field effect transistor is mounted.

### <Variation 6-6>

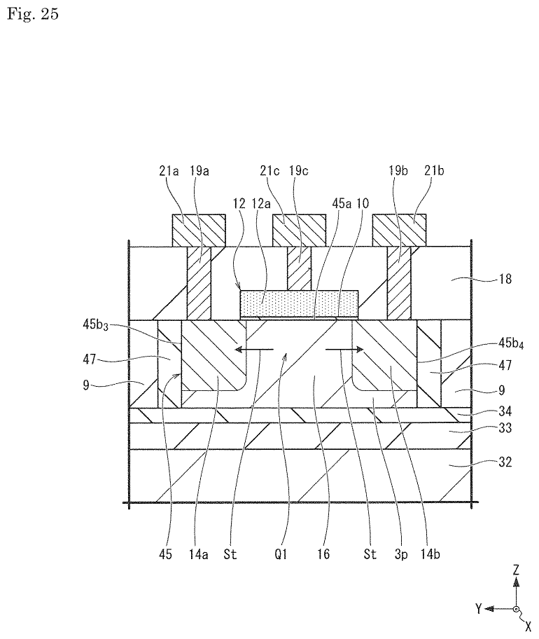

As illustrated in FIG. 25, Variation 6-6 combines the stress part 47 of the foregoing Embodiment 6 with the foregoing Variation 5-1 (see FIG. 16A). In the case of Variation 6-6, the tensile stress St can be produced more effectively in the semiconductor part 45 than in the foregoing Variation 5-1.

The combination in Variation 6-6 can also be applied in a semiconductor part on which the p-channel conductivity type field effect transistor Q2 is mounted. Furthermore, the stress part 7 illustrated in FIG. 3 of the foregoing Embodiment 1 can also be combined with Variation 6-6.

These combinations can also be applied in a SOI-structure semiconductor part on which a p-channel conductivity type field effect transistor is mounted.

### Embodiment 7

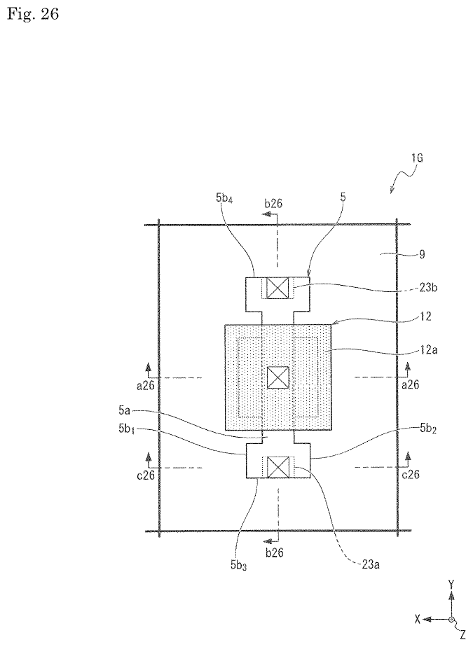

Referring to FIGS. 26 to 29, Embodiment 7 will describe an example in which the present technique is applied in a semiconductor apparatus 1G having the n-channel conductivity type field effect transistor Q1 provided in the semiconductor part 5 having a three-dimensional shape.

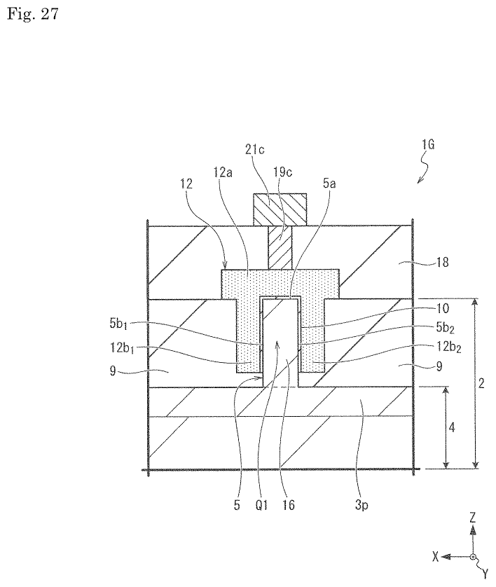

For the sake of simplicity, FIG. 26 does not illustrate the insulating layer 18, contact electrodes (19a₁, 19b₁, 19c), and interconnects (21 a, 21b, 21c), which are illustrated in FIGS. 27 to 29.

As illustrated in FIGS. 26 to 29, the semiconductor apparatus 1G according to Embodiment 7 of the present technique has basically the same configuration as the semiconductor apparatus 1F according to the foregoing Embodiment 6, with the exception of the following configurations.

First, as illustrated in FIGS. 26 to 29, the semiconductor apparatus 1G according to Embodiment 7 includes two contact electrodes 23a and 23b instead of the two contact electrodes 19a and 19b illustrated in FIGS. 17 to 19 described above in Embodiment 6. Furthermore, the semiconductor apparatus 1G according to Embodiment 7 does not include the stress part 47 of the foregoing Embodiment 6.

Here, in the semiconductor apparatus 1F according to Embodiment 6, the tensile stress St along the gate length direction of the gate electrode 12 (the Y direction) is produced (induced) in the semiconductor part 5 by the stress part 47, which is provided in each of the two side faces 5b₃ and 5b₄ in the lengthwise direction of the semiconductor part 5.

In contrast, in the semiconductor apparatus 1G of Embodiment 7, the tensile stress St along the gate length direction of the gate electrode 12 (the Y direction) is produced (induced) in the semiconductor part 5 by the two contact electrodes 23a and 23b. In other words, the two contact electrodes 23a and 23b of Embodiment 7 also serve as a stress part that produces stress in the semiconductor part 5 in a direction in which current flowing in the semiconductor part 5 increases.

As illustrated in FIGS. 26 to 29, as in the foregoing Embodiment 1, the semiconductor part 5 is provided with the n-channel conductivity type field effect transistor Q1.

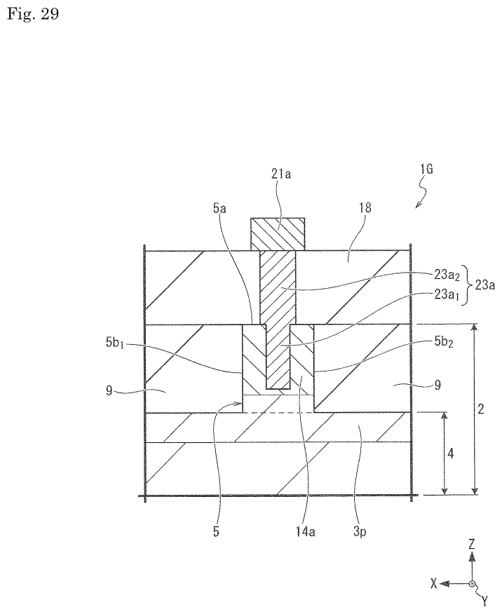

As illustrated in FIG. 29, each of the two contact electrodes 23a and 23b penetrates the insulating layer 18 and extends from the upper face 5a side to the base part 4 side of the semiconductor part 5. The respective two contact electrodes 23a and 23b are provided adjacent and connected to the semiconductor part 5 and the insulating layer 9 along the thickness direction of the semiconductor part 5 (the Z direction) on outer sides of the gate electrode 12. In other words, the two contact electrodes 23a and 23b include first parts (one end sides) 23a₁ and 23b₁ adjacent and connected to the semiconductor part 5 along the thickness direction of the semiconductor part 5, and second parts (other end sides) 23a₂ and 23b₂ adjacent and connected to the insulating layer 18 along the thickness direction of the insulating layer 18 (the Z direction).

As illustrated in FIG. 29, the contact electrode 23a has the first part 23a₁ thinner than the second part 23a₂.

Although not illustrated, like the contact electrode 23a, the contact electrode 23b also has the first part 23b₁ thinner than the second part 23b₂.

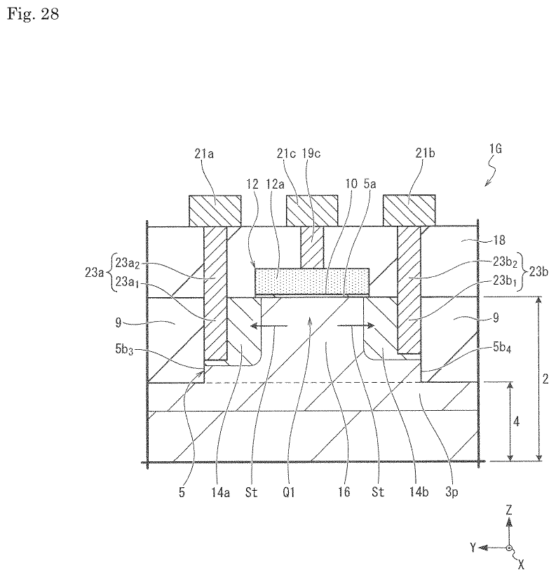

As illustrated in FIGS. 28 and 29, in the contact electrode 23a, the first part 23a₁ is electrically connected to the main electrode region 14a along the thickness direction of the semiconductor part 5 (the Z direction). As illustrated in FIG. 28, in the contact electrode 23b, the first part 23b₁ is electrically connected to the main electrode region 14b along the thickness direction of the semiconductor part 5 (the Z direction).

As illustrated in FIGS. 26 and 28, in the contact electrode 23a, the first part 23a₁ is provided on the one side face 5b₃ of the two side faces 5b₃ and 5b₄ in the lengthwise direction of the semiconductor part 5 (the Y direction), and cuts into the interior of the semiconductor part 5 from the one side face 5b₃ so as to be flush with the side face 5b₃ in plan view.

As illustrated in FIGS. 26 and 28, in the contact electrode 23b, the first part 23b₁ is provided on the other side face 5b₄ of the two side faces 5b₃ and 5b₄ in the lengthwise direction of the semiconductor part 5 (the Y direction), and cuts into the interior of the semiconductor part 5 from the other side face 5b₄ so as to be flush with the other side face 5b₄ in plan view.

Because each of the contact electrodes 23a and 23b suppresses shorting with the p-type well region 3p, the respective first parts 23a₁ and 23b₁ are made shallower than the bottoms of the main electrode regions 14a and 14b.

Each of the contact electrodes 23a and 23b contains an electrode material, such as tungsten, titanium, aluminum, molybdenum, polysilicon, or the like, for example. Each of the contact electrodes 23a and 23b containing these electrode materials basically has a greater thermal expansion coefficient than that of the silicon of the semiconductor part 5. Each of the contact electrodes 23a and 23b constituted by these electrode materials, and the semiconductor part 5, contract upon returning from high temperature to normal temperature during the manufacturing process.

Accordingly, providing the contact electrode 23a, which is connected to the semiconductor part 5 along the thickness direction of the semiconductor part 5, on the one side face 5b₃ of the two side faces 5b₃ and 5b₄ in the lengthwise direction of the semiconductor part 5 makes it possible to produce tensile stress St in the semiconductor part 5 in the gate length direction of the gate electrode 12 (the Y direction), i.e., in the direction in which the pair of main electrode regions 14a and 14b are arranged (the Y direction), as illustrated in FIG. 28. In this case, the first part 23a1 of the contact electrode 23a has an inherent compressive stress.

In addition, providing the contact electrode 23b, which is connected to the semiconductor part 5 along the thickness direction of the semiconductor part 5, on the other side face 5b₄ of the two side faces 5b₃ and 5b₄ in the lengthwise direction of the semiconductor part 5 makes it possible to produce tensile stress St in the semiconductor part 5 in the gate length direction of the gate electrode 12 (the Y direction), i.e., in the direction in which the pair of main electrode regions 14a and 14b are arranged (the Y direction), as illustrated in FIG. 28. In this case, the first part 23b₁ of the contact electrode 23b has an inherent compressive stress.

Note that as illustrated in FIG. 26, in the semiconductor part 5 of Embodiment 7, the width of each of the one end side (the side face 5b₃ side) and the other end side (the side face 5b₄ side) in the longer direction (the Y direction) is wider than the width of the part overlapping with the gate electrode 12 in plan view.

### <<Main Effects of Embodiment 7>>

In Embodiment 7, the semiconductor part 5 is provided with the n-channel conductivity type field effect transistor Q1. Accordingly, providing the contact electrodes 23a and 23b, which have a greater thermal expansion coefficient than the semiconductor part 5, on the side faces 5b₃ and 5b₄ of the semiconductor part 5 in the lengthwise direction (the Y direction) makes it possible to produce the tensile stress St in the semiconductor part 5 acting in the gate length direction of the gate electrode 12, which improves the carrier mobility and increases the current (the drain current Id) flowing from one to the other of the pair of main electrode regions 14a and 14b through the channel of the channel forming part 16.

Accordingly, the semiconductor apparatus 1G of Embodiment 7 can improve the mutual conductance (gm) of the n-channel conductivity type field effect transistor Q1, in the same manner as the semiconductor apparatus 1F of Embodiment 6.

In addition, because the mutual conductance of the field effect transistor Q1 can be improved, the circuit including the field effect transistor Q1 can be made faster, i.e., the semiconductor apparatus 1G can be made faster, in the same manner as in the foregoing Embodiment 6.

Although Embodiment 7 describes a case where the two contact electrodes 23a and 23b also function as a stress part, only one of the two electrodes may function as the stress part. However, as in Embodiment 7, when the two contact electrodes 23a and 23b also function as the stress part, the tensile stress St can be produced more effectively in the semiconductor part 5.

### <<Variations on Embodiment 7>>

### <Variation 7-1>

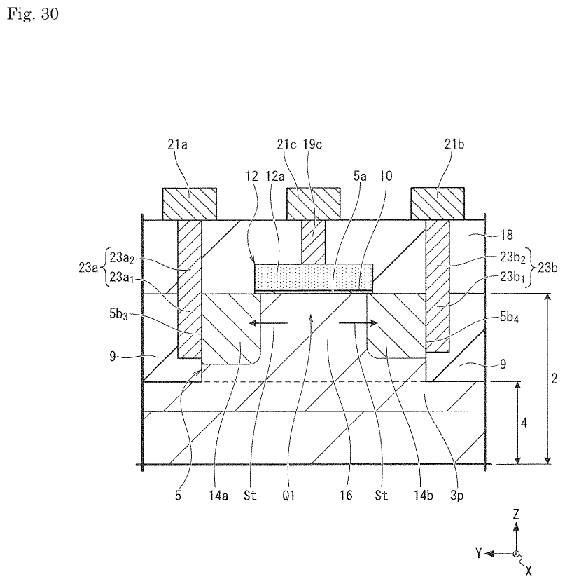

As illustrated in FIG. 30, each of the contact electrodes 23a and 23b, which also function as the stress part, may be connected to the semiconductor part 5 along the thickness direction of the semiconductor part 5 (the Z direction) on the outer sides of the side faces 5b₃ and 5b₄ in the lengthwise direction of the semiconductor part 5. The same effects as those of the foregoing Embodiment 7 can be achieved in this case as well.

Note that in the case of Variation 7-1 too, to suppress shorting with the p-type well region 3p, the first parts 23a₁ and 23b₁ of the contact electrodes 23a and 23b are made shallower than the bottoms of the main electrode regions 14a and 14b.

### <Variation 7-2>

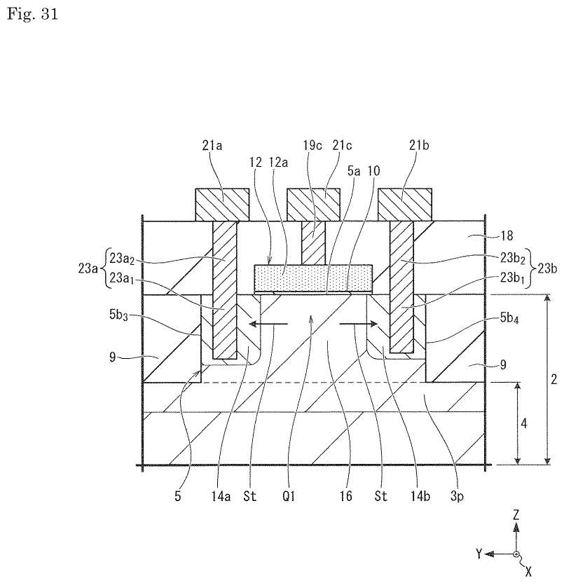

As illustrated in FIG. 31, in the contact electrodes 23a and 23b, which also function as a stress part, the first parts 23a₁ and 23b₁ may be provided in the main electrode regions 14a and 14b of the semiconductor part 5 such that the first parts 23a₁ and 23b₁ are connected to the semiconductor part 5 along the thickness direction of the semiconductor part 5 (the Z direction) on the outer sides of the gate electrode 12. In this case, the surface area of the connection between the first parts 23a₁ and 23b₁ of the contact electrodes 23b and 23a and the main electrode regions 14a and 14b can be increased.

Note that in the case of Variation 7-2 too, to suppress shorting with the p-type well region 3p, the first parts 23a₁ and 23b₁ of the contact electrodes 23a and 23b are made shallower than the bottoms of the main electrode regions 14a and 14b.

### <Variation 7-3>

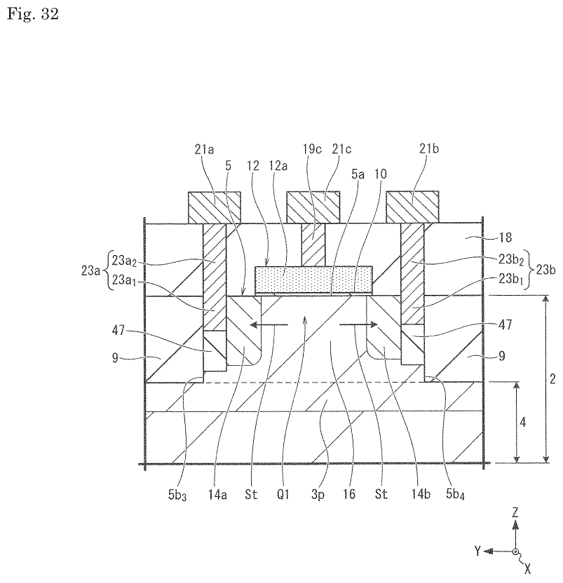

As illustrated in FIG. 32, Variation 7-3 combines the stress part 47 of the foregoing Embodiment 6 (FIGS. 17 to 19) with the contact electrodes 19a₁ and 19b₁ of the foregoing Embodiment 7. The stress part 47 is disposed at a position deeper than the contact electrodes 23a and 23b. The stress part 47 and the contact electrodes 23a and 23b overlap in plan view. In the case of Variation 7-3, setting the thermal expansion coefficient of the stress part 47 to be higher than the thermal expansion coefficient of the contact electrodes 23a and 23b makes it possible to produce the tensile stress St more effectively in the semiconductor part 5 than in the foregoing Embodiment 7.

### <Variation 7-4>

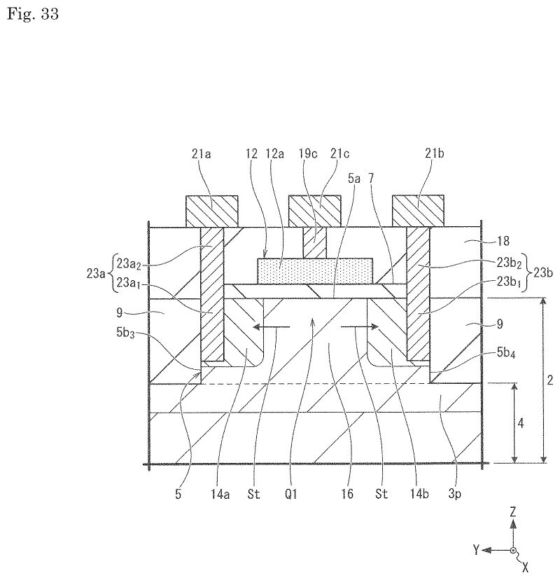

As illustrated in FIG. 33, Variation 7-4 combines the stress part 7 of the foregoing Embodiment 1 (FIGS. 1 to 3) with the foregoing Embodiment 7. In the case of Variation 7-4, the tensile stress St can be produced more effectively in the semiconductor part 5 than in the foregoing Embodiment 7 and Embodiment 1.

### <Variation 7-5>

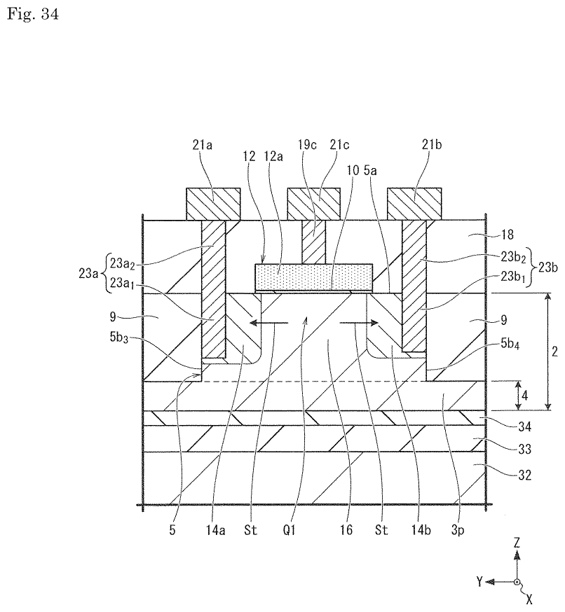

As illustrated in FIG. 34, Variation 7-5 combines the stress part 34 of the foregoing Embodiment 4 (FIGS. 9 to 11) with the foregoing Embodiment 7. In the case of Variation 7-5, the tensile stress St can be produced more effectively in the semiconductor part 5 than in the foregoing Embodiment 7.

### <Variation 7-6>

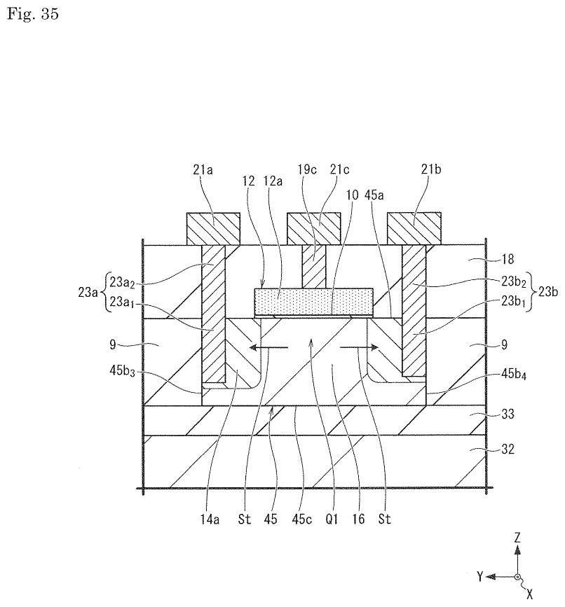

As illustrated in FIG. 35, Variation 7-6 combines the contact electrodes 23a and 23b of the foregoing Embodiment 7 with the semiconductor part 45 of the foregoing Embodiment 5 (FIGS. 13 to 15). Variation 7-5 achieves the same effects as those of the foregoing Embodiment 7.

<variation 7-7>

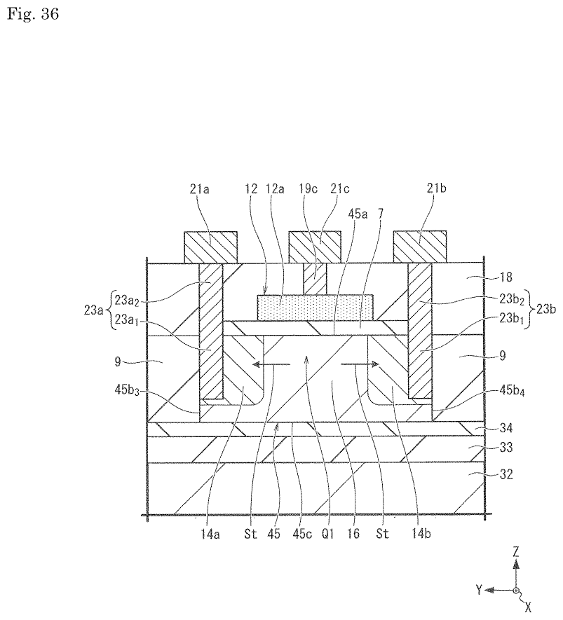

As illustrated in FIG. 36, Variation 7-7 combines the stress part 7 and the stress part 34 of the foregoing Embodiment 4 (FIGS. 9 to 11) with the foregoing Variation 7-6. In the case of Variation 7-7, the tensile stress St can be produced more effectively in the semiconductor part 45 than in the foregoing Embodiment 4.

The configuration may be such that one of the stress part 7 and the stress part 34 is combined with the foregoing Variation 7-6.

### <Variation 7-8>

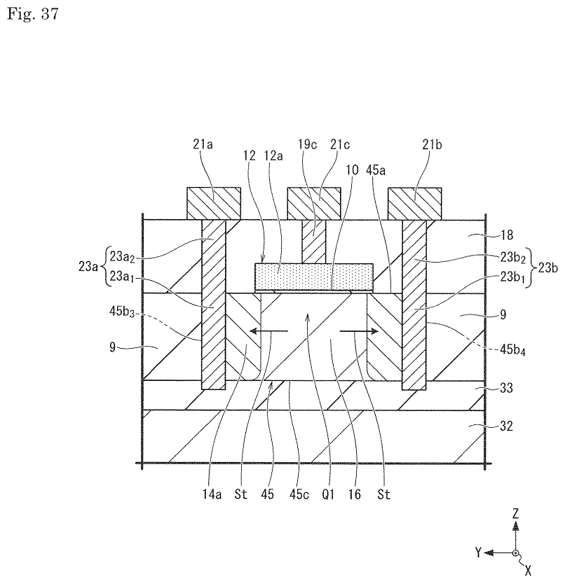

As illustrated in FIG. 37, in Variation 7-8, the tips of the contact electrodes 23a and 23b of Variation 7-6 are embedded in the insulating layer 33. In the case of Variation 7-8, the tensile stress St can be produced more effectively in the semiconductor part 45 than in the foregoing Variation 7-6.

### <Variation 7-9>

The contact electrodes 23a and 23b in the foregoing Embodiment 7 can also be applied in the semiconductor part 6 on which the p-channel conductivity type field effect transistor Q2 is mounted. The foregoing Variations 7-1 to 7-8 can also be applied in the semiconductor part 6 on which the p-channel conductivity type field effect transistor Q2 is mounted.

### Embodiment 8

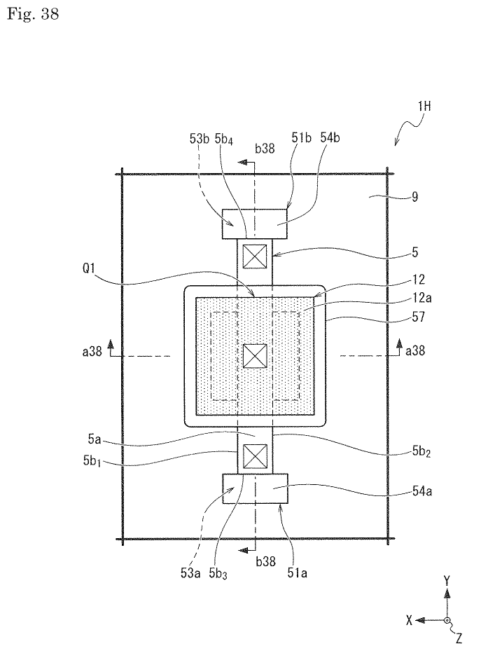

Referring to FIGS. 38 to 40, Embodiment 8 will describe an example in which the present technique is applied in a semiconductor apparatus having the n-channel conductivity type field effect transistor Q1 provided in the semiconductor part 5 having a three-dimensional shape.

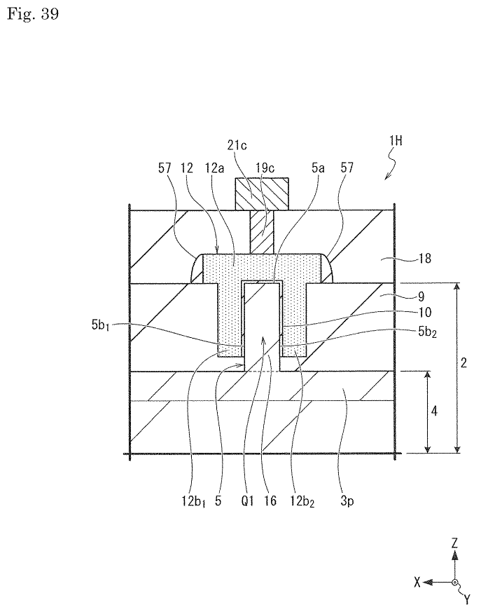

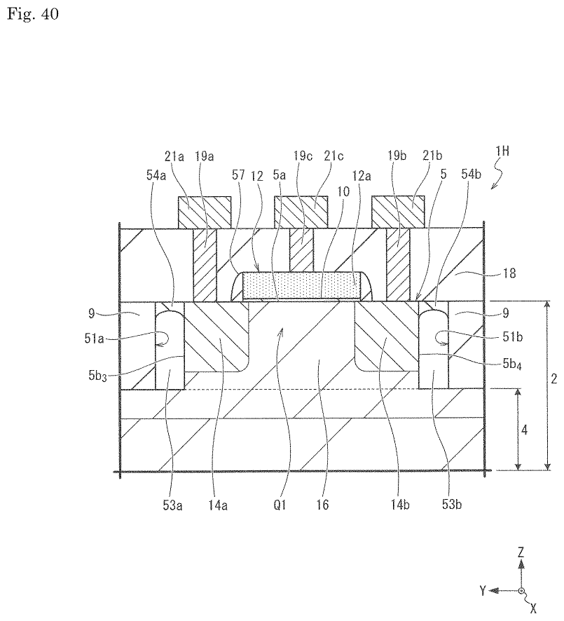

For the sake of simplicity, FIG. 38 does not illustrate the insulating layer 18, contact electrodes (19a, 19b, 19c), and interconnects (21a, 21b, 21c), which are illustrated in FIGS. 39 and 40.

### <<Overall Configuration of Semiconductor Apparatus>>

As illustrated in FIGS. 38 to 40, a semiconductor apparatus 1H according to Embodiment 8 of the present technique includes the semiconductor part 5 and the n-channel conductivity type field effect transistor Q1 provided in the semiconductor part 5. The semiconductor part 5 and the field effect transistor Q1 have the same configurations as in the foregoing Embodiment 1. In other words, the semiconductor part 5 is configured having a cuboid shape having the upper face 5a and the four side faces 5b₁, 5b₂, 5b₃, and 5b₄. The field effect transistor Q1 has the gate insulating film 10, the gate electrode 12, the pair of main electrode regions 14a and 14b, and the channel forming part 16 provided in the semiconductor part 5.

The semiconductor apparatus 1H according to Embodiment 8 of the present technique further includes the insulating layer 9 surrounding the semiconductor part 5, and two cavity parts 53a and 53b provided between the insulating layer 9 and the semiconductor part 5 in plan view.

The semiconductor apparatus 1H according to Embodiment 8 of the present technique further includes two trench parts 51a and 51b provided between the insulating layer 9 and the semiconductor part 5 in plan view, and two cover members 54a and 54b that individually block (cover) the open sides of the corresponding trench parts 51a and 51b. The other configurations are generally the same as those described in the foregoing Embodiment 1.

Unlike the field effect transistor Q1 of the foregoing embodiments, the field effect transistor Q1 according to Embodiment 8 further includes a side wall spacer 57 provided on a side wall of the tip part 12a of the gate electrode 12 so as to surround the tip part 12a.

### <Trench Parts and Cover Members>

As illustrated in FIGS. 38 and 40, the trench part 51a is provided on an outer side of the side face 5b₃ of the semiconductor part 5 in plan view. On the other hand, the trench part 51b is provided on the outer side of the side face 5b₄ of the semiconductor part 5 in plan view. In other words, the two trench parts 51a and 51b are provided on outer sides of the side faces 5b₃ and 5b₄, respectively, which are located in the lengthwise direction of the semiconductor part 5 (the gate length direction of the gate electrode 12; the Y direction).

Each of the two trench parts 51a and 51b can be formed by selectively etching the insulating layer 9. Although not limited thereto, for example, in Embodiment 8, the two trench parts 51a and 51b are formed adjacent to the side faces 5b₃ and 5b₄ of the semiconductor part 5 such that the side faces 5b₃ and 5b₄ of the semiconductor part 5 are exposed. In addition, each of the two trench parts 51a and 51b is formed at a depth that reaches the base part 4 from the upper face 5a side of the semiconductor part 5. Furthermore, the width of each of the two trench parts 51a and 51b is wider than the width of the semiconductor part 5 in the widthwise direction (the gate width direction of the gate electrode 12 in plan view; the X direction).

As illustrated in FIGS. 38 and 40, the cover member 54a blocks (covers) the insulating layer 18 side of the trench part 51a such that the cavity part 53a is formed within the trench part 51a. On the other hand, the cover member 54b blocks (covers) the insulating layer 18 side of the trench part 51b such that the cavity part 53b is formed inside the trench part 51b. Each of the two cover members 54a and 54b can individually block (cover) the open side of the corresponding one of the trench parts 51a and 51b, without filling the trench parts 51a and 51b, by using film having low coverage during film formation. A silicon nitride film can be used as the cover members 54a and 54b, for example.

### <Cavity Parts>

As illustrated in FIGS. 38 and 40, the cavity part 53a is provided within the trench part 51a. The cavity part 53a is surrounded by the side face of the insulating layer 9 and the side face 5b₃ of the semiconductor part 5 in the lengthwise direction of the semiconductor part 5 (the Y direction), and is surrounded by the cover member 54a and the base part 4 in the thickness direction of the semiconductor part 5 (the Z direction). On the other hand, the cavity part 53b is provided within the trench part 51b. The cavity part 53b is surrounded by the side face of the insulating layer 9 and the side face 5b₄ of the semiconductor part 5 in the lengthwise direction of the semiconductor part 5 (the Y direction), and is surrounded by the cover member 54b and the base part 4 in the thickness direction of the semiconductor part 5 (the Z direction). Each of the two cavity parts 53a and 53b can be formed in the manufacturing process by forming the trench parts 51a and 51b in the insulating layer 9, and then blocking (covering) the open sides of the trench parts 51a and 51b with the cover members 54a and 54b such that the trench parts 51a and 51b are not filled.

Each of the two cavity parts 53a and 53b is a stress suppression part that suppresses compressive stress acting on the semiconductor part 5 due to a difference between the thermal expansion coefficients of the semiconductor part 5 and the insulating layer 9. In Embodiment 8, the two cavity parts 53a and 53b are provided in the side faces 5b₃ and 5b₄, respectively, of the semiconductor part 5 in the lengthwise direction (the Y direction), and the insulating layer 9.

Accordingly, each of the two cavity parts 53a and 53b suppresses compressive stress acting in the lengthwise direction of the semiconductor part 5 due to a difference between the thermal expansion coefficients of the semiconductor part 5 and the insulating layer 9.

As illustrated in FIG. 38, each of the two cavity parts 53a and 53b is wider than the width of the gate electrode 12 in the gate length direction (the X direction) in plan view. In addition, as illustrated in FIG. 40, each of the two cavity parts 53a and 53b extends along the thickness direction of the semiconductor part 5 (the Z direction).

Note that a buffer insulating film may be provided along inner wall parts (side wall parts and bottom wall parts) of the trench parts 51a and 51b.

### <<Method for Manufacturing Semiconductor Apparatus>>

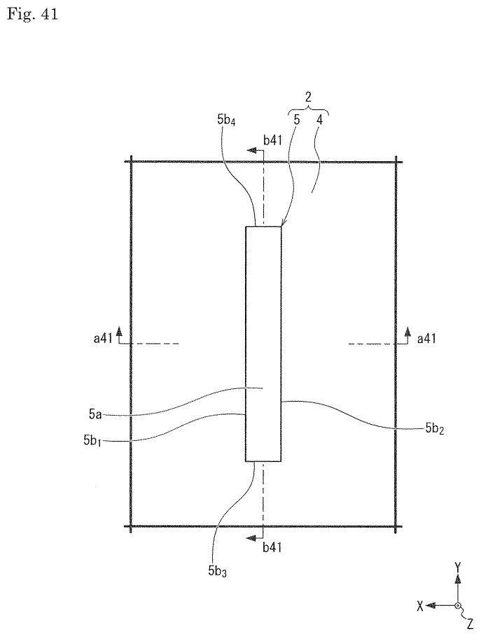

A method for manufacturing the semiconductor apparatus 1H according to Embodiment 8 will be described next with reference to FIGS. 41 to 67.

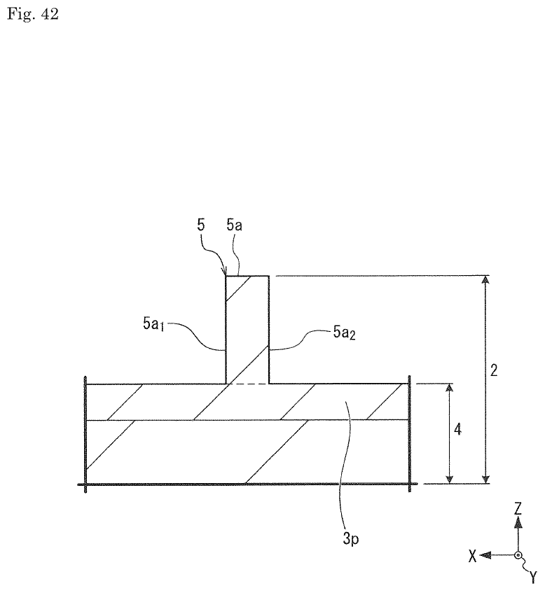

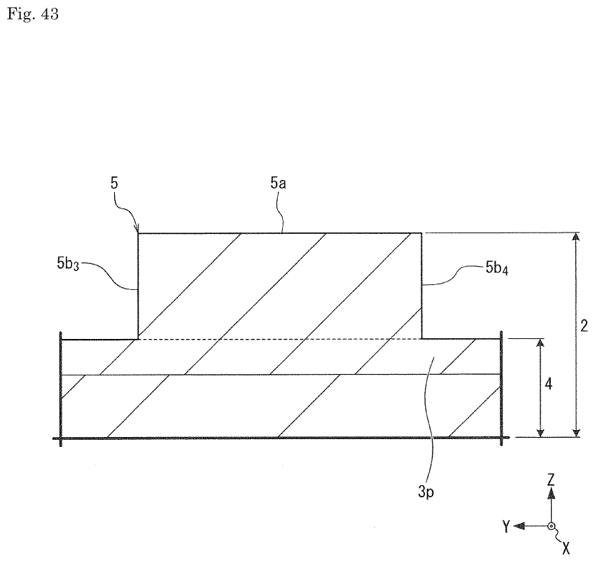

First, as illustrated in FIG. 41 (a schematic plan view), FIG. 42 (a schematic longitudinal cross-sectional view along the line a41-a41 in FIG. 41), and FIG. 43 (a schematic longitudinal cross-sectional view along the line b41-b41 in FIG. 41), the semiconductor part 5 having a three-dimensional shape protruding upward from the base part 4 is formed.

Although not limited thereto, the semiconductor part 5 is configured having a cuboid shape integrated with the base part 4, for example, and includes the upper face 5a and four side faces 5b₁, 5b₂, 5b₃, and 5b₄. The semiconductor part 5 extends such that the lengthwise direction is the Y direction in plan view.

Of the four side faces 5b₁, 5b₂, 5b₃, and 5b₄ of the semiconductor part 5, the two side faces 5b₁ and 5b₂ are located opposite to each other in the widthwise direction of the semiconductor part 5 (the X direction). The remaining two side faces 5b₃ and 5b₄ are located opposite to each other in the lengthwise direction of the semiconductor part 5 (the Y direction). The upper face 5a is located on the side of the semiconductor part 5 opposite from the side where the base part 4 is located, in the thickness direction of the semiconductor layer 2 (the Z direction). The semiconductor part 5 can be formed by selectively etching the semiconductor layer 2 to a depth at which the base part 4 remains. Although not limited thereto, the semiconductor layer 2 uses a semiconductor substrate that, for example, takes silicon (Si) as the semiconductor material, a single crystal as the crystal, and p-type as the conductivity type.

Note that the p-type well region 3p constituted by a p-type semiconductor region is formed in the semiconductor layer 2 before the semiconductor part 5 is formed.

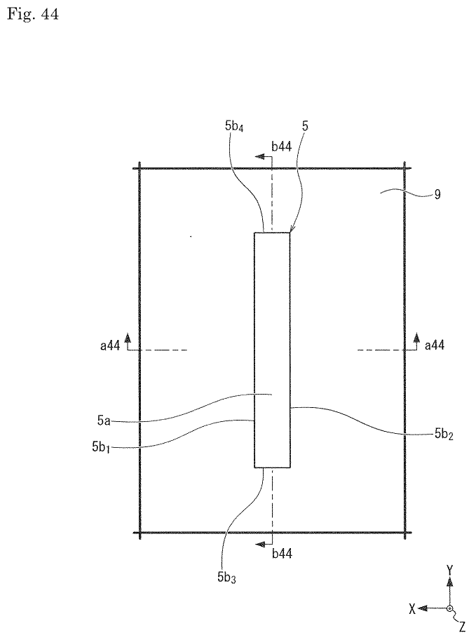

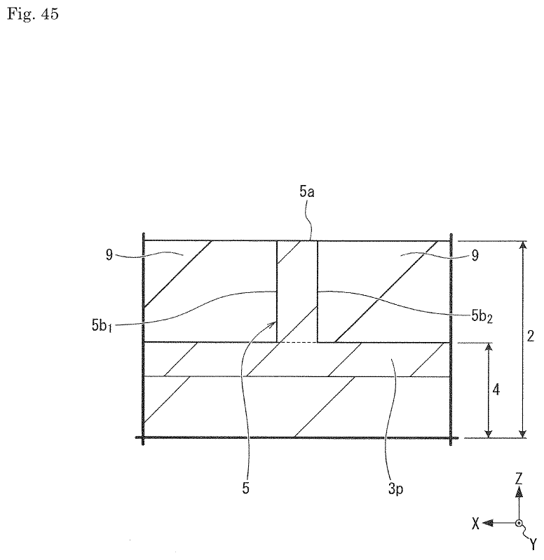

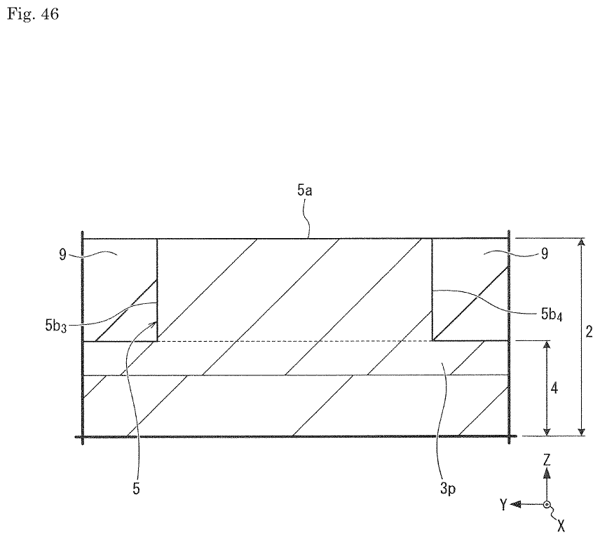

Next, as illustrated in FIG. 44 (a schematic plan view), FIG. 45 (a schematic cross-sectional view along the line a44-a44 in FIG. 44), and FIG. 46 (a schematic cross-sectional view along the line b44-b44 in FIG. 44), the insulating layer 9 that surrounds the periphery of the semiconductor part 5 on the outer side of the semiconductor part 5 in plan view is formed. The insulating layer 9 can be formed, for example, by forming a silicon oxide film on the entire surface, including the base part 4 and the semiconductor part 5 of the semiconductor layer 2, through a well-known film forming method, and then selectively removing the silicon oxide film on the semiconductor part 5 through CMP.

In this step, the upper face on the side of the insulating layer 9 opposite from the side where the base part 4 is located is flattened, and the upper face of the insulating layer 9 and the upper face 5a of the semiconductor part 5 become substantially flush with each other. The insulating layer 9 is formed at a thickness approximately equal to the height of the semiconductor part 5 (the protrusion amount).

Additionally, in this step, each of the four side faces 5b₁, 5b₂, 5b₃, and 5b₄ of the semiconductor part 5 is adjacent to the insulating layer 9.

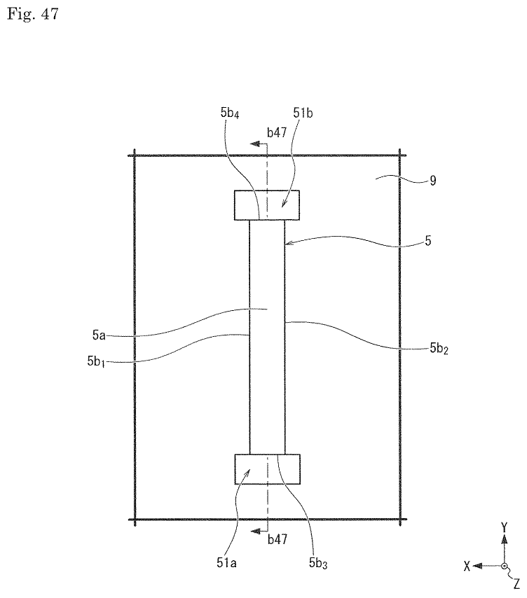

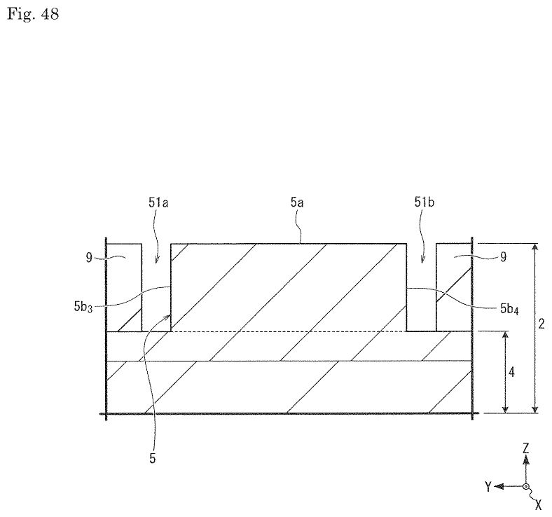

Next, as illustrated in FIG. 47 (a schematic plan view) and FIG. 48 (a schematic cross-sectional view along the line b47-b47 in FIG. 47), the trench parts 51a and 51b are formed on the outer sides of both ends of the semiconductor part 5 in the lengthwise direction (the Y direction) (the side faces 5b₃ and 5b₄).

Each of the two trench parts 51a and 51b can be formed by selectively etching the insulating layer 9 using a well-known photolithography technique and dry etching technique. Although not limited thereto, for example, in Embodiment 8, the trench parts 51a and 51b are formed adjacent to the side faces 5b₃ and 5b₄ of the semiconductor part 5 such that the side faces 5b₃ and 5b₄ of the semiconductor part 5 are exposed. In addition, each of the two trench parts 51a and 51b is formed at a depth that reaches the base part 4 from the upper face 5a side of the semiconductor part 5. In addition, each of the two trench parts 51a and 51b is formed such that the width thereof in the same direction as the widthwise direction of the semiconductor part 5 (the X direction) is wider than the width of the semiconductor part 5 in the widthwise direction (the X direction).

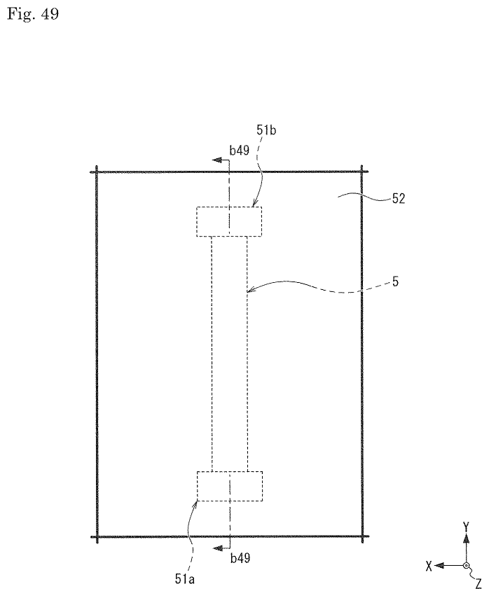

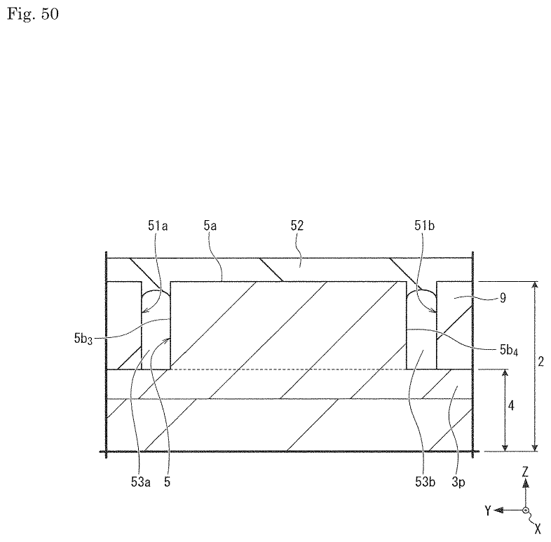

Next, as illustrated in FIG. 49 (a schematic plan view) and FIG. 50 (a schematic cross-sectional view along the line b49-b49 in FIG. 49), the cavity parts 53a and 53b are formed in the two trench parts 51a and 51b, respectively, by forming a deposition film 52 on the entire surface of the upper face side of the semiconductor layer 2 so as to cover the open sides of the two trench parts 51a and 51b. The deposition film 52 is formed such that the open sides of the trench parts 51a and 51b are blocked, but the interiors of the trench parts 51a and 51b are not filled. Such cavity parts 53a and 53b can be formed by using a silicon nitride film having low coverage as the deposition film 52, for example.

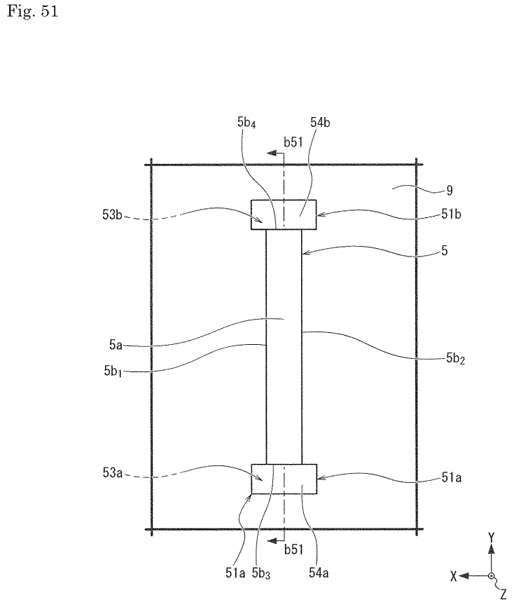

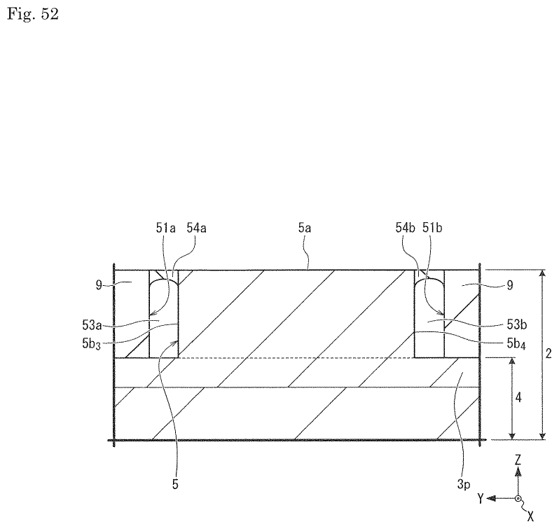

Next, the deposition film 52 on the upper face 5a of the semiconductor part 5 and the upper face of the insulating layer 9 is selectively removed to form the cover members 54a and 54b that block the respective openings on the open sides of the trench parts 51a and 51b, as illustrated in FIG. 51 (a schematic plan view) and FIG. 52 (a schematic cross-sectional view along the line b51-b51 in FIG. 51).

In this step, the cavity part 53a, which is surrounded by the side face of the insulating layer 9, the side face 5b₃ of the semiconductor part 5, the base part 4, and the cover member 54a is formed between the side face 5b₃ of the semiconductor part 5 and the insulating layer 9 in plan view. Additionally, the cavity part 53a, which is surrounded by the side face of the insulating layer 9, the side face 5b₃ of the semiconductor part 5, the base part 4, and the cover member 54a is formed between the side face 5b₄ of the semiconductor part 5 and the insulating layer 9 in plan view.

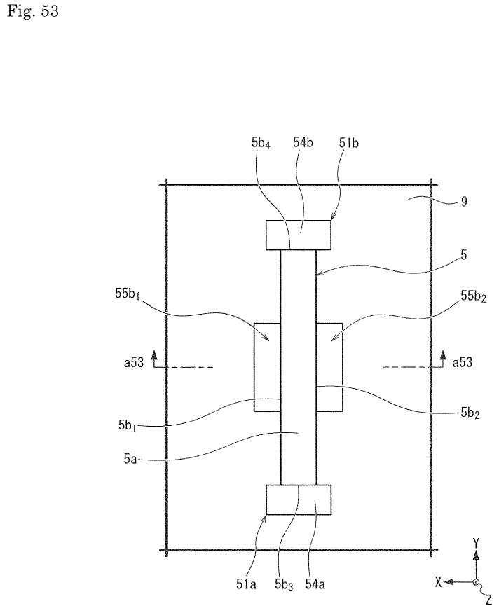

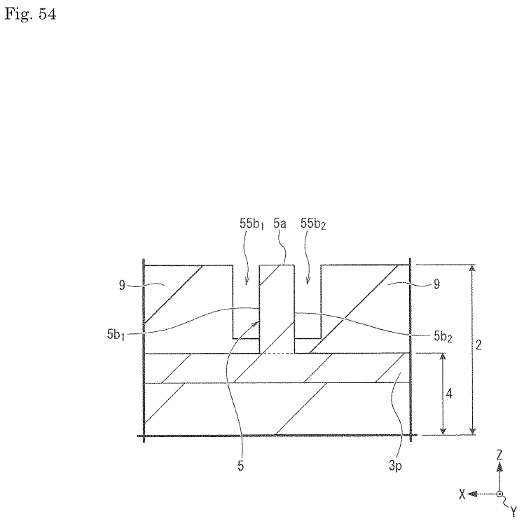

Next, the insulating layer 9 on the outer side of the semiconductor part 5 in the widthwise direction (the X direction) is selectively removed, and as illustrated in FIG. 53 (a schematic plan view) and FIG. 54 (a schematic cross-sectional view along the line a53-a53 in FIG. 53), the trench part 55b₁ that exposes the side face 5b1 of the semiconductor part 5, and the trench part 55b₂ that exposes the side face 5b2 of the semiconductor part 5, are formed individually on the outer side of the semiconductor part 5 in the widthwise direction thereof.

Each of the two trench parts 55b₁ and 55b₂ can be formed by selectively etching the insulating layer 9 using a well-known photolithography technique and dry etching technique. Each of the two trench parts 55b₁ and 55b₂ is formed at a depth separated from the base part 4 of the semiconductor layer 2.

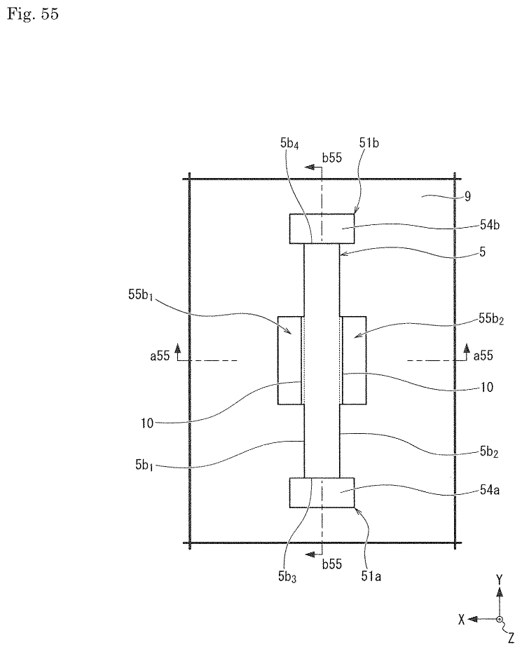

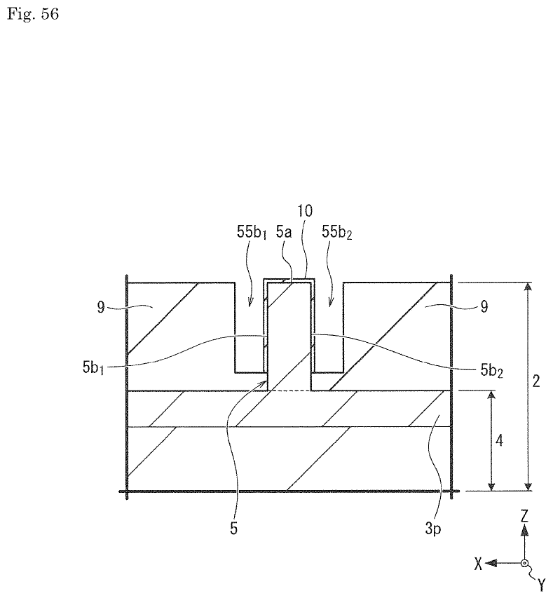

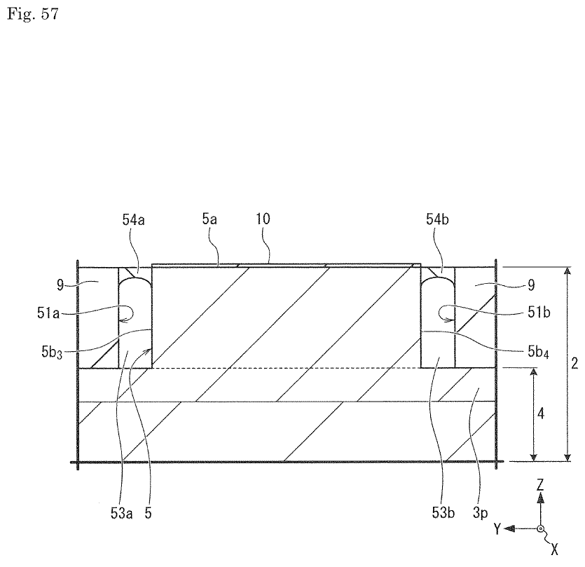

Next, as illustrated in FIG. 55 (a schematic plan view of primary elements), FIG. 56 (a schematic cross-sectional view along the line a55-a55 in FIG. 55), and FIG. 57 (a schematic cross-sectional view along the line b55-b55 in FIG. 55), the gate insulating film 10 is formed across the upper face 5a and the two side faces 5b₁ and 6b₂ of the semiconductor part 5. The gate insulating film 10 can be formed through thermal oxidation or deposition, for example. A silicon oxide film can be used as the gate insulating film 10, for example.

In this step, the gate insulating film 10 is selectively formed in each of the two side faces 5b₁ and 5b₂ of the semiconductor part 5, within the two trench parts 55b₁ and 55b₂, respectively.

Note that because the side faces 5b₃ and 5b₄ in the lengthwise direction of the semiconductor part 5 (the Y direction) are located in the closed cavity parts 53a and 53b, respectively, the gate insulating film 10 is basically not formed in the side faces 5b₃ and 5b₄ of the semiconductor part 5.

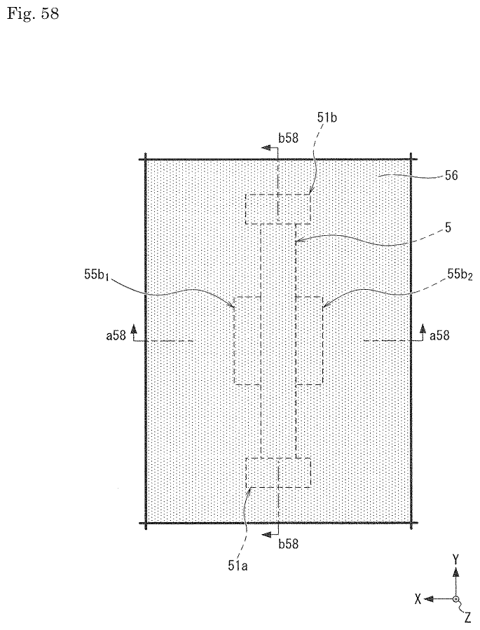

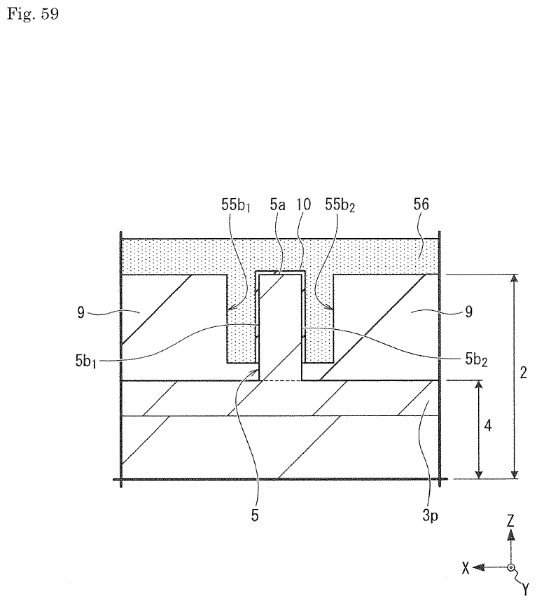

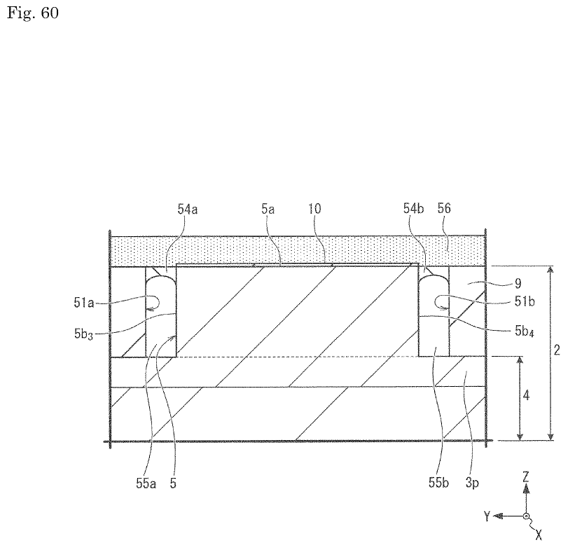

Next, as illustrated in FIG. 58 (a schematic plan view of the primary elements), FIG. 59 (a schematic cross-sectional view along the line a58-a58 in FIG. 58), and FIG. 60 (a schematic cross-sectional view along the line b58-b58 in FIG. 58), a conductive film 56 is formed on the entire surface of the semiconductor layer 2, including the interiors of the trench parts 55b₁ and 55b₂, the upper face 5a of the semiconductor part 5, and the upper face of the insulating layer 9. A polycrystal silicon into which impurities that reduce the resistance value are introduced during or after film formation (doped polysilicon) can be used as the conductive film 56, for example. Where the gate insulating film 10 is formed in the semiconductor part 5, the gate insulating film 10 is interposed between the semiconductor part 5 and a conductive film 14.

Because the upper face sides of the trench parts 51a and 51b are blocked by the cover members 54a and 54b, respectively, in this step, the conductive film 56 is not formed within the trench parts 51a and 51b, i.e., within the cavity parts 53a and 53b.

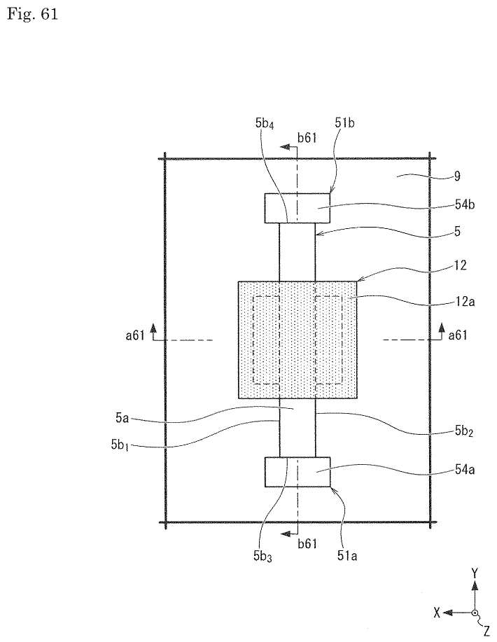

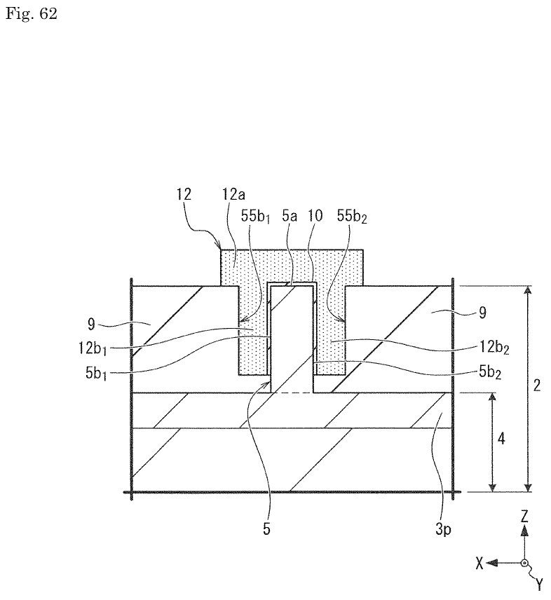

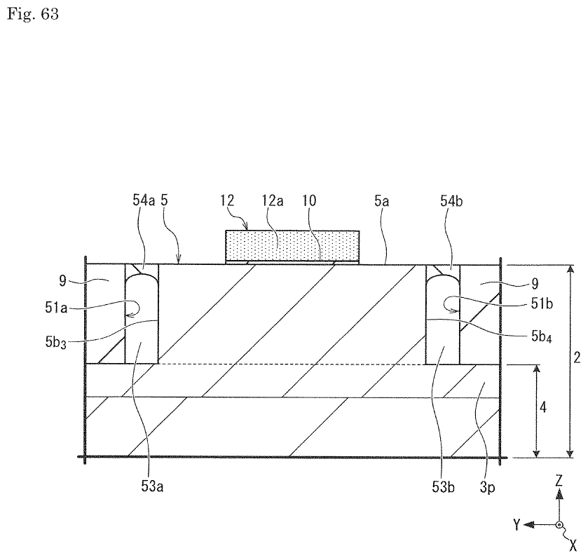

Next, the conductive film 56 is patterned using well-known photolithography and dry etching techniques, and the gate electrode 12 that faces the upper face 5a and the two side faces 5b₁ and 5b₂ of the semiconductor part 5 with the gate insulating film 10 interposed therebetween is formed, as illustrated in FIG. 61 (a schematic plan view of the primary elements), FIG. 62 (a schematic cross-sectional view along the line a61-a61 in FIG. 61), and FIG. 63 (a schematic cross-sectional view along the line b61-b61 in FIG. 61).

The gate electrode 12 has the tip part 12a provided on the upper face 5a side of the semiconductor part 5 with the gate insulating film 10 interposed therebetween; and the leg parts 12b₁ and 12b₂ which are formed integrally with the tip part 12a, and which on the outer sides of the two side faces 5b₁ and 5b₂, respectively, of the semiconductor part 5 with the gate insulating film 10 interposed therebetween. The tip part 12a is formed protruding from the insulating layer 9. The leg parts 12b₁ and 12b₂ are individually formed in the trench parts 55b₁ and 55b₂ so as to be connected to the tip part 12a.

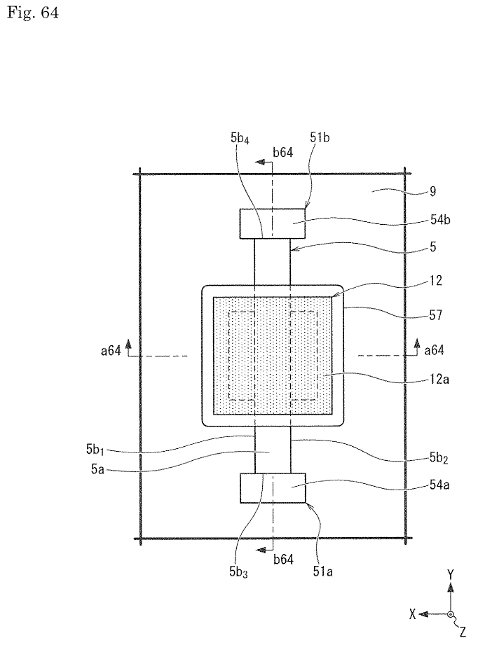

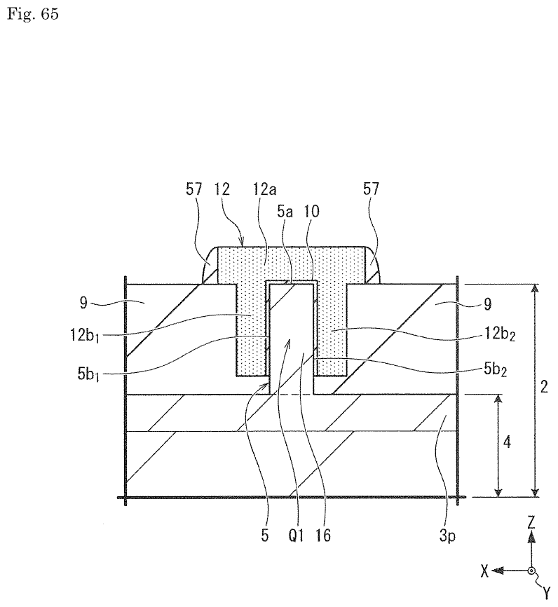

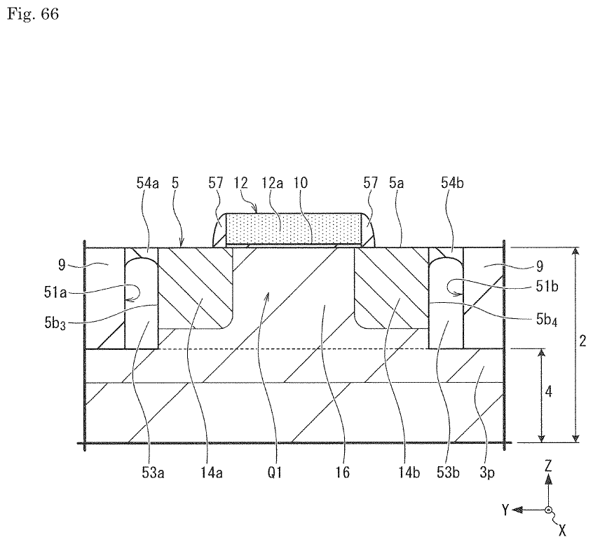

Next, as illustrated in FIG. 64 (a schematic plan view of the primary elements), FIG. 65 (a schematic cross-sectional view along the line a64-a64 in FIG. 64), and FIG. 66 (a schematic cross-sectional view along the line b64-b64 in FIG. 64), the pair of main electrode regions 14a and 14b constituted by n-type semiconductor regions, and the side wall spacer 57 that surrounds the periphery of the tip part 12a of the gate electrode 12 on the side faces of the tip part 12a, are formed in the semiconductor part 5 on both sides thereof in the gate length direction of the gate electrode 12 (the Y direction).

The pair of n-type main electrode regions 14a and 14b function as a source region and a drain region. The pair of n-type main electrode regions 14a and 14b can be formed by using the gate electrode 12, the insulating layer 9, and the cover members 54a and 54b as a mask for introducing impurities, implanting ions such as arsenic ions (As⁺) or phosphorus ions (P⁺) as impurities that exhibit n-type conductivity in the semiconductor part 5 on both sides thereof in the gate length direction of the gate electrode 12 (the Y direction), and then applying heat treatment to activate the impurities. The pair of main electrode regions 14a and 14b are formed in alignment with the gate electrode 12 in the semiconductor part 5.

Because the upper face sides of the trench parts 51a and 51b are blocked by the cover members 54a and 54b, respectively, in this step, impurities are not introduced into the trench parts 51a and 51b, i.e., into the cavity parts 53a and 53b.

The side wall spacer 57 can be formed by forming an insulating film over the entire upper face of the semiconductor layer 2 through CVD so as to cover the semiconductor part 5, the insulating layer 9, and the tip part 12a of the gate electrode 12, and then performing anisotropic dry etching such as RIE on the insulating film. A silicon oxide film can be used as the insulating film, for example.

Because the upper face sides of the trench parts 51a and 51b are blocked by the cover members 54a and 54b, respectively, in this step, the insulating film is not formed within the trench parts 51a and 51b, i.e., within the cavity parts 53a and 53b.

In this step, the channel forming part 16, which overlaps with the gate electrode 12 in plan view, is formed in the semiconductor part 5 between the pair of main electrode regions 14a and 14b.

In addition, in this step, the n-channel conductivity type field effect transistor Q1, including the gate insulating film 10, the gate electrode 12, the pair of main electrode regions 14a and 14b, the channel forming part 16, the side wall spacer 57, and the like, is formed in the semiconductor part 5.

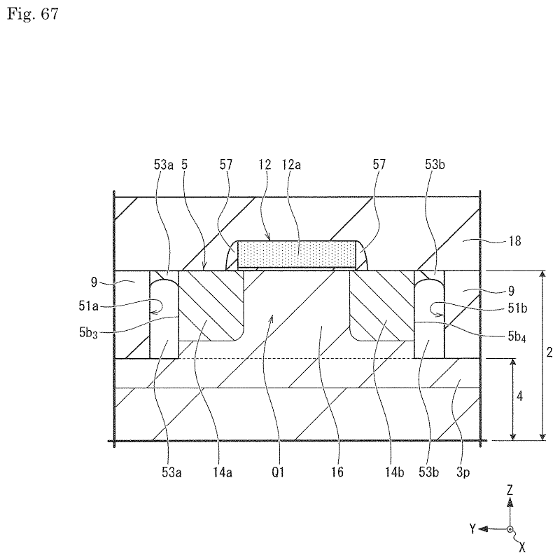

Next, as illustrated in FIG. 67 (a schematic longitudinal cross-sectional view from the same position as the line b64-b64 in FIG. 64), the insulating layer 18 covering the semiconductor part 5, the insulating layer 9, and the tip part 12a of the gate electrode 12 is formed on the insulating layer 9 side of the semiconductor layer 2. The insulating layer 18 can be formed by forming a silicon oxide film, for example, as an insulating film over the entire upper face of the semiconductor layer 2 so as to cover the semiconductor part 5, the insulating layer 9, and the tip part 12a of the gate electrode 12, and then flattening the surface of the silicon oxide film through CMP or the like.

Because the upper face sides of the trench parts 51a and 51b are covered by the cover members 54a and 54b, respectively, in this step, the formation of the silicon oxide film within the trench parts 51a and 51b, i.e., within the cavity parts 53a and 53b, can be suppressed.

Next, the contact electrodes 19a, 19b, and 19c and the like are formed in the insulating layer 18, and then interconnect layer, serving as the first layer including the interconnects 21a, 21b, and 21c and the like, is formed on the upper face of the insulating layer 18, resulting in the state illustrated in FIGS. 38 to 40.

After forming the side wall spacer 57, the tip part 12a of the gate electrode 12 and the side wall spacer 57 may be used as a mask for introducing impurities to implant ions such as arsenic ions (As+) or phosphorus ions (P+) as impurities that exhibit n-type conductivity in the semiconductor part 5 on both sides thereof in the gate length direction of the gate electrode 12 (the Y direction). The semiconductor part on the outer sides in the gate length direction of the gate electrode may then be subjected to heat treatment to activate the impurities, and the pair of contact regions constituted of n type semiconductor regions having a higher impurity concentration than the pair of main electrode regions may be formed.

### <<Main Effects of Embodiment 8>>

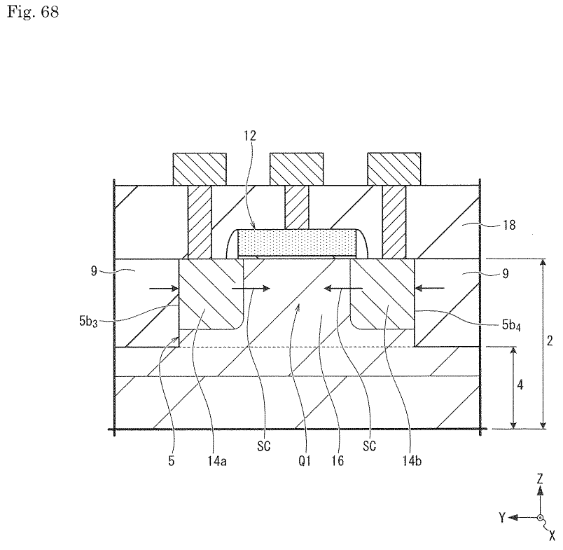

The main effects of Embodiment 8 will be described next with comparison to a reference example illustrated in FIG. 68.

As illustrated in FIG. 68, in the semiconductor apparatus of the reference example, the two side faces 5b₃ and 5b₄ located in the lengthwise direction of the semiconductor part 5 (the Y direction) and the insulating layer 9 provided around the semiconductor part 5 are adjacent to and in contact with each other. A silicon oxide (SiO₂) film having a smaller thermal expansion coefficient than that of the silicon of the semiconductor part 5 is normally used as the insulating layer 9. In this case, the compressive stress Sc along the lengthwise direction of the semiconductor part 5 (the Y direction) acts on the semiconductor part 5 due to the difference between the thermal expansion coefficients of the semiconductor part 5 and the insulating layer 9. In the n-channel conductivity type field effect transistor Q1, such compressive stress Sc along the Y direction acting on the semiconductor part 5 is a factor that reduces the current (the drain current Id) flowing from one to the other of the pair of main electrode regions 14a and 14b through the channel forming part 16, i.e., reduces the mobility of carriers moving from one to the other of the pair of main electrode regions 14a and 14b through the channel forming part 16.

In contrast, as illustrated in FIG. 40, in the semiconductor apparatus 1H according to Embodiment 8, the cavity parts 53a and 53b are provided between the two side faces 5b₃ and 5b₄, which are located in the lengthwise direction of the semiconductor part 5 (the Y direction), and the insulating layer 9.

Accordingly, the compressive stress Sc along the lengthwise direction of the semiconductor part 5 (the Y direction), which acts on the semiconductor part 5 due to the difference between the thermal expansion coefficients of the semiconductor part 5 and the insulating layer 9, can be suppressed. As such, in the n-channel conductivity type field effect transistor Q1, a reduction in the current (the drain current Id) flowing from one to the other of the pair of main electrode regions 14a and 14b through the channel forming part 16, i.e., a reduction in the mobility of carriers moving from one to the other of the pair of main electrode regions 14a and 14b through the channel forming part 16, can be suppressed.

Therefore, compared to the reference example, the semiconductor apparatus 1H according to Embodiment 8 makes it possible to improve the mutual conductance (gm) of the n-channel conductivity type field effect transistor Q1.

In addition, because the mutual conductance (gm) of the field effect transistor Q1 can be improved, the circuit including the field effect transistor Q1 can be made faster, and the semiconductor apparatus 1A can therefore be made faster.

In addition, according to the method for manufacturing the semiconductor apparatus 1H according to Embodiment 8, the cavity parts 63a and 63b can be formed between the two side faces 5b₃ and 5b₄, which are located in the lengthwise direction of the semiconductor part 5 (the Y direction), and the insulating layer 9.

Although the foregoing Embodiment 8 described a case where the cavity parts 53a and 53b are provided separately between the two side faces 5b₃ and 5b₄, which are located in the lengthwise direction of the semiconductor part 5 (the Y direction), and the insulating layer 9, a cavity part may instead be provided between one of the two side faces 5b₃ and 5b₄ and the insulating layer 9.

However, providing the cavity parts 53a and 53b between the two side faces 5b₃ and 5b₄ and the insulating layer 9 makes it possible to more effectively suppress the compressive stress Sc acting on the semiconductor part 5.

Although the foregoing Embodiment 8 described a case where the cavity parts 53a and 53b are applied in the semiconductor part 5 on which the n-channel conductivity type field effect transistor Q1 is mounted, to describe with reference to FIGS. 5 to 7 of the foregoing Embodiment 2, the cavity parts 53a and 53b can also be applied in the semiconductor part 6 on which the p-channel conductivity type field effect transistor Q2 is mounted.

The cavity parts 53a and 53b of Embodiment 8 can also be applied in the SOI-structure semiconductor part 45 described in the foregoing Embodiment 5 (FIGS. 13 to 15).

### <<Variations on Embodiment 8>>

Although the foregoing Embodiment 8 described a case where the cavity parts 53a and 53b are provided between the side faces 5b₃ and 5b₄ of the semiconductor part 5 in the lengthwise direction (the Y direction) thereof and the insulating layer 9, the present technique is not limited to the foregoing Embodiment 8.

### <Variation 8-1>

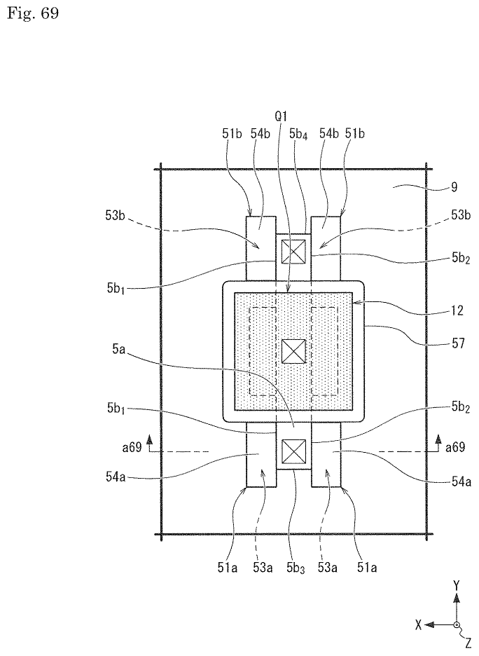

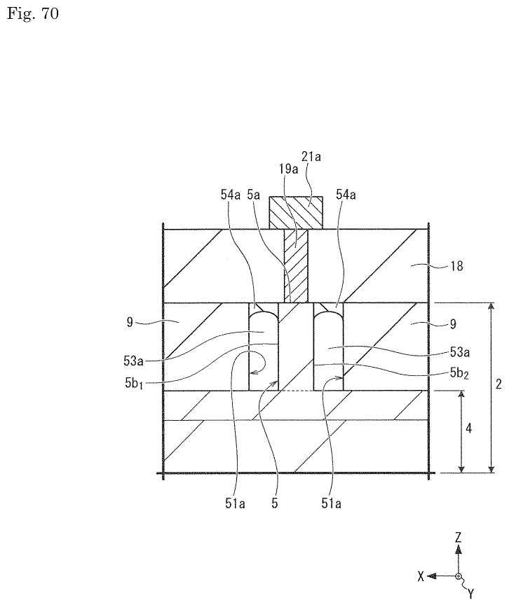

For example, as illustrated in FIGS. 69 and 70, the cavity parts 53a and 53b may be provided between the two side faces 5b₁ and 5b₂ of the semiconductor part 5 in the widthwise direction (the X direction) thereof in plan view and the insulating layer 9. In this case too, the cavity part may also be provided on one or the other end side of the semiconductor part 5 in the lengthwise direction thereof.

### <Variation 8-2>

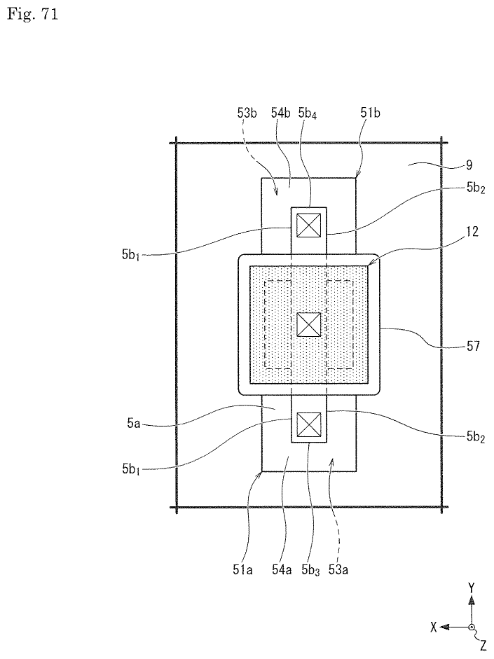

In addition, as illustrated in FIG. 71, the trench parts 51a and 51b may be formed on the outer sides of corresponding ones of the two side faces 5b₃ and 5b₄ located in the lengthwise direction of the semiconductor part 5 (the Y direction), and on the outer sides of corresponding ones of the two side faces 5b₁ and 5b₂ located in the widthwise direction of the semiconductor part 5 (the X direction); and a cavity part may be provided between (i) the two side faces 5b₁ and 5b₂ and the two side faces 5b₃ and 5b₄ of the semiconductor part 5 and (ii) the insulating layer 9. In this case too, the cavity part may also be provided on one or the other end side of the semiconductor part 5 in the lengthwise direction thereof.

### Embodiment 9

Embodiment 9 will describe an example in which the present technique is applied in a semiconductor apparatus 1I having an n-channel conductivity type field effect transistor Q1 provided in a semiconductor part 5 having a three-dimensional shape.

### <<Overall Configuration of Semiconductor Apparatus>>

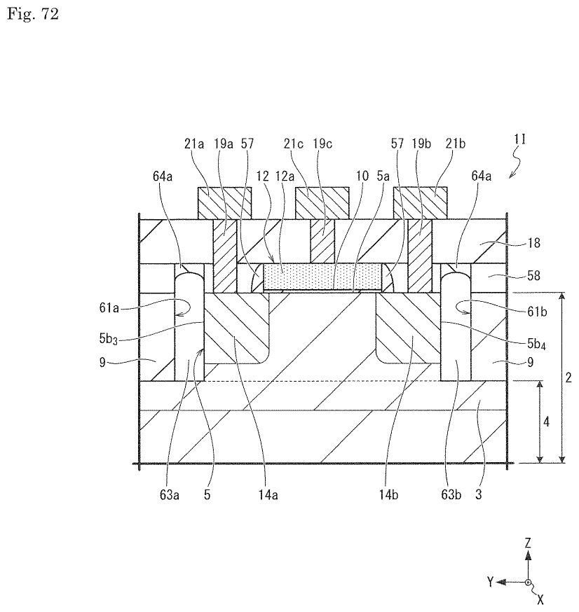

As illustrated in FIG. 72, the semiconductor apparatus 1I according to Embodiment 9 of the present technique has basically the same configuration as the semiconductor apparatus 1H according to the foregoing Embodiment 8, with the exception of the following configurations.

First, as illustrated in FIG. 72, the semiconductor apparatus 1I according to Embodiment 9 of the present technique includes trench parts 61a and 61b, cavity parts 63a and 63b, and cover members 64a and 64b, instead of the trench parts 51a and 51b, the cavity parts 53a and 53b, and the cover members 54a and 54b illustrated in FIG. 40 of the foregoing Embodiment 8. Furthermore, the semiconductor apparatus 1I according to Embodiment 9 of the present technique further includes an insulating layer 58 provided between (i) the semiconductor part 5 and the insulating layer 9 and (ii) the insulating layer 18 in the upper layer.

### <insulating Layer>

As illustrated in FIG. 72, the insulating layer 58 is provided across the semiconductor part 5 and the insulating layer 9 on the upper face 5a side of the semiconductor part 5 and the upper face side of the insulating layer 9. The insulating layer 58 surrounds the periphery of the tip part 12a of the gate electrode 12 protruding further upward than the semiconductor part 5 and the insulating layer 9. The upper face of the insulating layer 58 on the side opposite from the side where the semiconductor layer 2 is located is flattened. The insulating layer 58 alleviates a level difference between the insulating layer 9 and the tip part 12a of the gate electrode 12, and flattens the upper face side of the semiconductor layer 2. The insulating layer 58 is constituted by a silicon oxide film, for example.

### <Trench Parts and Cover Members>

As illustrated in FIG. 72, the trench part 61a is provided on an outer side of the side face 5b3 of the semiconductor part 5 in plan view, extending across the insulating layers 58 and 9 in the Z direction. On the other hand, the trench part 61b is provided on an outer side of the side face 5b4 of the semiconductor part 5 in plan view, extending across the insulating layers 58 and 9. In other words, like the trench parts 51a and 51b of the foregoing Embodiment 1, the two trench parts 61a and 61b are provided on outer sides of the side faces 5b₃ and 5b₄, respectively, which are located in the lengthwise direction of the semiconductor part 5 (the gate length direction of the gate electrode 12; the Y direction).

Each of the two trench parts 61a and 61b can be formed by selectively etching the insulating layers 58 and 9. Although not limited thereto, for example, in Embodiment 9, the two trench parts 61a and 61b are formed adjacent to the side faces 5b₃ and 5b₄ of the semiconductor part 5 such that the side faces 5b₃ and 5b₄ of the semiconductor part 5 are exposed. In addition, each of the two trench parts 61a and 61b is formed at a depth that reaches the base part 4 from the upper face side of the insulating layer 58 opposite from the side where the semiconductor layer 2 is located. Furthermore, like the trench parts 51a and 51b of the foregoing Embodiment 8, the width of each of the two trench parts 61a and 61b is wider than the width of the semiconductor part 5 in the widthwise direction (the gate width direction of the gate electrode 12 in plan view; the X direction). The open sides of the two trench parts 61a and 61b are blocked by the cover members 64a and 64b, respectively.

As illustrated in FIG. 72, the cover member 64a blocks (covers) the insulating layer 58 side of the trench part 61a such that the cavity part 63a is formed inside the trench part 61a. On the other hand, the cover member 64b blocks (covers) the insulating layer 58 side of the trench part 61b such that the cavity part 63b is formed inside the trench part 61b. Like the cover members 54a and 54b of the foregoing Embodiment 8, each of the two cover members 64a and 64b can individually block (cover) the open side of the corresponding one of the trench parts 61a and 61b, without filling the trench parts 61a and 61b, by using film having low coverage during film formation. A silicon nitride film can be used as the cover members 64a and 64b, for example.

<cavity Parts>

The cavity part 63a is provided within the trench part 61a. The cavity part 63a is surrounded by the side faces of the insulating layer 58 and the insulating layer 9 and the side face 5b3 of the semiconductor part 5 in the lengthwise direction of the semiconductor part 5 (the Y direction), and is surrounded by the cover member 64a and the base part 4 in the thickness direction of the semiconductor part 5 (the Z direction). On the other hand, the cavity part 63b is provided within the trench part 61b. The cavity part 63b is surrounded by the side faces of the insulating layers 58 and 9 and the side face 5b4 of the semiconductor part 5 in the lengthwise direction of the semiconductor part 5 (the Y direction), and is surrounded by the cover member 64b and the base part 4 in the thickness direction of the semiconductor part 5 (the Z direction). Each of the two cavity parts 63a and 63b can be formed in the manufacturing process by forming the trench parts 61a and 61b extending across the insulating layer 58 and the insulating layer 9, and then blocking the open sides of the trench parts 61a and 61b with the cover members 64a and 64b such that the trench parts 61a and 61b are not filled.

Each of the two cavity parts 63a and 63b is a stress suppression part that suppresses compressive stress acting on the semiconductor part 5 due to a difference between the thermal expansion coefficients of the semiconductor part 5 and the insulating layer 9. In Embodiment 9, the two cavity parts 63a and 63b are provided between (i) the side faces 5b₃ and 5b₄, respectively, of the semiconductor part 5 in the lengthwise direction (the Y direction) and (ii) the insulating layer 9. Accordingly, each of the two cavity parts 63a and 63b according to Embodiment 9 suppresses compressive stress acting in the lengthwise direction of the semiconductor part 5 due to a difference between the thermal expansion coefficients of the semiconductor part 5 and the insulating layer 9.

### <Contact Electrodes and Interconnects>

As illustrated in FIG. 72, unlike the foregoing Embodiment 8, each of the contact electrodes 19a and 19b of Embodiment 9 extends across the insulating layers 18 and 58. One end side of the contact electrode 19a is electrically and mechanically connected to the main electrode region 14a, and the other end side is electrically and mechanically connected to the interconnect 21a. One end side of the contact electrode 19b is electrically and mechanically connected to the main electrode region 14b, and the other end side is electrically and mechanically connected to the interconnect 21b.

On the other hand, as in the foregoing Embodiment 8, the contact electrode 19c of Embodiment 9 is provided in the interconnect layer in the first layer. One end side of the contact electrode 19c is electrically and mechanically connected to the tip part 12a of the gate electrode 12, and the other end side is electrically and mechanically connected to the interconnect 21c.

### <<Method for Manufacturing Semiconductor Apparatus>>

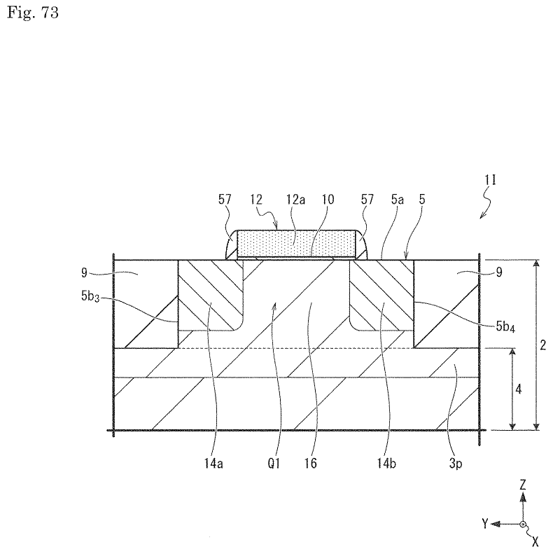

A method for manufacturing the semiconductor apparatus 1I according to Embodiment 9 will be described next with reference to FIGS. 73 to 79. FIGS. 73 to 79 are longitudinal cross-sectional views schematically illustrating the longitudinal cross-sectional structure along the Y direction. Embodiment 9 will specifically describe the manufacturing of the cavity parts 63a and 63b in the method for manufacturing the semiconductor apparatus 1I.

First, aside from the process for forming the trench parts 51a and 51b and the cover members 54a and 54b of the foregoing Embodiment 8, the same process as in the foregoing Embodiment 8 is performed to form the n-channel conductivity type field effect transistor Q1 in the semiconductor part 5, as illustrated in FIG. 73.

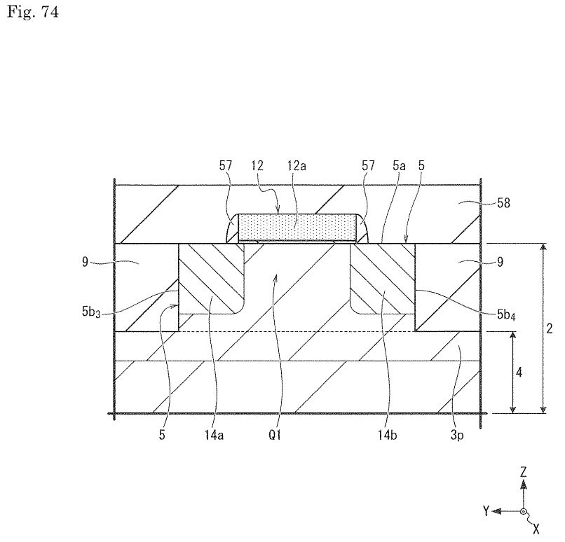

Next, as illustrated in FIG. 74, the insulating layer 58 covering the semiconductor part 5, the insulating layer 9, and the tip part 12a of the gate electrode 12 is formed on the insulating layer 9 side of the semiconductor layer 2. The insulating layer 18 is formed through CVD as a silicon oxide film, for example, as an insulating film over the entire upper face of the semiconductor layer 2 so as to cover the semiconductor part 5, the insulating layer 9, and the tip part 12a of the gate electrode 12.

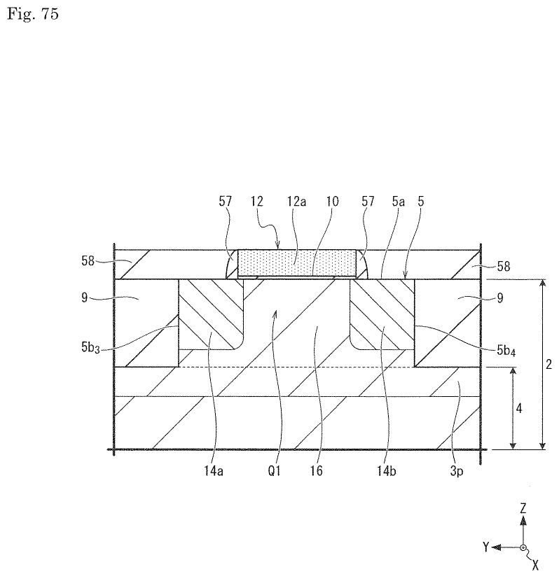

Next, as illustrated in FIG. 75, the side of the insulating layer 58 opposite from the side where the semiconductor layer 2 is located is polished through CMP, for example, to reduce the thickness of the insulating layer 58. The polishing of the insulating layer 58 is performed using the tip part 12a of the gate electrode 12 as a stopper, and the thickness of the insulating layer 58 is reduced such that the upper face of the insulating layer 58 and the upper face of the tip part 12a of the gate electrode 12 are flush.

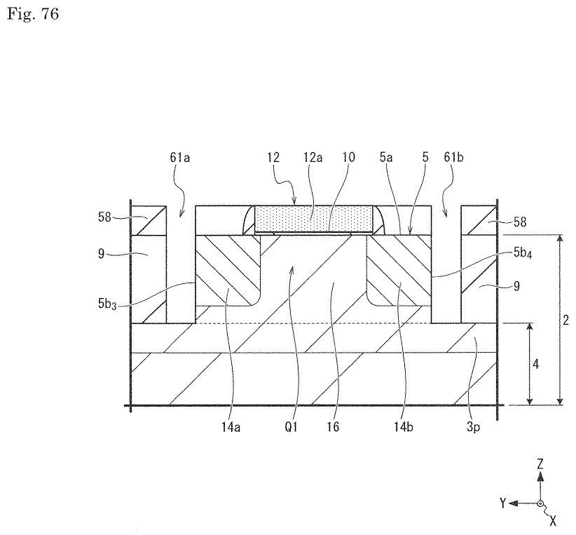

Next, as illustrated in FIG. 76 (a schematic plan view), the trench parts 61a and 61b are formed on the outer sides of both ends (the side faces 5b₃ and 5b₄) of the semiconductor part 5 in the lengthwise direction (the Y direction). Each of the two trench parts 61a and 61b can be formed by selectively etching the insulating layer 58 and the insulating layer 9 using a well-known photolithography technique and dry etching technique. Although not limited thereto, for example, in Embodiment 9, the trench parts 61a and 61b are formed adjacent to the side faces 5b₃ and 5b₄ of the semiconductor part 5 such that the side faces 5b₃ and 5b₄ of the semiconductor part 5 are exposed. In addition, each of the two trench parts 61a and 61b is formed at a depth that reaches the base part 4 from the upper face side of the insulating layer 58. In addition, each of the two trench parts 61a and 61b is formed such that the width thereof in the same direction as the widthwise direction of the semiconductor part 5 (the X direction) is wider than the width of the semiconductor part 5 in the widthwise direction (the X direction).

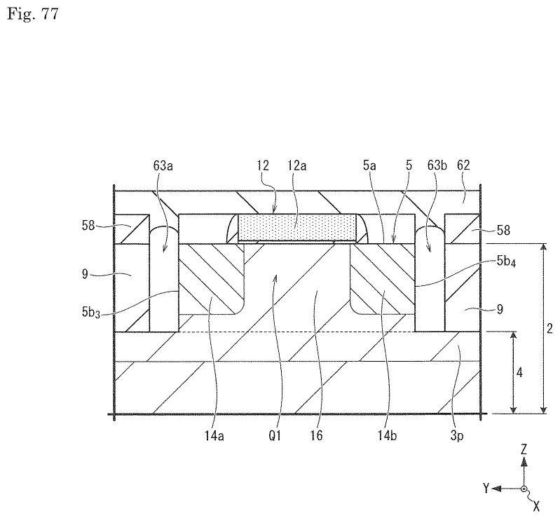

Next, as illustrated in FIG. 77, the cavity parts 63a and 63b are formed in the two trench parts 61a and 61b, respectively, by forming a deposition film 62 on the upper face side of the insulating layer 58, across the insulating layer 58 and the gate electrode 12, so as to cover the open side of each of the two trench parts 61a and 61b. The deposition film 62 is formed such that the open sides of the trench parts 61a and 61b are blocked, but the interiors of the trench parts 61a and 61b are not filled. Like the deposition film 52 of the foregoing Embodiment 8, such cavity parts 63a and 63b can be formed by using a silicon nitride film having low coverage as the deposition film 62, for example.

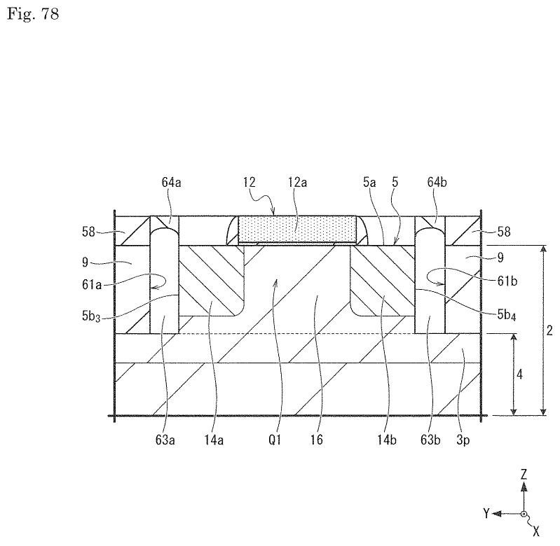

Next, the deposition film 62 on the upper face of the insulating layer 58 and the upper face of the tip part 12a of the gate electrode 12 is selectively removed to form the cover members 64a and 64b covering the respective open sides of the trench parts 61a and 61b, as illustrated in FIG. 78.

In this step, the cavity part 63a, which is surrounded by the side faces of the insulating layers 58 and 9, the side face 5b₃ of the semiconductor part 5, the base part 4, and the cover member 54a, is formed between the side face 5b₃ of the semiconductor part 5 and the insulating layer 9 in plan view. In addition, the cavity part 53a, which is surrounded by the side faces of the insulating layers 58 and 9, the side face 5b₃ of the semiconductor part 5, the base part 4, and the cover member 54a, is formed between the side face 5b4 of the semiconductor part 5 and the insulating layer 9 in plan view.

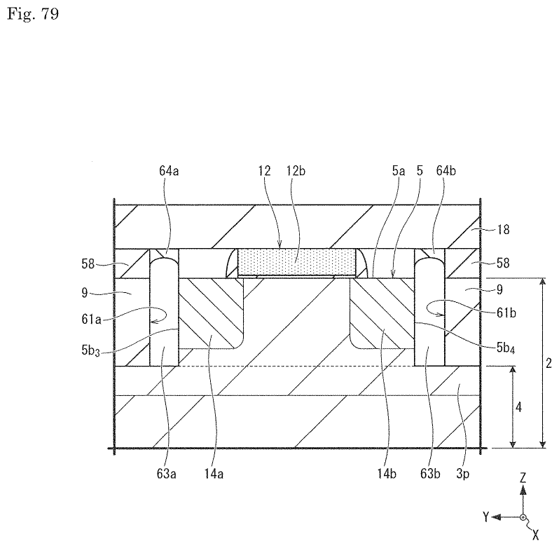

Next, as illustrated in FIG. 79, the insulating layer 18 covering the insulating layer 58 and the tip part 12a of the gate electrode 12 is formed on the insulating layer 9 side of the semiconductor layer 2. The insulating layer 18 can be formed by forming a silicon oxide film, for example, as an insulating film over the entire upper face of the semiconductor layer 2 so as to cover the insulating layer 58 and the tip part 12a of the gate electrode 12, and then flattening the surface of the silicon oxide film through CMP or the like.

Because the upper face sides of the trench parts 61a and 61b are blocked by the cover members 64a and 64b in this step, the formation of the silicon oxide film within the trench parts 61a and 61b, i.e., within the cavity parts 63a and 63b, can be suppressed.

Next, the contact electrodes 19a, 19b, and 19c and the like are formed in the insulating layers including the insulating layer 18 and the insulating layer 58, and then interconnect layer, serving as the first layer including the interconnects 21a, 21b, and 21c and the like, is formed on the upper face of the insulating layer 18, resulting in the state illustrated in FIG. 72.

### <<Main Effects of Embodiment 9>>

In the semiconductor apparatus 1I according to Embodiment 9, the cavity parts 63a and 63b are provided between the two side faces 5b₃ and 5b₄, which are located in the lengthwise direction of the semiconductor part 5 (the Y direction), and the insulating layer 9. Accordingly, the semiconductor apparatus 1I according to Embodiment 9 provides the same effects as those of the semiconductor apparatus 1H according to the foregoing Embodiment 8.

In addition, according to the method for manufacturing the semiconductor apparatus 1I according to Embodiment 9, the cavity parts 63a and 63b can be formed between the two side faces 5b₃ and 5b₄, which are located in the lengthwise direction of the semiconductor part 5 (the Y direction), and the insulating layer 9, even after the field effect transistor Q1 is formed in the semiconductor part 5.

Note that to describe with reference to FIGS. 5 to 7 of the foregoing Embodiment 2, the cavity parts 63a and 63b of Embodiment 9 can also be applied in the semiconductor part 6 on which the p-channel conductivity type field effect transistor Q2 is mounted.

The cavity parts 63a and 63b of Embodiment 9 can also be applied in the SOI-structure semiconductor part 45 described in the foregoing Embodiment 5 (FIGS. 13 to 15).

### Embodiment 10

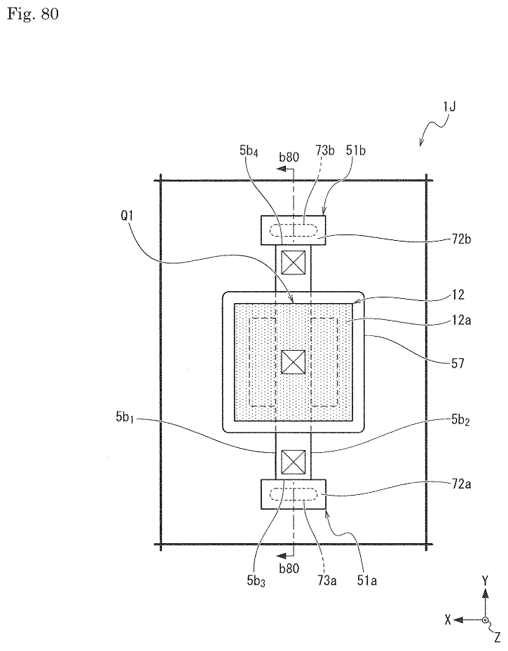

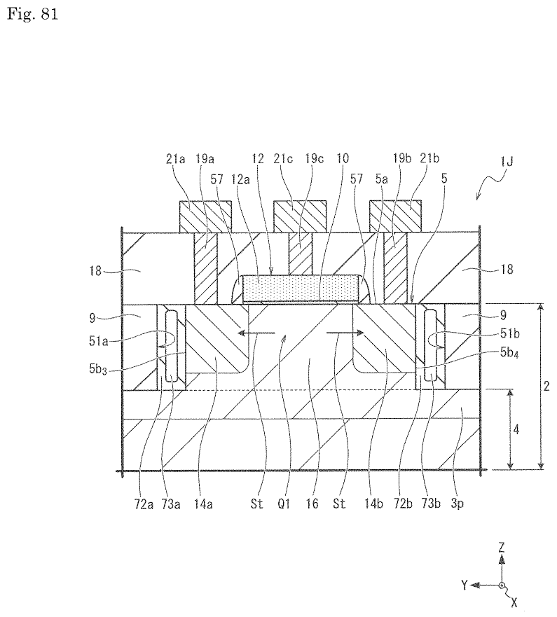

Referring to FIGS. 80 and 81, Embodiment 10 will describe an example in which the present technique is applied in a semiconductor apparatus 1J having the n-channel conductivity type field effect transistor Q1 provided in the semiconductor part 5 having a three-dimensional shape.

For the sake of simplicity, FIG. 80 does not illustrate the insulating layer 18, contact electrodes (19a, 19b, 19c), and interconnects (21a, 21b, 21c), which are illustrated in FIG. 81.

### <<Overall Configuration of Semiconductor Apparatus>>

As illustrated in FIGS. 80 and 81, the semiconductor apparatus 1J according to Embodiment 10 of the present technique has basically the same configuration as the semiconductor apparatus 1H according to the foregoing Embodiment 8, with the exception of the following configurations.

First, as illustrated in FIGS. 80 and 81, the semiconductor apparatus 1J according to Embodiment 10 of the present technique includes cavity parts 73a and 73b and stress films 72a and 72b instead of the cavity parts 53a and 53b and the cover members 54a and 54b illustrated in FIGS. 38 and 40 of the foregoing Embodiment 8. The other configurations are generally the same as those described in the foregoing Embodiment 8.

As illustrated in FIGS. 80 and 81, the two trench parts 51a and 51b are provided on outer sides of the side faces 5b₃ and 5b₄, respectively, in the lengthwise direction of the semiconductor part 5 (the gate length direction of the gate electrode 12; the Y direction), similar to the foregoing Embodiment 8.

Each of the two trench parts 51a and 51b can be formed by selectively etching the insulating layer 9. Although not limited thereto, for example, in Embodiment 10, the two trench parts 51a and 51b are formed adjacent to the side faces 5b₃ and 5b₄ of the semiconductor part 5 such that the side faces 5b₃ and 5b₄ of the semiconductor part 5 are exposed. In addition, each of the two trench parts 51a and 51b is formed at a depth that reaches the base part 4 from the upper face 5a side of the semiconductor part 5. Furthermore, the width of each of the two trench parts 51a and 51b is wider than the width of the semiconductor part 5 in the widthwise direction (the gate width direction of the gate electrode 12 in plan view; the X direction).

### <Stress Films>

As illustrated in FIG. 81, the stress film 72a is provided within the trench part 51a. The stress film 72a is provided along the inner wall part (the side wall part and bottom wall part) of the trench part 51a at a film thickness that does not fill the trench part 51a, such that the cavity part 73a is present within the trench part 51a, and blocks the open side of the trench part 51a. Although not limited thereto, the stress film 72a of Embodiment 10 is adjacent to each of the side face 5b3 of the semiconductor part 5, the upper face 5a of the base part 4, and the side face of the insulating layer 9, in contact therewith, within the trench part 51a.

The stress film 72b is provided within the trench part 51b. The stress film 72b is provided along the inner wall part (the side wall part and bottom wall part) of the trench part 51b at a film thickness that does not fill the trench part 51b, such that the cavity part 73b is present within the trench part 51b, and blocks the open side of the trench part 51b. Although not limited thereto, the stress film 72b of Embodiment 10 is adjacent to each of the side face 5b4 of the semiconductor part 5, the upper face of the base part 4, and the side face of the insulating layer 9, in contact therewith, within the trench part 51b.

By using films having low coverage during film formation, the stress films 72a and 72b can individually cover the inner wall sides of the trench parts 51a and 51b, respectively, without filling the trench parts 51a and 51b, and can block the open sides of the trench parts 51a and 51b. A silicon nitride film can be used as the stress films 72a and 72b, for example.

The stress films 72a and 72b are adjacent to the side faces 5b₃ and 5b₄, respectively, of the semiconductor part 5, along the thickness direction of the semiconductor part 5 (the Z direction). The stress films 72a and 72b are stress-inducing parts that produce (induce) stress in the semiconductor part 5 in a direction in which current flowing in the semiconductor part 5 increases. In other words, the stress films 72a and 72b produce (induce) stress in the semiconductor part 5 in a direction in which current (the drain current Id) flowing from one to the other of the pair of main electrode regions 14a and 14b through the channel forming part 16 increases. To rephrase again, the stress films 72a and 72b produce (induce) stress in the semiconductor part 5 in a direction in which the mobility of carriers moving from one to the other of the pair of main electrode regions 14a and 14b through the channel forming part 16 increases.

A silicon nitride (SiN) film that can be formed through plasma CVD can be used as the stress films 72a and 72b, for example. As described above, with a silicon nitride film, the coefficient of thermal expansion can be controlled by changing the conditions under which the film is formed (the reaction gas, pressure, temperature, high-frequency power, and the like).

Accordingly, by using the silicon nitride film as the stress films 72a and 72b, the cavity parts 73a and 73b can be formed in the trench parts 51a and 51b, and stress can be produced (induced) in the semiconductor part 5 in a direction in which current flowing in the semiconductor part 5 increases.

In Embodiment 10, the semiconductor part 5 is provided with the n-channel conductivity type field effect transistor Q1. Accordingly, the thermal expansion coefficients of the stress films 72a and 72b are controlled such that the tensile stress St in the gate length direction of the gate electrode (the Y direction) is produced in the semiconductor part 5.

Note that a natural oxide film, a buffer film, or the like may be interposed between the side faces 5b₃ and 5b₄ of the semiconductor part 5 and the stress films 72a and 72b.

### <Cavity Parts>

The cavity part 73a is provided within the trench part 51a. The cavity part 73a is surrounded by the stress film 72a along the side face of the insulating layer 9 and the stress film 72a along the side face 5b₃ of the semiconductor part 5 in the lengthwise direction of the semiconductor part 5 (the Y direction), and is surrounded by the stress film 72a blocking the open side of the trench part 51a and the stress film 72a along the upper face of the base part 4 in the thickness direction of the semiconductor part 5 (the Z direction).

On the other hand, the cavity part 73b is provided within the trench part 51b. The cavity part 73b is surrounded by the stress film 72b along the side face of the insulating layer 9 and the stress film 72b along the side face 5b₄ of the semiconductor part 5 in the lengthwise direction of the semiconductor part 5 (the Y direction), and is surrounded by the stress film 72b blocking the open side of the trench part 51b and the stress film 72b along the upper face of the base part 4 in the thickness direction of the semiconductor part 5 (the Z direction).

Each of the two cavity parts 73a and 73b can be formed in the manufacturing process by forming the trench parts 51a and 51b in the insulating layer 9, and then forming a stress film along the inner wall parts of the trench parts 51a and 51b such that the open sides of the trench parts 51a and 51b are blocked.

Each of the two cavity parts 73a and 73b is a stress suppression part that suppresses compressive stress acting on the semiconductor part 5 due to a difference between the thermal expansion coefficients of the semiconductor part 5 and the insulating layer 9. In Embodiment 10, the two cavity parts 73a and 73b are provided between (i) the side faces 5b₃ and 5b₄, respectively, of the semiconductor part 5 in the lengthwise direction (the Y direction) and (ii) the insulating layer 9. Accordingly, each of the two cavity parts 73a and 73b suppresses compressive stress acting in the lengthwise direction of the semiconductor part 5 due to a difference between the thermal expansion coefficients of the semiconductor part 5 and the insulating layer 9.

### <<Method for Manufacturing Semiconductor Apparatus>>

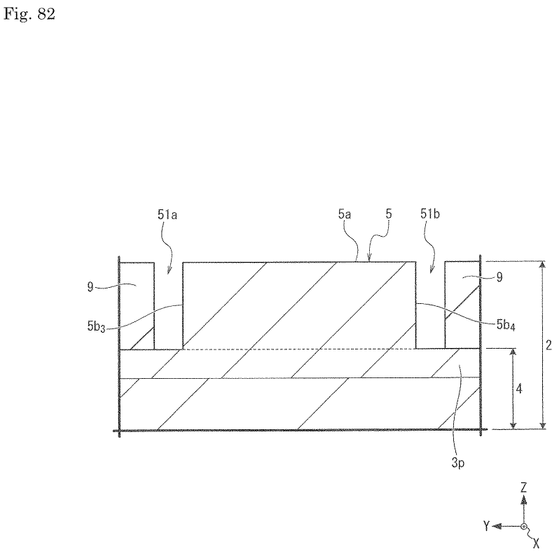

A method for manufacturing the Semiconductor apparatus 1J according to Embodiment 10 will be described next with reference to FIGS. 82 to 84. FIGS. 82 to 84 are longitudinal cross-sectional views schematically illustrating the longitudinal cross-sectional structure along the Y direction.

Embodiment 10 will specifically describe the manufacturing of the cavity parts 73a and 73b in the method for manufacturing the semiconductor apparatus 1J.

First, the same steps as in the foregoing Embodiment 8 are performed to form the trench parts 51a and 51b on the outer sides of both ends (the side faces 5b₃ and 5b₄) of the semiconductor part 5 in the lengthwise direction (the Y direction), as illustrated in FIG. 82.

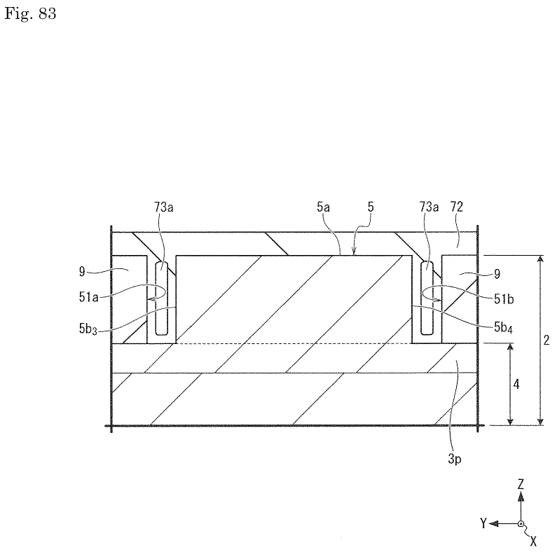

Next, as illustrated in FIG. 83, a stress film 72 is formed extending along the inner wall parts (the side wall parts and bottom wall parts) of the trench parts 51a and 51b so as to block the open sides of the trench parts 51a and 51b, and the cavity parts 73a and 73b surrounded by the stress film 72 are formed.

The stress film 72 is formed such that the open sides of the trench parts 51a and 51b are blocked, but the interiors of the trench parts 51a and 51b are not filled.

The cavity parts 73a and 73b can be formed by using a silicon nitride film having low coverage as the stress film 72, for example.

With a silicon nitride film, the thermal expansion coefficient can be controlled by changing the film formation conditions. In this embodiment, a silicon nitride film having a smaller (lower) thermal expansion coefficient than the thermal expansion coefficient of the semiconductor part 5 is used as the stress film 72, for example.

In this step, the stress film 72 is formed on the semiconductor part 5 and the insulating layer 9.

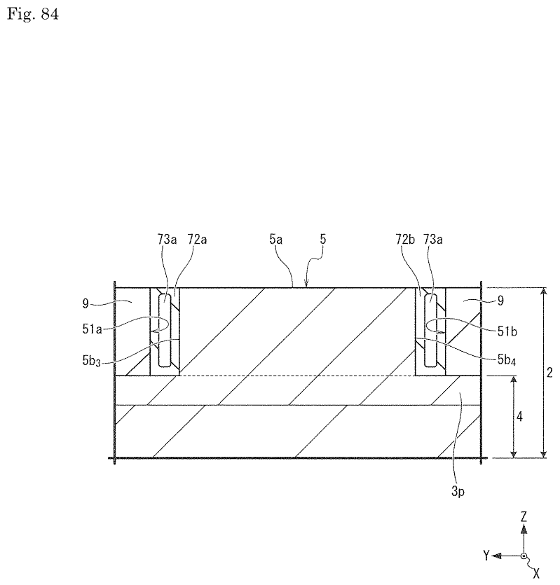

Next, as illustrated in FIG. 84, the stress film 72 on the semiconductor part 5 and the insulating layer 9 is selectively removed by CMP or etching back, for example.

Through this step, the stress film 72a and the cavity part 73a surrounded by the stress film 72a can be selectively formed within the trench part 51a.

Additionally, the stress film 72b and the cavity part 73b surrounded by the stress film 72b can be selectively formed within the trench part 51b.

Thereafter, the same steps as in Embodiment 8 above are performed to form the n-channel conductivity type field effect transistor Q1, the insulating layer 18, the contact electrodes 19a, 19b, and 19c, the interconnects 21a, 21b, and 21c, and the like, resulting in the state illustrated in FIGS. 80 and 81.

### <<Main Effects of Embodiment 10>>

In the semiconductor apparatus 1J according to Embodiment 10, the cavity parts 73a and 73b are provided between the two side faces 5b₃ and 5b₄, which are located in the lengthwise direction of the semiconductor part 5 (the Y direction), and the insulating layer 9. Accordingly, the semiconductor apparatus 1J according to Embodiment 10 provides the same effects as those of the semiconductor apparatus 1H according to the foregoing Embodiment 8.

In addition, the semiconductor apparatus 1J according to Embodiment 10 includes the stress films 72a and 72b on the outer sides of the side surfaces of the semiconductor part 5 in the lengthwise direction. The stress films 72a and 72b are stress-inducing parts that produce (induce) stress in the semiconductor part 5 in a direction in which current flowing in the semiconductor part 5 increases. The thermal expansion coefficients of the stress films 72a and 72b are controlled such that the tensile stress St along the gate length direction of the gate electrode 12 (the Y direction) is produced in the semiconductor part 5.

Accordingly, as in the foregoing Embodiment 6, the semiconductor apparatus 1J according to Embodiment 10 can improve the carrier mobility in the semiconductor part 5, and can increase the current (the drain current Id) flowing from one to the other of the pair of main electrode regions 14a and 14b through the channel of the channel forming part 16.

In other words, the semiconductor apparatus 1J according to Embodiment 10 makes it possible to further improve the mutual conductance (gm) of the n-channel conductivity type field effect transistor Q1.

In addition, because the mutual conductance of the field effect transistor Q1 can be further improved, the circuit including the field effect transistor Q1 can be made even faster, i.e., the semiconductor apparatus 1J can be made even faster.

In addition, according to the method for manufacturing the semiconductor apparatus 1J according to Embodiment 10, the stress films 72a and 72b and the cavity parts 73a and 73b can be formed between the two side faces 5b₃ and 5b₄, which are located in the lengthwise direction of the semiconductor part 5 (the Y direction), and the insulating layer 9.

The foregoing Embodiment 10 described a case where the stress films 72a and 72b and the cavity parts 73a and 73b are provided on the outer sides of the two side faces 5b₃ and 5b₄ located opposite from each other in the lengthwise direction of the semiconductor part 5. However, the stress films 72a and 72b and the cavity parts 73a and 73b do not absolutely have to be provided in each of the two side faces 5b₃ and 5b₄ located in the lengthwise direction of the semiconductor part 5, and may be provided in at least one thereof. However, providing the stress films 72a and 72b and the cavity parts 73a and 73b in each of the two side faces 5b₃ and 5b₄ makes it possible to effectively improve the mutual conductance (gm) of the field effect transistor Q1.

Additionally, although the foregoing Embodiment 10 described a case where the stress films 72a and 72b and the cavity parts 73a and 73b are applied in the semiconductor part 5 on which the n-channel conductivity type field effect transistor Q1 is mounted, to describe with reference to FIGS. 5 to 7 of the foregoing Embodiment 2, the stress films 72a and 72b and the cavity parts 73a and 73b can also be applied in the semiconductor part 6 on which the p-channel conductivity type field effect transistor Q2 is mounted.

The stress films and cavity parts of Embodiment 10 can also be applied in the SOI-structure semiconductor part 45 illustrated in FIGS. 13 to 15 of the foregoing Embodiment 5.

### Embodiment 11

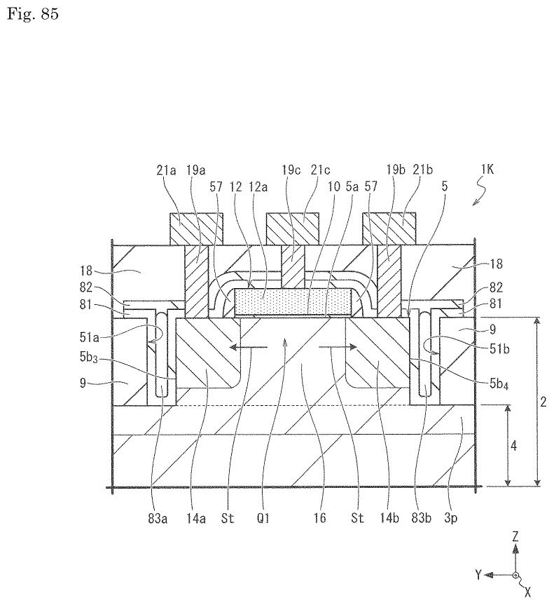

Referring to FIG. 85, Embodiment 11 will describe an example in which the present technique is applied in a semiconductor apparatus 1K having the n-channel conductivity type field effect transistor Q1 provided in the semiconductor part 5 having a three-dimensional shape.

### <<Overall Configuration of Semiconductor Apparatus>>

As illustrated in FIG. 85, the semiconductor apparatus 1K according to Embodiment 11 of the present technique has basically the same configuration as the semiconductor apparatus 1H according to the foregoing Embodiment 8, with the exception of the following configurations.

As illustrated in FIG. 85, the semiconductor apparatus 1K according to Embodiment 11 of the present technique includes cavity parts 83a and 83b, a stress film 81, and a stress film 82 instead of the cavity parts 53a and 53b and the cover members 54a and 54b illustrated in FIGS. 38 and 40 of the foregoing Embodiment 8. The other configurations are generally the same as those described in the foregoing Embodiment 8.

### <Trench Parts>

As illustrated in FIG. 85, the two trench parts 51a and 51b are provided on outer sides of the side faces 5b₃ and 5b₄, respectively, in the lengthwise direction of the semiconductor part 5 (the gate length direction of the gate electrode 12; the Y direction), similar to the foregoing Embodiment 8.

Each of the two trench parts 51a and 51b can be formed by selectively etching the insulating layer 9. Although not limited thereto, for example, in Embodiment 11, the two trench parts 51a and 51b are formed adjacent to the side faces 5b₃ and 5b₄ of the semiconductor part 5 such that the side faces 5b₃ and 5b₄ of the semiconductor part 5 are exposed. In addition, each of the two trench parts 51a and 51b is formed at a depth that reaches the base part 4 from the upper face 5a side of the semiconductor part 5. Furthermore, the width of each of the two trench parts 51a and 51b is wider than the width of the semiconductor part 5 in the widthwise direction (the gate width direction of the gate electrode 12 in plan view; the X direction).

### <Stress Films>

As illustrated in FIG. 85, the stress film 81 is provided over both the insides and the outsides of the trench parts 51a and 51b, respectively. The stress film 81 is provided along the inner wall parts (the side wall parts and bottom wall parts) of the trench parts 51a and 51b, respectively, within the trench parts 51a and 51b. In addition, the stress film 81 covers the tip part 12a of the gate electrode 12 and the semiconductor part 5 on the outer sides of the trench parts 51a and 51b. In other words, the stress film 81 is provided across the upper face 5a and the side faces 5b₃ and 5b₄ of the semiconductor part 5. The stress film 81 is formed at a film thickness that does not fill the trench parts 51a and 51b.

The stress film 81 can be formed along the inner wall parts of the trench parts 51a and 51b by using a film having high coverage during film formation. A silicon nitride film can be used as the stress film 81, for example.

As illustrated in FIG. 85, the stress film 82 is provided on the upper layer of the stress film 81, and overlaps the stress film 81 in plan view, covering the tip part 12a of the gate electrode 12, the semiconductor part 5, and the trench parts 51a and 51b. The stress film 82 blocks (covers) the open sides of the trench parts 51a and 51b such that the cavity parts 83a and 83b are present within the trench parts 51a and 51b.

By using a film having low coverage during film formation, the stress film 82 can block the open sides of the trench parts without filling the trench parts. A silicon nitride film can be used as the stress film 82, for example.

Each of the stress films 81 and 82 covers the tip part 12a of the gate electrode 12 and the upper face 5a side of the semiconductor part 5. The stress film 82 is adjacent to the side faces 5b₃ and 5b₄ of the semiconductor part 5 along the thickness direction of the semiconductor part 5 (the Z direction). The stress films 81 and 82 are stress-inducing parts that produce (induce) stress in the semiconductor part 5 in a direction in which current flowing in the semiconductor part 5 increases. In other words, the stress films 81 and 82 produce (induce) stress in the semiconductor part 5 in a direction in which current (the drain current Id) flowing from one to the other of the pair of main electrode regions 14a and 14b through the channel forming part 16 increases. To rephrase again, the stress films 72a and 72b produce (induce) stress in the semiconductor part 5 in a direction in which the mobility of carriers moving from one to the other of the pair of main electrode regions 14a and 14b through the channel forming part 16 increases.

A silicon nitride (SiN) film that can be formed through plasma CVD can be used as the stress films 81 and 82, for example. As described above, with a silicon nitride film, the coefficient of thermal expansion can be controlled by changing the conditions under which the film is formed (the reaction gas, pressure, temperature, high-frequency power, and the like).

Accordingly, by using the silicon nitride film as the stress films 81 and 82, the cavity parts 83a and 83b can be formed in the trench parts 51a and 51b, and stress can be produced (induced) in the semiconductor part 5 in a direction in which current flowing in the semiconductor part 5 increases.

In Embodiment 11, the semiconductor part 5 is provided with the n-channel conductivity type field effect transistor Q1. Accordingly, the thermal expansion coefficients of the stress films 81 and 82 are controlled such that the tensile stress St in the gate length direction of the gate electrode 12 (the Y direction) is produced in the semiconductor part 5.

Note that a natural oxide film, a buffer film, or the like may be interposed between the side faces 5b₃ and 5b₄ of the semiconductor part 5 and the stress film 81.

### <Cavity Parts>

The cavity part 83a is provided within the trench part 51a, and the cavity part 83b is provided within the trench part 51b. Each of the cavity parts 83a and 83b is surrounded by the stress film 81 along the side face of the insulating layer 9 and the stress film 81 along the side faces 5b₃ and 5b₄ of the semiconductor part 5 in the lengthwise direction of the semiconductor part 5 (the Y direction), and is surrounded by the stress film 82 blocking the open side of the trench part 51a and the stress film 81 along the upper face of the base part 4 in the thickness direction of the semiconductor part 5 (the Z direction).

Each of the two cavity parts 73a and 73b can be formed in the manufacturing process by forming the trench parts 51a and 51b in the insulating layer 9, forming the stress film 81 along the inner wall parts of the trench parts 51a and 51b, and then forming the stress film 82 so as to cover the open sides of the trench parts 51a and 51b.

Each of the two cavity parts 83a and 83b is a stress suppression part that suppresses compressive stress acting on the semiconductor part 5 due to a difference between the thermal expansion coefficients of the semiconductor part 5 and the insulating layer 9. In Embodiment 11, the two cavity parts 83a and 83b are provided between (i) the side faces 5b₃ and 5b₄, respectively, of the semiconductor part 5 in the lengthwise direction (the Y direction) and (ii) the insulating layer 9. Accordingly, each of the two cavity parts 83a and 83b suppresses compressive stress acting in the lengthwise direction of the semiconductor part 5 due to a difference between the thermal expansion coefficients of the semiconductor part 5 and the insulating layer 9.

### <<Main Effects of Embodiment 11>>

In the semiconductor apparatus 1K according to Embodiment 11, the cavity parts 83a and 83b are provided between the two side faces 5b₃ and 5b₄, which are located in the lengthwise direction of the semiconductor part 5 (the Y direction), and the insulating layer 9. Accordingly, the semiconductor apparatus 1K according to Embodiment 11 provides the same effects as those of the semiconductor apparatus 1H according to the foregoing Embodiment 8.

In addition, the semiconductor apparatus 1K according to Embodiment 11 includes the stress film 81 covering the semiconductor part 5 and the gate electrode 12, and covering the side faces 5b₃ and 5b₄ located in the lengthwise direction of the semiconductor part 5 (the Y direction); and the stress film 82 covering the semiconductor part 5 and the gate electrode 12, and blocking the open sides of the trench parts 51a and 51b. The stress films 81 and 82 are stress-inducing parts that produce (induce) stress in the semiconductor part 5 in a direction in which current flowing in the semiconductor part 5 increases. In Embodiment 11, the thermal expansion coefficients of the stress films 81 and 82 are controlled such that the tensile stress St along the gate length direction of the gate electrode 12 (the Y direction) is produced in the semiconductor part 5.

Accordingly, as in the foregoing Embodiment 6, the semiconductor apparatus 1K according to Embodiment 11 can improve the carrier mobility in the semiconductor part 5, and can increase the current (the drain current Id) flowing from one to the other of the pair of main electrode regions 14a and 14b through the channel of the channel forming part 16.

In other words, the semiconductor apparatus 1K according to Embodiment 11 makes it possible to further improve the mutual conductance (gm) of the n-channel conductivity type field effect transistor Q1.

In addition, because the mutual conductance of the field effect transistor Q1 can be further improved, the circuit including the field effect transistor Q1 can be made even faster, i.e., the semiconductor apparatus 1K can be made even faster.

The foregoing Embodiment 11 described a case where the stress film 81 and the cavity parts 83a and 83b are provided on the outer sides of the two side faces 5b₃ and 5b₄ located opposite from each other in the lengthwise direction of the semiconductor part 5 (the Y direction). However, the stress film 81 and the cavity parts 83a and 83b do not absolutely have to be provided in each of the two side faces 5b₃ and 5b₄ located in the lengthwise direction of the semiconductor part 5, and may be provided in at least one thereof. However, providing the stress film 81 and the cavity parts 83a and 83b in each of the two side faces 5b₃ and 5b₄ makes it possible to effectively improve the mutual conductance (gm) of the field effect transistor Q1.

Additionally, although the foregoing Embodiment 11 described a case where the stress films 81 and 82 and the cavity parts 83a and 83b are applied in the semiconductor part 5 on which the n-channel conductivity type field effect transistor Q1 is mounted, to describe with reference to FIGS. 5 to 7 of the foregoing Embodiment 2, the stress films 81 and 82 and the cavity parts 83a and 83b can also be applied in the semiconductor part 6 on which the p-channel conductivity type field effect transistor Q2 is mounted.

The stress films 81 and 82 and the cavity parts 83a and 83b of Embodiment 11 can also be applied in the SOI-structure semiconductor part 45 illustrated in FIGS. 13 to 15 of the foregoing Embodiment 5.

### Embodiment 12

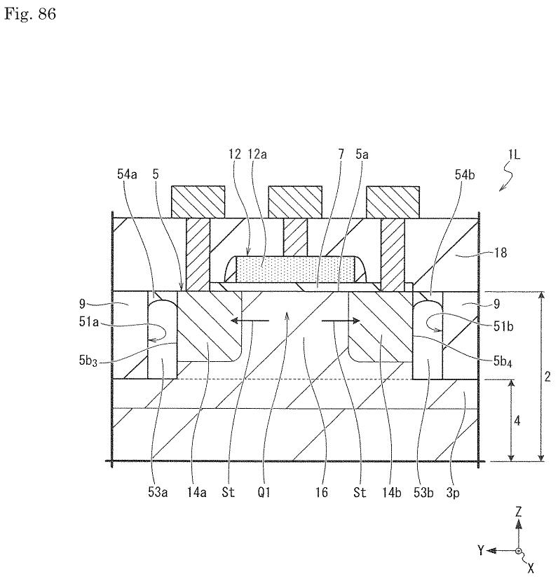

As illustrated in FIG. 86, a semiconductor apparatus 1L according to Embodiment 12 of the present technique combines the stress part 7 of Embodiment 1 with the configuration of the foregoing Embodiment 8. In other words, the semiconductor apparatus 1L according to Embodiment 12 includes the cavity parts 53a and 53b on the outer sides of the side faces 5b₃ and 5b₄, which are located in the lengthwise direction of the semiconductor part 5 (the Y direction), and further includes the stress part 7 on the upper face 5a of the semiconductor part 5.

Compared to the foregoing Embodiment 1 and Embodiment 8, the semiconductor apparatus 1L according to Embodiment 12 makes it possible to further improve the mutual conductance (gm) of the n-channel conductivity type field effect transistor Q1.

The stress part 34 of the foregoing Embodiment 5 may be combined with the semiconductor apparatus 1L according to Embodiment 12.

Additionally, a combination of the configuration of Embodiment 8 and the stress part 7 of Embodiment 1 can also be applied in the semiconductor part 6 on which the p-channel conductivity type field effect transistor Q2 is mounted (see FIG. 7), and can also be applied in the SOI-structure semiconductor part 45 (FIG. 15).

### Embodiment 13

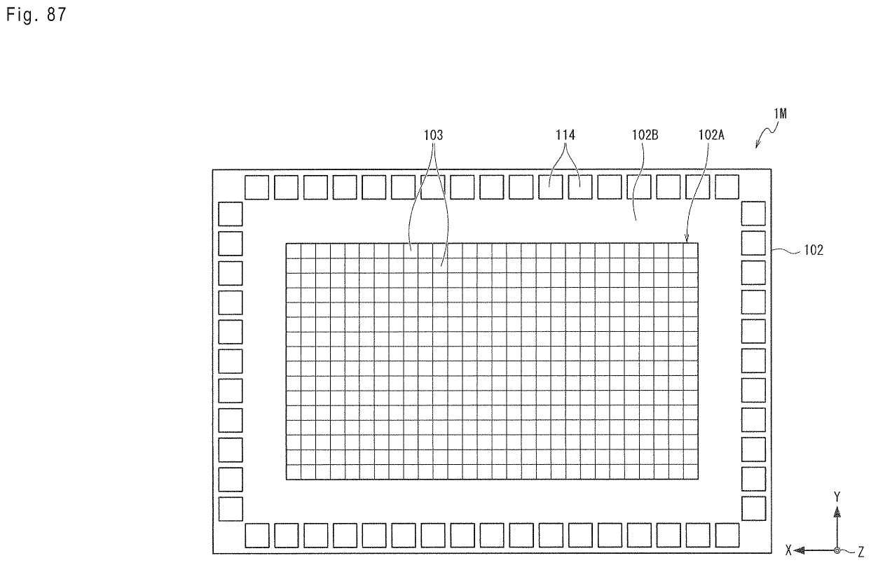

Referring to FIGS. 87 to 90, Embodiment 13 will describe an example in which the present technique is applied in a solid-state imaging device called a back-illuminated Complementary Metal Oxide Semiconductor (CMOS) image sensor serving as a light detection device included in the semiconductor apparatus.

### <<Overall Configuration of Solid-State Imaging Device>>

The overall configuration of a solid-state imaging device 1N will be described first.

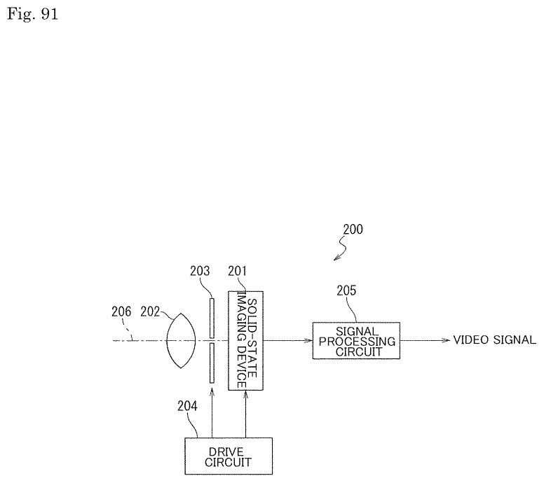

As illustrated in FIG. 87, the solid-state imaging device 1M according to Embodiment 13 of the present technique is constituted mainly by a semiconductor chip 102, which has a square two-dimensional planar shape when viewed in plan view. In other words, the solid-state imaging device 1N is installed on the semiconductor chip 102, and the semiconductor chip 102 can be therefore regarded as the solid-state imaging device 1N. As illustrated in FIG. 91, the solid-state imaging device 1N (201) takes in image light from a subject (incident light 206) through an optical lens 202, converts the amount of incident light 206 formed on an imaging plane into electrical signals on a pixel-by-pixel basis, and outputs the electrical signals as pixel signals (image signals).

As illustrated in FIG. 87, the semiconductor chip 102 on which the solid-state imaging device 1N is installed includes a square pixel array unit 102A provided in a central area and a peripheral part 102B provided outside the pixel array unit 102A so as to surround the pixel array unit 102A, in a two-dimensional plane including the X direction and the Y direction orthogonal to each other. The semiconductor chip 102 is formed by subdividing a semiconductor wafer, which includes the semiconductor layer 2 (described later), into each of chip formation regions in a manufacturing process. Accordingly, the configuration of the solid-state imaging device 1N described below is generally the same in the wafer state prior to subdividing the semiconductor wafer. In other words, the present technique can be applied in both a semiconductor chip state and a semiconductor wafer state.

The pixel array unit 102A is a light-receiving surface that receives the light focused by the optical lens (optical system) 202 illustrated in FIG. 91, for example. In the pixel array unit 102A, a plurality of pixels (sensor pixels) 103 are arranged in a matrix in the two-dimensional plane including the X direction and the Y direction. In other words, the pixels 103 are arranged in a repeating manner in both the X direction and the Y direction, which are orthogonal to each other in the two-dimensional plane.

As illustrated in FIG. 87, a plurality of bonding pads 114 are disposed in the peripheral part 102B. Each of the plurality of bonding pads 114, for example, is disposed along one of the four sides of the two-dimensional plane of the semiconductor chip 102. Each of the plurality of bonding pads 114 functions as an input/output terminal that electrically connects the semiconductor chip 102 to an external device.

### <Logic Circuitry>

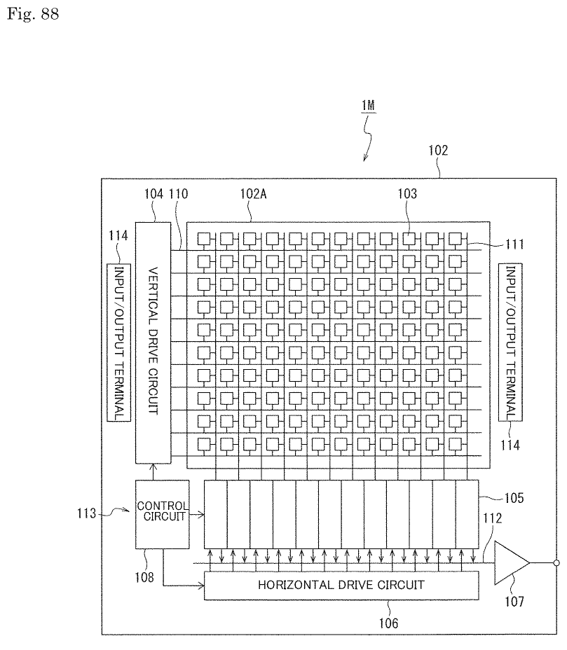

The semiconductor chip 102 includes a logic circuit 113, which is illustrated in FIG. 88. As illustrated in FIG. 88, the logic circuit 113 includes a vertical drive circuit 104, column signal processing circuits 105, a horizontal drive circuit 106, an output circuit 107, a control circuit 108, and the like. The logic circuit 113 is constituted by a Complementary MOS (CMOS) circuit having an n-channel conductivity type Metal Oxide Semiconductor Field Effect Transistor (MOSFET) and a p-channel conductivity type MOSFET as field effect transistors, for example.

The vertical drive circuit 104 is constituted by a shift register, for example. The vertical drive circuit 104 selects a desired pixel drive line 110 in sequence, supplies a pulse for driving the pixels 103 to the selected pixel drive line 110, and drives respective pixels 103 in unit of rows. In other words, the vertical drive circuit 104 sequentially performs selective scanning of the pixels 103 of the pixel array unit 102A in units of rows in a vertical direction, and supplies pixel signals from the pixels 103, which are based on signal charges generated in accordance with the amount of light received by photoelectric conversion units (photoelectric conversion elements) of the pixels 103, to the column signal processing circuits 105 through vertical signal lines 111.

The column signal processing circuits 105 are provided, for example, for corresponding columns of pixels 103, and perform signal processing such as noise removal for each pixel column on a signal output from the pixels 103 corresponding to one row. For example, the column signal processing circuits 105 perform signal processing such as Correlated Double Sampling (CDS) and Analog Digital (AD) conversion for removing pixel-specific fixed pattern noise.

The horizontal drive circuit 106 is constituted by a shift register, for example. The horizontal drive circuit 106 sequentially selects each column signal processing circuit 105 by sequentially outputting a horizontal scanning pulse to the column signal processing circuit 105, and outputs a pixel signal on which signal processing has been performed from each column signal processing circuit 105 to a horizontal signal line 112.

The output circuit 107 performs signal processing on the pixel signals sequentially supplied from the respective column signal processing circuits 105 through the horizontal signal line 112, and outputs the resulting pixel signals.

Examples of the signal processing which may be used include buffering, black level adjustment, column variation correction, various types of digital signal processing, and the like, for example.

The control circuit 108 generates a clock signal or a control signal as a reference for operations of the vertical drive circuit 104, the column signal processing circuit 105, the horizontal drive circuit 106, and the like on the basis of a vertical synchronization signal, a horizontal synchronization signal, and a master clock signal. The control circuit 108 then outputs the generated clock signal or control signal to the vertical drive circuit 104, the column signal processing circuits 105, the horizontal drive circuit 106, and the like.

### <Circuit Configuration of Pixel>

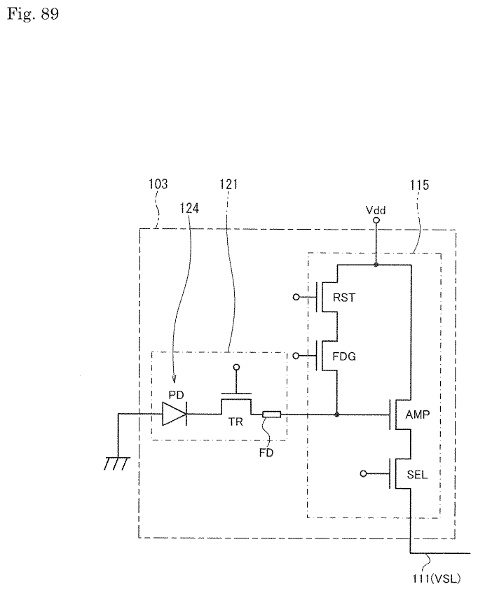

Each pixel 103 of the plurality of pixels 103 illustrated in FIGS. 87 and 88 includes a photoelectric conversion region 121 and a pixel circuit (readout circuit) 115, illustrated in FIG. 89. The photoelectric conversion region 121 includes a photoelectric conversion unit 124, a transfer transistor TR, and a charge holding region (Floating Diffusion) FD. The pixel circuit 115 is electrically connected to the charge holding region FD of the photoelectric conversion region 121. Although Embodiment 5 will describe a circuit configuration in which one pixel circuit 115 is assigned to one pixel 103 as an example, the configuration is not limited thereto, and a circuit configuration in which one pixel circuit 115 is shared by a plurality of pixels 103 may be used. For example, a circuit configuration in which one pixel circuit 115 is shared by four pixels 103 in a 2×2 arrangement, with two pixels in each of the X direction and the Y direction (a single pixel block), may be used.

The photoelectric conversion unit 124 illustrated in FIG. 89 is constituted by, for example, a pn junction photodiode (PD), and generates a signal charge according to an amount of light received. The photoelectric conversion unit 124 is electrically connected to the source region of the transfer transistor TR on the cathode side, and to a reference potential line (e.g., ground) on the anode side.

The transfer transistor TR illustrated in FIG. 89 transfers a signal charge photoelectrically converted by the photoelectric conversion unit 124 to the charge holding region FD. The source region of the transfer transistor TR is electrically connected to the cathode side of the photoelectric conversion unit 124, and the drain region of the transfer transistor TR is electrically connected to the charge holding region FD. The gate electrode of the transfer transistor TR is electrically connected to a transfer transistor drive line of the pixel drive lines 110 (see FIG. 76).

The charge holding region FD illustrated in FIG. 89 temporarily holds (accumulates) the signal charge transferred from the photoelectric conversion unit 124 via the transfer transistor TR.

The photoelectric conversion region 121 including the photoelectric conversion unit 124, the transfer transistor TR, and the charge holding region FD is provided in a semiconductor layer 130 (described later) serving as a second semiconductor layer (see FIG. 88).

The pixel circuit 115 illustrated in FIG. 89 reads out the signal charge held in the charge holding region FD, converts the read-out signal charge into a pixel signal, and outputs the pixel signal. In other words, the pixel circuit 115 converts the signal charge converted by the photoelectric conversion unit 124 into a pixel signal based on this signal charge, and outputs the pixel signal. Although not limited thereto, the pixel circuit 115 includes, for example, an amplifying transistor AMP, a selection transistor SEL, a reset transistor RST, and a switching transistor FDG as pixel transistors. Each of the pixel transistors (AMP, SEL, RST, and FDG) and the transfer transistor TR described above is constituted by a MOSFET as a field effect transistor, for example. The transistors may be MISFETs.

Among the pixel transistors included in the pixel circuit 115, each of the selection transistor SEL, the reset transistor RST, and the switching transistor FDG functions as a switching element, and the amplifying transistor AMP functions as an amplifying element. In other words, the pixel circuit 115 includes field effect transistors having different applications.

Note that the selection transistor SEL and the switching transistor FDG may be omitted as necessary.

As illustrated in FIG. 89, the amplifying transistor AMP has a source region electrically connected to a drain region of the selection transistor SEL, and a drain region electrically connected to a power source line Vdd and a drain region of the reset transistor RST. The gate electrode of the amplifying transistor AMP is electrically connected to the charge holding region FD and a source region of the switching transistor FDG.

The selection transistor SEL has a source electrically connected to the vertical signal line 111 (VSL), and a drain region electrically connected to a source region of the amplifying transistor AMP. The gate electrode of the selection transistor SEL is electrically connected to a selection transistor drive line of the pixel drive lines 110 (see FIG. 86).

The reset transistor RST has a source region electrically connected to a drain region of the switching transistor FDG, and a drain region electrically connected to the power source line Vdd and a drain region of the amplifying transistor AMP. The gate electrode of the reset transistor RST is electrically connected to a reset transistor drive line of the pixel drive lines 110 (see FIG. 86).

The switching transistor FDG has a source region electrically connected to the charge holding region FD and the gate electrode of the amplifying transistor AMP, and a drain region electrically connected to the power source line Vdd and the drain region of the amplifying transistor AMP. The gate electrode of the switching transistor FDG is electrically connected to a switching transistor drive line of the pixel drive lines 110 (see FIG. 86).

Note that when the selection transistor SEL is omitted, the source region of the amplifying transistor AMP is electrically connected to the vertical signal line 111 (VSL). In addition, when the switching transistor FDG is omitted, the source region of the reset transistor RST is electrically connected to the gate electrode of the amplifying transistor AMP and the charge holding region FD.

When the transfer transistor TR is turned on, the transfer transistor TR transfers the signal charge generated by the photoelectric conversion unit 124 to the charge holding region FD.

When the reset transistor RST is turned on, the reset transistor RST resets the potential of the charge holding region FD (the signal charge) to the potential of the power source line Vdd. The selection transistor SEL controls the timing at which the pixel signal is output from the pixel circuit 115.

The amplifying transistor AMP generates, as the pixel signal, a signal at a voltage based on the level of the signal charge held in the charge holding region FD. The amplifying transistor AMP constitutes a source-follower amplifier, and outputs a pixel signal at a voltage based on the level of the signal charge generated by the photoelectric conversion unit 124. When the selection transistor SEL is turned on, the amplifying transistor AMP amplifies the potential of the charge holding region FD and outputs a voltage based on that potential to the column signal processing circuit 105 over the vertical signal line 111 (VSL).

The switching transistor FDG controls the holding of the charge by the charge holding region FD, and adjusts a voltage multiplication factor based on the potential amplified by the amplifying transistor AMP.

During the operation of the solid-state imaging device 1N according to Embodiment 5, the signal charge generated by the photoelectric conversion unit 124 of the pixel 103 is held (accumulated) in the charge holding region FD via the transfer transistor TR of the pixel 103. The signal charge held in the charge holding region FD is then read out by the pixel circuit 115 and applied in the gate electrode of the amplifying transistor AMP of the pixel circuit 115. A horizontal line selection control signal is provided from the vertical shift register to the gate electrode of the selection transistor SEL of the pixel circuit 115. Then, when the selection control signal is set to high (H) level, the selection transistor SEL becomes conductive, and a current corresponding to the potential of the charge holding region FD, amplified by the amplifying transistor AMP, flows in the vertical signal line 111. Additionally, when a reset control signal applied to the gate electrode of the reset transistor RST of the pixel circuit 115 is set to high (H) level, the reset transistor RST becomes conductive and resets the signal charge accumulated in the charge holding region FD.

### <<Longitudinal Cross-Sectional Structure of Solid-State Imaging Device>>

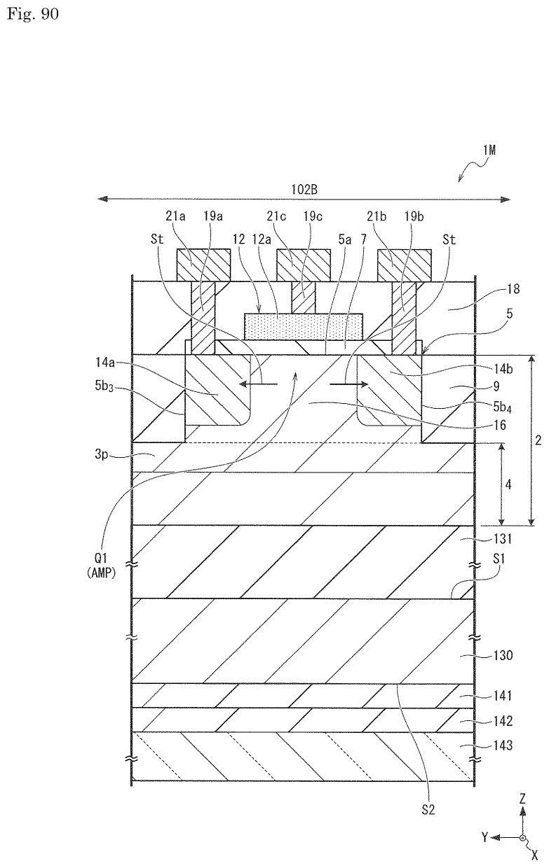

The longitudinal cross-sectional structure of the semiconductor chip 102 (the solid-state imaging device 1N) will be described next with reference to FIG. 90. FIG. 90 is a schematic longitudinal cross-sectional view illustrating the longitudinal cross-sectional structure in the pixel array unit illustrated in FIG. 87, and is inverted vertically relative to FIG. 87 to make the figure easier to understand.

### <Semiconductor Chip>

As illustrated in FIG. 90, the semiconductor chip 102 includes: a semiconductor layer 130 having a first face S1 and a second face S2 located on opposite sides from each other in the thickness direction (the Z direction); an insulating layer 131 provided on the first face S1 side of the semiconductor layer 130; and the semiconductor layer 2 provided on the side of the insulating layer 131 opposite from the side where the semiconductor layer 130 is located.

The semiconductor chip 102 also includes a flattening layer 141, a color filter layer 142, and a lens layer 143 on the second face S2, which are layered in that order from the second face S2 side of the semiconductor layer 130.

The semiconductor layer 130 is constituted by single-crystal silicon, for example.

The flattening layer 141 is constituted by a silicon oxide film, for example. The flattening layer 141 covers the entirety of the second face S2 side of the semiconductor layer 130 in the pixel array unit 102A such that the second face S2 (light incidence surface) side of the semiconductor layer 130 is a flat, even surface.

In the color filter layer 142, color filters such as red (R), green (G), and blue (B) are provided for each pixel 103 so as to separate the colors of the incident light incident from the light incidence surface side of the semiconductor chip 102.

In the lens layer 143, each pixel 103 is provided with a microlens that focuses irradiated light and efficiently causes the focused light to be incident on the photoelectric conversion region 121.

As illustrated in FIG. 90, the semiconductor layer 2 of Embodiment 13 has the same configuration as the semiconductor layer 2 illustrated in FIGS. 2 and 3 of the foregoing Embodiment 1, and the field effect transistor Q1 is provided in the semiconductor part 5 of the semiconductor layer 2. The insulating layer 9 is provided on the base part 4 of the semiconductor layer 2 so as to surround the semiconductor part 5. The field effect transistor Q1 of Embodiment 13 has the same configuration as the field effect transistor Q1 of the foregoing Embodiment 1.

The semiconductor layer 130 is disposed overlapping the semiconductor part 5 of the semiconductor layer 2 in plan view. In other words, the semiconductor chip 102 has a two-level structure in which the semiconductor layer 130 and the semiconductor layer 2 are layered in the thickness directions thereof (the Z direction). In other words, the semiconductor chip 102 of this embodiment further includes the semiconductor layer 130 which overlaps the semiconductor part 5 in plan view and in which the photoelectric conversion unit 124 is provided.

In Embodiment 13, although not illustrated in detail, each of the photoelectric conversion unit 124, the transfer transistor TR, and the charge holding region FD illustrated in FIG. 89 is provided in the semiconductor layer 130 illustrated in FIG. 90.

Meanwhile, although not illustrated in detail, each of the pixel transistors (AMP, SEL, RST, and FDG) included in the pixel circuit 115 in FIG. 89 is provided in the semiconductor layer 2 illustrated in FIG. 90. Each of the pixel transistors (AMP, SEL, RST, and FDG) included in the pixel circuit 115 is constituted by the field effect transistor Q1 illustrated in FIG. 90. FIG. 90 illustrates the amplifying transistor AMP constituted by the field effect transistor Q1 as an example.

### <<Main Effects of Embodiment 13>>

In the solid-state imaging device 1M according to Embodiment 13, each of the pixel transistors (AMP, SEL, RST, and FDG) included in the pixel circuit 115 is constituted by the field effect transistor Q1 provided in the semiconductor part 5.

Furthermore, the semiconductor part 5 is provided with the stress part 7. The solid-state imaging device 1M according to Embodiment 5 therefore provides effects similar to those of the semiconductor apparatus 1A according to the

### Foregoing Embodiment 1.

Here, compared to the pixel transistors that function as switching elements (SEL, RST, and FDG), it is important that the amplifying transistor AMP suppress deterioration in noise resistance to noise such as 1/f noise and RTS noise. Therefore, the present technique is particularly useful in the amplifying transistor AMP included in the pixel circuit, i.e., when the amplifying transistor AMP is constituted by the field effect transistor Q.

Furthermore, the pixel transistors (AMP, SEL, RST, and FDG) included in the pixel circuit 115 are provided in the semiconductor layer 2, which is different from the semiconductor layer 130 provided with the photoelectric conversion unit 124, the transfer transistor TR, and the charge holding region FD. Accordingly, the freedom with which the pixel transistors (AMP, SEL, RST, and FDG) included in the pixel circuit 115 can be arranged can be increased, and higher integration and noise resistance can be achieved compared to the case where the photoelectric conversion unit 124, the transfer transistor TR, the charge holding region FD, the pixel transistors, and the like are provided in the same semiconductor layer.

### <<Variations on Embodiment 13>>

Note that at least one of the pixel transistors (AMP, SEL, RST, and FDG) included in the pixel circuit 115 may be constituted by the field effect transistor Q1 mounted on the semiconductor part 5.

In addition, at least one of the pixel transistors (AMP, SEL, RST, and FDG) included in the pixel circuit 115 may be constituted by the field effect transistor mounted on the semiconductor part of the other embodiments and variations described above.

Although the foregoing Embodiment 13 described a case where the semiconductor part 5 and the field effect transistor Q1 of Embodiment 1 are applied, the semiconductor parts 5, 6, and 45 and the field effect transistors Q1 and Q2 of the foregoing other embodiments and variations can of course also be applied.

### Embodiment 14

### <<Example of Application in Electronic Device>>

The present technique (the technique according to the present disclosure) may be applied in various electronic devices, including imaging devices such as digital still cameras and digital video cameras, mobile phones having imaging functions, or other devices having imaging functions, for example.

FIG. 91 is a diagram illustrating the overall configuration of an electronic device (e.g., a camera) according to Embodiment 6 of the present technique.

As illustrated in FIG. 91, an electronic device 200 includes a solid-state imaging device 201, the optical lens 202, a shutter device 203, a driving circuit 204, and a signal processing circuit 205. This electronic device 200 corresponds to an embodiment in a case where the solid-state imaging device 1M according to Embodiment 13 of the present technique is used as the solid-state imaging device 201 in an electronic device (e.g., a camera).

The optical lens 202 forms an image of image light (incident light 206) from a subject on an imaging plane of the solid-state imaging device 201. As a result, signal charges are accumulated in the solid-state imaging device 201 over a set period. The shutter device 203 controls a light emission period and a light shielding period for the solid-state imaging device 201. The driving circuit 204 supplies a drive signal for controlling a transfer operation of the solid-state imaging device 201 and a shutter operation of the shutter device 203. An operation of transferring a signal to the solid-state imaging device 201 is performed according to the drive signal (timing signal) supplied from the driving circuit 204. The signal processing circuit 205 performs various types of signal processing on signals (pixel signals (image signals) output from the solid-state imaging device 201. A video signal having been subjected to the signal processing is stored in a storage medium such as a memory or output to a monitor.

This configuration makes it possible to achieve faster operations in the solid-state imaging device 201, which makes it possible to achieve faster operations in the electronic device 200 of Embodiment 14.

The electronic device 200 to which the solid-state imaging device of the foregoing embodiments can be applied is not limited to a camera, and the solid-state imaging device can be applied in other electronic devices as well. For example, the solid-state imaging device may be applied in an image capturing device such as a camera module for a mobile device such as a mobile phone or a tablet terminal.

In addition to solid-state imaging devices serving as image sensors as described above, the present technique can be applied in all types of light detection devices, including range sensors which measure distances, known as Time of Flight (ToF) sensors, and the like. A range sensor is a sensor that emits irradiated light toward an object, detects reflected light which returns when the irradiated light is reflected by a surface of the object, and calculates a distance to the object based on a time of flight from when the irradiated light is emitted to when the reflected light is received. The stress-inducing parts (the stress parts 7, 8, 34, 47, and 48), the contact electrodes 23a and 23b, the cavity parts 53a, 53b, 73a, 73b, 83a, and 83b, and the stress films 72a, 72b, 81, and 82 described above can also be used in such a range sensor.

### Other Embodiments

The foregoing embodiments described a case where a field effect transistor is provided in the semiconductor part 5 having a cuboid shape extending in the Y direction. However, the present technique is not limited to a semiconductor part 5 having a cuboid shape.

For example, the present technique can be applied in a field effect transistor in which a channel forming part and a gate electrode are provided in a corner of a semiconductor part having what is an L shape in plan view.

Furthermore, as described in the foregoing Variation 1-1, in the foregoing Embodiment 8 to Embodiment 13, the gate electrode 12 may include three or more leg parts as the leg parts of the gate electrode 12.

The present technique may be configured as follows.

(1)

A semiconductor apparatus including:
a semiconductor part having an upper face and a side face;
a field effect transistor having a gate electrode provided across the upper face and the side face of the semiconductor part; and
a stress part provided between the upper face of the semiconductor part and the gate electrode, the stress part producing, in the semiconductor part, stress in a direction that increases current flowing in the semiconductor part.
   (2)

The semiconductor apparatus according to (1),
wherein the stress part is provided on the upper face of the semiconductor part, across an inner side and an outer side of the gate electrode in plan view.
   (3)

The semiconductor apparatus according to (1) or (2),
wherein the field effect transistor is of an n-channel conductivity type, and the stress produced in the semiconductor part by the stress part is tensile
   (4) The semiconductor apparatus according to (1) or (2), p1 wherein the field effect transistor is of a p-channel conductivity type, and the stress produced in the semiconductor part by the stress part is compressive stress.
   (5)

The semiconductor apparatus according to (1) or (2),
wherein the field effect transistor is of an n-channel conductivity type, and the stress part has a smaller thermal expansion coefficient than the semiconductor part.
   (6)

The semiconductor apparatus according to (1) or (2),
wherein the field effect transistor is of a p-channel conductivity type, and the stress part has a greater thermal expansion coefficient than the semiconductor part.
   (7)

The semiconductor apparatus according to (1) or (2),
wherein the field effect transistor is of an n-channel conductivity type, and the stress part has an inherent tensile stress.
   (8)

The semiconductor apparatus according to (1) or (2),
wherein the field effect transistor is of a p-channel conductivity type, and the stress part has an inherent compressive stress.
   (9)

The semiconductor apparatus according to any one of (1) to (8), further including:
a photoelectric conversion unit; and
a pixel circuit that converts, to a pixel signal, a signal charge obtained by photoelectric conversion by the photoelectric conversion unit,
wherein at least one of a plurality of pixel transistors included in the pixel circuit is constituted by the field effect transistor.
   (10)

The semiconductor apparatus according to (9), further including:
a semiconductor layer which is provided overlapping with the semiconductor part in plan view, and in which the photoelectric conversion unit is provided.
   (11)

The semiconductor apparatus according to any one of (1) to (9),
wherein the stress part is a silicon nitride film.
   (12)

The semiconductor apparatus according to any one of (1) to (11),
wherein the stress part is a first stress part,
the semiconductor apparatus further including:
   a second stress part provided, in plan view, overlapping with the semiconductor part and on an opposite side of the semiconductor part to the upper face side, the second stress part producing, in the semiconductor part, stress in a direction that increases current flowing in the semiconductor part.
      (13)

The semiconductor apparatus according to (12), further including:
an insulating layer provided between the semiconductor part and the second stress part.
   (14)

The semiconductor apparatus according to (12),
wherein the field effect transistor is of an n-channel conductivity type, and the stress produced in the semiconductor part by the second stress part i is tensile stress.
   (15)

The semiconductor apparatus according to (12),
wherein the field effect transistor is of a p-channel conductivity type, and the stress produced in the semiconductor part by the second stress part is compressive stress.
   (16)

The semiconductor apparatus according to (12),
wherein the field effect transistor is of an n-channel conductivity type, and the second stress part has a smaller thermal expansion coefficient than the semiconductor part.
   (17)

The semiconductor apparatus according to (12),
wherein the field effect transistor is of a p-channel conductivity type, and the second stress part has a greater thermal expansion coefficient than the semiconductor part.
   (18)

The semiconductor apparatus according to any one of (12) to (17),
wherein the second stress part is a silicon nitride film.
   (19)

A semiconductor apparatus including:
a semiconductor part having an upper face and a side face;
a field effect transistor having a gate electrode provided across the upper face and the side face of the semiconductor part; and
a stress part provided, in plan view, overlapping with the semiconductor part and on an opposite side of the semiconductor part to the upper face side, the stress part producing, in the semiconductor part, stress in a direction that increases current flowing in the semiconductor part.
   (20)

A semiconductor apparatus including:
a semiconductor part having an upper face and a side face;
a field effect transistor having a gate electrode provided across the upper face and the side face of the semiconductor part; and
a stress part adjacent to the semiconductor part along a thickness direction of the semiconductor part on an outer side of the gate electrode, the stress part producing stress in the semiconductor part in a direction that increases current flowing in the semiconductor part.
   (21)

The semiconductor apparatus according to (20),
wherein the stress part is provided on the side face of the semiconductor part in a gate length direction of the gate electrode.
   (22)

The semiconductor apparatus according to (20),
wherein the stress part is provided within the semiconductor part.
   (23)

The semiconductor apparatus according to any one of (20) to (22),
wherein the field effect transistor is of an n-channel conductivity type, and the stress produced in the semiconductor part by the stress part is tensile stress.
   (24)

The semiconductor apparatus according to any one of (20) to (22),
wherein the field effect transistor is of a p-channel conductivity type, and the stress produced in the semiconductor part by the stress part is compressive stress.
   (25)

The semiconductor apparatus according to any one of (20) to (22),
wherein the field effect transistor is of an n-channel conductivity type, and the stress part has a greater thermal expansion coefficient than the semiconductor part.
   (26)

The semiconductor apparatus according to any one of (20) to (22),
wherein the field effect transistor is of a p-channel conductivity type, and the stress part has a smaller thermal expansion coefficient than the semiconductor part.
   (27)

The semiconductor apparatus according to any one of (20) to (26),
wherein the stress part is a silicon nitride film.
   (28)

The semiconductor apparatus according to (20), further including:
an insulating layer covering the semiconductor part and the gate electrode,
wherein the stress part is a contact electrode extending across the semiconductor part and the insulating layer.
   (29)

The semiconductor apparatus according to (28),
wherein the field effect transistor is of an n-channel conductivity type, and the contact electrode has a greater thermal expansion coefficient than the semiconductor part.
   (30)

The semiconductor apparatus according to (28),
wherein the contact electrode includes any material from among tungsten, titanium, aluminum, molybdenum, and polysilicon.
   (31)

A semiconductor apparatus including:
a semiconductor part having an upper face and a side face;
a field effect transistor having a gate electrode provided across the upper face and the side face of the semiconductor part;
an insulating layer surrounding the side face of the semiconductor part in plan view; and
a cavity part provided between the insulating layer and the side face of the semiconductor part.
   (32)

The semiconductor apparatus according to (31),
wherein in plan view, the cavity part is wider than a width of the semiconductor part along a gate length direction of the gate electrode.
   (33)

The semiconductor apparatus according to (31) or (32),
wherein the cavity part extends along a thickness direction of the semiconductor part.
   (34)

The semiconductor apparatus according to any one of (31) to (33),
wherein the cavity part is surrounded by a trench part provided in the insulating layer and a cover member that covers an open side of the trench part.
   (35)

The semiconductor apparatus according to any one of (31) to (34), further including:
a stress film that produces stress in the semiconductor part in a direction that increases current flowing in the semiconductor part,
wherein the stress film is provided along an inner wall part of the trench part.
   (36)

The semiconductor apparatus according to (35),
wherein the stress film is provided across an inner side of the trench part, and covers the gate electrode.
   (37)

An electronic device including:
a semiconductor apparatus;
an optical lens that forms, on an imaging plane of the semiconductor apparatus, an image of image light from a subject; and
a signal processing circuit that performs signal processing on a signal output from the semiconductor layer,
wherein the semiconductor apparatus includes:
a semiconductor part having an upper face and a side face;
a field effect transistor having a gate electrode provided across the upper face and the side face of the semiconductor part;
a stress part provided between the upper face of the semiconductor part and the gate electrode, the stress part producing, in the semiconductor part, stress in a direction that increases current flowing in the semiconductor part.

The scope of the present technique is not limited to the exemplary embodiments illustrated in the drawings and described above, and includes all embodiments which have the object of the present technique and provide equivalent effects. Furthermore, the scope of the present technique is not limited to the combinations of features of the invention defined by the claims, and can be defined by all desired combinations of specific features among all the features disclosed.

### REFERENCE SIGNS LIST

1A, 1B, 1C, 1D, 1E, 1F, 1G, 1H, 1I, 1J, 1K, 1L Semiconductor apparatus
1M Solid-state imaging device
2 Semiconductor layer
3 Well region
4 Base part
5, 6 Semiconductor part
5a, 6a Upper face
5b₁, 5b₂, 5b₃, 5b₄, 6b₁, 6b₂, 6b₃, 6b₄ Side face
7, 8 Stress part
9 Insulating layer
10, 11 Gate insulating film
12, 13 Gate electrode
14a, 14b, 15a, 15b Main electrode region
16, 17 Channel forming part
18 Insulating layer
19a, 19b, 19c, 20a, 20b, 20c Contact electrode
21a, 21b, 21c, 22a, 22b, 22c Interconnect
23a, 23b Contact electrode
23a₁, 23b₁ First part
23a₂, 23b₂ Second part
34 Stress part
45 Semiconductor part
45a Upper face
45b₁, 45b₂, 45b₃, 45b₄ Side face
45c Lower face
51a, 51b Trench part
52 Deposition film
53a, 53b Cavity part
54a, 54b Cover member
55b1, 55b2 Trench part
56 Conductive film
57 Side wall spacer
58 Insulating layer
61a, 61b Trench part
62 Deposition film
63a, 63b Cavity part
64a, 64b Cover member
70, 72a, 72b Stress film
73a, 73b Cavity part
81, 82 Stress film
83a, 83b Cavity part
102 Semiconductor chip
102A Pixel array unit
102B Peripheral part
103 Pixel
104 Vertical drive circuit
105 Column signal processing circuit
106 Horizontal drive circuit
107 Output circuit
108 Control circuit
110 Pixel drive line
111 Vertical signal line
113 Logic circuit
114 Bonding pad
115 Readout circuit
130 Semiconductor layer (second semiconductor layer)
131 Interconnect layer
141 Flattening layer
142 Filter layer
143 Lens layer
202 Optical lens
203 Shutter device
204 Drive circuit
205 Signal processing circuit
206 Incident light
AMP Amplifying transistor
FDG Switching transistor
RST Reset transistor
SEL Selection transistor
S1 First face
S2 Second face
TR Transfer transistor
Sc Compressive stress
St Tensile stress
Q1, Q2 Field effect transistor

1. A semiconductor apparatus comprising:
a semiconductor part having an upper face and a side face;
a field effect transistor having a gate electrode provided across the upper face and the side face of the semiconductor part; and
a stress part provided between the upper face of the semiconductor part and the gate electrode, the stress part producing, in the semiconductor part, stress in a direction that increases current flowing in the semiconductor part.

2. The semiconductor apparatus according to claim 1,
wherein the stress part is provided on the upper face of the semiconductor part, across an inner side and an outer side of the gate electrode in plan view.

3. The semiconductor apparatus according to claim 1,
wherein the field effect transistor is of an n-channel conductivity type, and the stress produced in the semiconductor part by the stress part is tensile stress.

4. The semiconductor apparatus according to claim 1,
wherein the field effect transistor is of a p-channel conductivity type, and the stress produced in the semiconductor part by the stress part is compressive stress.

5. The semiconductor apparatus according to claim 1,
wherein the field effect transistor is of an n-channel conductivity type, and the stress part has a smaller thermal expansion coefficient than the semiconductor part.

6. The semiconductor apparatus according to claim 1,
wherein the field effect transistor is of a p-channel conductivity type, and the stress part has a greater thermal expansion coefficient than the semiconductor part.

7. The semiconductor apparatus according to claim 1,
wherein the field effect transistor is of an n-channel conductivity type, and the stress part has an inherent tensile stress.

8. The semiconductor apparatus according to claim 1,
wherein the field effect transistor is of a p-channel conductivity type, and the stress part has an inherent compressive stress.

9. The semiconductor apparatus according to claim 1, further comprising:
a photoelectric conversion unit; and
a pixel circuit that converts, to a pixel signal, a signal charge obtained by photoelectric conversion by the photoelectric conversion unit,
wherein at least one of a plurality of pixel transistors included in the pixel circuit is constituted by the field effect transistor.

10. The semiconductor apparatus according to claim 1, further comprising:
a semiconductor layer which is provided overlapping with the semiconductor part in plan view, and in which the photoelectric conversion unit is provided.

11. The semiconductor apparatus according to claim 1,
wherein the stress part is a silicon nitride film.

12. The semiconductor apparatus according to claim 1,
wherein the stress part is a first stress part,
the semiconductor apparatus further comprising:
a second stress part provided, in plan view, overlapping with the semiconductor part and on an opposite side of the semiconductor part to the upper face side, the second stress part producing, in the semiconductor part, stress in a direction that increases current flowing in the semiconductor part.

13. The semiconductor apparatus according to claim 12, further comprising:
an insulating layer provided between the semiconductor part and the second stress part.

14. The semiconductor apparatus according to claim 12,
wherein the field effect transistor is of an n-channel conductivity type, and the stress produced in the semiconductor part by the second stress part is tensile stress.

15. The semiconductor apparatus according to claim 12,
wherein the field effect transistor is of a p-channel conductivity type, and the stress produced in the semiconductor part by the second stress part is compressive stress.

16. The semiconductor apparatus according to claim 12,
wherein the field effect transistor is of an n-channel conductivity type, and the second stress part has a smaller thermal expansion coefficient than the semiconductor part.

17. The semiconductor apparatus according to claim 12,
wherein the field effect transistor is of a p-channel conductivity type, and the second stress part has a greater thermal expansion coefficient than the semiconductor part.

18. The semiconductor apparatus according to claim 12,
wherein the second stress part is a silicon nitride film.

19. A semiconductor apparatus comprising:
a semiconductor part having an upper face and a side face;
a field effect transistor having a gate electrode provided across the upper face and the side face of the semiconductor part; and
a stress part provided, in plan view, overlapping with the semiconductor part and on an opposite side of the semiconductor part to the upper face side, the stress part producing, in the semiconductor part, stress in a direction that increases current flowing in the semiconductor part.

20. A semiconductor apparatus comprising:
a semiconductor part having an upper face and a side face;
a field effect transistor having a gate electrode provided across the upper face and the side face of the semiconductor part; and
a stress part adjacent to the semiconductor part along a thickness direction of the semiconductor part on an outer side of the gate electrode, the stress part producing stress in the semiconductor part in a direction that increases current flowing in the semiconductor part.

21. The semiconductor apparatus according to claim 20,
wherein the stress part is provided on the side face of the semiconductor part in a gate length direction of the gate electrode.

22. The semiconductor apparatus according to claim 20,
wherein the stress part is provided within the semiconductor part.

23. The semiconductor apparatus according to claim 20,
wherein the field effect transistor is of an n-channel conductivity type, and the stress produced in the semiconductor part by the stress part is tensile stress.

24. The semiconductor apparatus according to claim 20,
wherein the field effect transistor is of a p-channel conductivity type, and the stress produced in the semiconductor part by the stress part is compressive stress.

25. The semiconductor apparatus according to claim 20,
wherein the field effect transistor is of an n-channel conductivity type, and the stress part has a greater thermal expansion coefficient than the semiconductor part.

26. The semiconductor apparatus according to claim 20,
wherein the field effect transistor is of a p-channel conductivity type, and the stress part has a smaller thermal expansion coefficient than the semiconductor part.

27. The semiconductor apparatus according to claim 20,
wherein the stress part is a silicon nitride film.

28. The semiconductor apparatus according to claim 20, further comprising:
an insulating layer covering the semiconductor part and the gate electrode, wherein the stress part is a contact electrode extending across the semiconductor part and the insulating layer.

29. The semiconductor apparatus according to claim 28,
wherein the field effect transistor is of an n-channel conductivity type, and the contact electrode has a greater thermal expansion coefficient than the semiconductor part.

30. The semiconductor apparatus according to claim 28,
wherein the contact electrode includes any material from among tungsten, titanium, aluminum, molybdenum, and polysilicon.

31. A semiconductor apparatus comprising:
a semiconductor part having an upper face and a side face;
a field effect transistor having a gate electrode provided across the upper face and the side face of the semiconductor part;
an insulating layer surrounding the side face of the semiconductor part in plan view; and
a cavity part provided between the insulating layer and the side face of the semiconductor part.

32. The semiconductor apparatus according to claim 31, p1 wherein in plan view, the cavity part is wider than a width of the semiconductor part along a gate length direction of the gate electrode.

33. The semiconductor apparatus according to claim 31,
wherein the cavity part extends along a thickness direction of the semiconductor part.

34. The semiconductor apparatus according to claim 31,
wherein the cavity part is surrounded by a trench part provided in the insulating layer and a cover member that covers an open side of the trench part.

35. The semiconductor apparatus according to claim 31, further comprising:
a stress film that produces stress in the semiconductor part in a direction that increases current flowing in the semiconductor part,
wherein the stress film is provided along an inner wall face of the trench part.

36. The semiconductor apparatus according to claim 35,
wherein the stress film is provided across an inner side of the trench part, and covers the gate electrode.

37. An electronic device comprising:
a semiconductor apparatus;
an optical lens that forms, on an imaging plane of the semiconductor apparatus, an image of image light from a subject; and
a signal processing circuit that performs signal processing on a signal output from the semiconductor layer,
wherein the semiconductor apparatus includes:
a semiconductor part having an upper face and a side face;
a field effect transistor having a gate electrode provided across the upper face and the side face of the semiconductor part; and
a stress part provided between the upper face of the semiconductor part and the gate electrode, the stress part producing, in the semiconductor part, stress in a direction that increases current flowing in the semiconductor part.
